(19) United States
(12) Patent Application Publication
(10) Pub. No.: US 2011/0001126 A1
(43) Pub. Date: Jan. 6, 2011

(54) Nitride semiconductor chip, method of fabrication thereof, and semiconductor device

(75) Inventors: Takeshi Kamikawa, Osaka (JP); Masataka Ohta, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/801,910

(22) Filed: Jul. 1, 2010

(30) Foreign Application Priority Data
Jul. 2, 2009 (JP) 2009-158199
Jul. 21, 2009 (JP) 2009-170472

(51) Int. Cl. H01L 29/205; H01L 21/20; H01L 29/20

(52) U.S. Cl. 257/14; 438/478; 257/200; 257/E21.09; 257/E29.091

(57) ABSTRACT

A nitride semiconductor chip is provided that offers enhanced luminous efficacy and an increased yield as a result of an improved EL emission pattern and improved surface morphology (flatness). This nitride semiconductor laser chip (nitride semiconductor chip) includes a GaN substrate having a principal growth plane and individual nitride semiconductor layers formed on the principal growth plane of the GaN substrate. The principal growth plane is a plane having an off angle in the a-axis direction relative to the m plane, and the individual nitride semiconductor layers include a lower clad layer of AlGaN. This lower clad layer is formed in contact with the principal growth plane of the GaN substrate.

This nonprovisional application claims priority under 35 U.S.C. §119(a) on Patent Application No. 2009-158199 filed in Japan on Jul. 2, 2009 and Patent Application No. 2009-170472 filed in Japan on Jul. 21, 2009, the entire contents of which are hereby incorporated by reference.

### BACKGROUND OF THE INVENTION

1. Field of the Invention

The present invention relates to a nitride semiconductor chip, to a method of manufacture thereof, and to a semiconductor device. More particularly, the present invention relates to a nitride semiconductor chip provided with a nitride semiconductor substrate, to a method of manufacture thereof, and to a semiconductor device incorporating such a nitride semiconductor chip.

2. Description of Related Art

Nitride semiconductors as exemplified by GaN, AlN, InN, and their mixed crystals are characterized by having wider band gaps Eg than AlGaInAs- and AlGaInP-based semiconductors and in addition being direct band gap materials. For these reasons, nitride semiconductors have been receiving attention as materials for building semiconductor light-emitting chips such as semiconductor laser chips emitting light in wavelength regions from ultraviolet to green and light-emitting diode chips covering wide emission wavelength ranges from ultraviolet to red, and are expected to find wide application in projectors and full-color displays, and further in environmental, medical, and other fields.

On the other hand, in recent years, many research institutions have been making vigorous attempts to realize semiconductor light-emitting chips emitting light in a green region (green semiconductor lasers) by making longer the emission wavelengths of semiconductor light-emitting chips using nitride semiconductors.

Generally, in a semiconductor light-emitting chip using a nitride semiconductor, a substrate (nitride semiconductor substrate) of GaN, which has a hexagonal crystal system, is used, and its c plane (the (0001) plane) is used as the principal growth plane. By stacking nitride semiconductor layers including an active layer on the c plane, a nitride semiconductor light-emitting chip is formed. Generally, in a case where a nitride semiconductor light-emitting chip is formed by use of a nitride semiconductor substrate, an active layer containing In is used, and by increasing the In composition ratio, a longer emission wavelength is sought.

Inconveniently, however, the c plane of a GaN substrate is a polar plane having polarity in the c-axis direction, and therefore stacking nitride semiconductor layers including an active layer on the c plane inconveniently causes spontaneous polarization in the active layer. Also inconveniently, when nitride semiconductor layers including an active layer are stacked on the c plane, as the In composition ratio increases, lattice distortion increases, inducing in the active layer a strong internal electric field due to piezoelectric polarization. The internal electric field reduces the overlap between the wave functions of electrons and holes, and thus diminishes the rate of radiative recombination. Accordingly, increasing the In composition ratio in an attempt to realize light emission in a green region suffers from the problem that, as the emission wavelength is lengthened, luminous efficacy significantly lowers.

To avoid the effects of spontaneous polarization and piezoelectric polarization, therefore, there are nowadays proposed nitride semiconductor light-emitting chips having nitride semiconductor layers stacked not on the c plane as commonly practiced but on the m plane (the {1-100} plane), which is a non-polar plane. Such nitride semiconductor light-emitting chips are disclosed, for example, in JP-A-2008-91488.

The nitride semiconductor light-emitting chip (light-emitting diode chip) disclosed in JP-A-2008-91488 mentioned above is provided with a GaN substrate of which the m plane, which is a non-polar plane, is used as the principal growth plane, and on this principal growth plane (the m plane), nitride semiconductor layers including an active layer are stacked. The m plane is a crystal plane perpendicular to the c plane, and therefore stacking nitride semiconductor layers including an active layer on the m plane causes the c axis, which is an axis of polarization, to lie on the plane of the active layer. Thus, the effects of spontaneous polarization and piezoelectric polarization are avoided, and the lowering of luminous efficacy is suppressed.

As described above, by use of a nitride semiconductor substrate having the m plane as the principal growth plane, it is possible to obtain a nitride semiconductor light-emitting chip in which the lowering of luminous efficacy due to spontaneous polarization and piezoelectric polarization is suppressed.

Inconveniently, however, through measurement of luminous efficacy (of light emission resulting from current injection, that is, electroluminescence, abbreviated to EL) with regard to nitride semiconductor light-emitting chips using a nitride semiconductor substrate having the m plane as the principal growth plane, it was confirmed that, as the In composition ratio in the active layer increased, the luminous efficacy sharply lowered. Through intensive studies in search of the cause of the phenomenon, the inventors of the present invention found out that the lowering of luminous efficacy was caused by the EL emission pattern (the light distribution across the plane as observed when light was emitted by current injection) becoming bright-spotted. That is, the inventors found out that, as the In composition ratio in the active layer increased, the EL emission pattern of nitride semiconductor light-emitting chips became bright-spotted.

Specifically, when nitride semiconductor light-emitting chips (light-emitting diode chips) using a nitride semiconductor substrate having the m plane as the principal growth plane were fabricated and were made to emit light by current injection, a bright-spotted EL emission pattern as shown in FIG. 48 was observed. What conditions caused this phenomenon had not conventionally been known at all. Through close studies in search for the cause, it was found out that, as the In composition ratio in the active layer increased, the EL emission pattern became increasingly bright-spotted. Such a bright-spotted EL emission pattern became more prominent as the In composition ratio in the active layer increased, and a tendency was observed that a bright-spotted EL emission pattern was especially prominent starting around a green region (with the In composition ratio in the active layer (well layer) equal to or more than 0.15). Variations in wavelength across the plane were also observed that were considered to result from variations in current injection density. As the In content increased further, the number of light-emitting bright spots (the area of light emission) decreased. Thus, a strong correlation was observed between the bright-spotted EL emission pattern and the In composition ratio, and it was therefore found out that the phenomenon of the EL emission pattern becoming bright-spotted caused the lowering of luminous efficacy that occurred with increased In composition ratios in the active layer.

The bright-spotted EL emission pattern described above is a phenomenon prominent in nitride semiconductor light-emitting chips using a nitride semiconductor substrate having a non-polar plane, in particular the m plane, as the principal growth plane.

As discussed above, it has been found out that, in nitride semiconductor light-emitting chips using a nitride semiconductor substrate having the m plane as the principal growth plane, as distinct from nitride semiconductor light-emitting chips using the c plane, whereas the lowering of luminous efficacy due to spontaneous polarization and piezoelectric polarization is suppressed, there is the problem of lower luminous efficacy due to a bright-spotted EL emission pattern. In nitride semiconductor light-emitting chips using the m plane, such a bright-spotted EL emission pattern poses a great problem because it hampers the lengthening of the emission wavelength. In particular, in semiconductor laser chips, low luminous efficacy is a serious problem because it leads to low gain.

In addition, in a case where nitride semiconductor layers are grown on the m plane of a nitride semiconductor substrate, as distinct from a case where nitride semiconductor layers are grown on the c plane, the growth of the nitride semiconductor layers tends to be unstable. This leads to another problem with a nitride semiconductor light-emitting chip (nitride semiconductor chip) using a nitride semiconductor substrate having the m plane as the principal growth plane, specifically the problem that the surface morphology of the nitride semiconductor layers is prone to degradation.

### SUMMARY OF THE INVENTION

The present invention has been devised to overcome the problems mentioned above, and it is an object of the present invention to provide a nitride semiconductor chip that offers enhanced luminous efficacy as a result of an improved EL emission pattern, to provide a method of its manufacture, and to provide a semiconductor device incorporating such a nitride semiconductor chip.

It is another object of the invention to provide a nitride semiconductor chip that has good surface morphology, to provide a method of its manufacture, and to provide a semiconductor device incorporating such a nitride semiconductor chip.

It is yet another object of the invention to provide a nitride semiconductor chip that offers enhanced device characteristics, higher reliability, and increased yields, to provide a method of its manufacture, and to provide a semiconductor device incorporating such a nitride semiconductor chip.

Through various experiments conducted and intensive studies made with attention paid to the problems mentioned above, the inventors have found out that, by using as the principal growth plane of a nitride semiconductor substrate a plane having an off angle relative to the m plane, it is possible to suppress a bright-spotted EL emission pattern.

Specifically, according to a first aspect of the invention, a nitride semiconductor chip includes: a nitride semiconductor substrate having a principal growth plane; and a nitride semiconductor layer formed on the principal growth plane of the nitride semiconductor substrate. Here, the principal growth plane is a plane having an off angle in an a-axis direction relative to an m plane, and the nitride semiconductor layer contains Al and is formed in contact with the principal growth plane.

In the nitride semiconductor chip according to the first aspect, as described above, a plane having an off-angle in the a-axis direction relative to the m plane is taken as the principal growth plane of the nitride semiconductor substrate, and this makes it possible to suppress a bright-spotted EL emission pattern. That is, with that structure, it is possible to improve the EL emission pattern of the nitride semiconductor chip. This makes it possible to enhance the luminous efficacy of the nitride semiconductor chip. By enhancing luminous efficacy, it is possible to obtain a high-luminance nitride semiconductor chip. Incidentally, one reason that an effect of suppressing bright-spotted emission as mentioned above is obtained is considered to be as follows: as a result of the principal growth plane of the nitride semiconductor substrate having an off-angle in the a-axis direction relative to the m plane, when a nitride semiconductor layer is grown on the principal growth plane, the direction of migration of atoms changes.

Moreover, according to the first aspect, by suppressing a bright-spotted EL emission pattern, it is possible to make the EL emission pattern uniform, and thus it is possible to reduce the driving voltage. Incidentally, by suppressing bright-spotted emission, it is possible to obtain a uniform EL emission pattern, and thus it is possible to increase gain in the formation of a nitride semiconductor laser chip. Moreover, with the structure described above, it is possible to suppress a bright-spotted EL emission pattern, and thus it is possible to enhance luminous efficacy. This makes it possible to enhance device characteristics and reliability. That is, it is possible to obtain a nitride semiconductor chip with superb device characteristics and high reliability.

Furthermore, according to the first aspect, by forming, on the principal growth plane having an off angle in the a-axis direction relative to the m plane, a nitride semiconductor layer containing Al in contact with the principal growth plane, it is possible to obtain good surface morphology. This makes it possible to give the nitride semiconductor layer a uniform thickness distribution across the plane, and also to give a semiconductor layer stacked on that nitride semiconductor layer a uniform thickness distribution across the plane. Moreover, by enhancing surface morphology, it is possible to reduce variations in device characteristics, and thus it is possible to increase manufacturing yields. This makes it possible to easily obtain chips having characteristics within the rated ranges. Moreover, by enhancing surface morphology, it is also possible to further enhance device characteristics and reliability.

In the above-described nitride semiconductor chip according to the first aspect, preferably, the absolute value of the off angle in the a-axis direction is larger than 0.1 degrees. With this structure, it is possible to suppress a bright-spotted EL emission pattern easily.

In the above-described nitride semiconductor chip according to the first aspect, preferably, the nitride semiconductor substrate is formed of GaN, and the nitride semiconductor layer is formed of AlGaN. With this structure, it is possible to easily enhance surface morphology while suppressing a bright-spotted EL emission pattern. The nitride semiconductor substrate may instead be formed of AlGaN.

In the above-described nitride semiconductor chip according to the first aspect, preferably, an active layer having a quantum well structure is formed on the nitride semiconductor layer, and the active layer has one well layer. With this structure, it is possible to obtain an effect of suppressing bright-spotted emission, and also to reduce the driving voltage easily. This too helps enhance device characteristics and reliability. Moreover, with this structure, it is possible to obtain higher luminous efficacy than with a structure where the active layer is formed to include three or more well layers. This makes it possible to obtain a high-luminance nitride semiconductor chip easily.

In the above-described nitride semiconductor chip according to the first aspect, preferably, an active layer having a quantum well structure is formed on the nitride semiconductor layer, and the active layer has two well layers. Also with this structure, it is possible to obtain an effect of suppressing bright-spotted emission, and also to reduce the driving voltage easily. Moreover, with this structure, it is possible to obtain higher luminous efficacy than with a structure where the active layer is formed to include three or more well layers.

In the above-described nitride semiconductor chip according to the first aspect, preferably, an active layer having a quantum well structure is formed on the nitride semiconductor layer, the active layer has a well layer formed of a nitride semiconductor containing In, and the well layer has an In composition ratio of 0.15 or more but 0.45 or less. In the nitride semiconductor chip according to the first aspect, in this way, even in a case where the In composition ratio in the well layer is 0.15 or more, that is, even under conditions where a bright-spotted EL emission pattern is prominent, it is possible to suppress a bright-spotted EL emission pattern effectively, and thus it is possible to obtain a prominent effect of suppressing a bright-spotted EL emission pattern. On the other hand, by making the In composition ratio in the well layer equal to or less than 0.45, it is possible to effectively suppress the inconvenience of a large number of dislocations developing in the active layer as a result of strain such as lattice mismatch due to the In composition ratio in the well layer being more than 0.45.

In the above-described structure including an active layer, the active layer has a barrier layer formed of a nitride semiconductor containing Al. With this structure, it is possible to enhance the flatness of the barrier layer; thus, by forming the well layer on the barrier layer with high flatness, it is possible to suppress the well layer having a non-uniform In composition distribution across the plane. It is also possible to enhance the crystallinity of the active layer (well layer). This makes it possible to further enhance luminous efficacy.

In that case, it is preferable that the barrier layer be formed of AlGaN.

In the above-described nitride semiconductor chip according to the first aspect, the principal growth plane of the nitride semiconductor substrate may have an off angle also in a c-axis direction in addition to in the a-axis direction. In that case, it is preferable that the off angle in the a-axis direction be larger than the off angle in the c-axis direction. With this structure, it is possible to suppress a bright-spotted EL emission pattern more effectively.

According to a second aspect of the invention, a nitride semiconductor chip includes: a nitride semiconductor substrate having a principal growth plane; a nitride semiconductor layer formed on the principal growth plane of the nitride semiconductor substrate; and an active layer formed on the nitride semiconductor layer. Here, the principal growth plane is a non-polar plane, ad the active layer has a barrier layer formed of a nitride semiconductor containing Al.

In the nitride semiconductor chip according to the second aspect, as described above, the barrier layer in the active layer formed on the nitride semiconductor layer is formed out of a nitride semiconductor containing Al, and this makes it possible to enhance the flatness of the barrier layer; thus, it is possible to enhance luminous efficacy and reliability.

In the above-described nitride semiconductor chip according to the second aspect, preferably, the principal growth plane is a plane having an off angle in an a-axis direction relative to an m plane. With this structure, as with the nitride semiconductor chip according to the first aspect described previously, it is possible to suppress a bright-spotted EL emission pattern.

In the above-described nitride semiconductor chip according to the second aspect, preferably, the nitride semiconductor layer contains Al and is formed in contact with the principal growth plane. With this structure, it is possible to enhance the flatness of the nitride semiconductor layer; thus, by forming the active layer on this nitride semiconductor layer with high flatness, it is possible to further enhance luminous efficacy.

According to a third aspect of the invention, a nitride semiconductor chip includes: a nitride semiconductor substrate having a principal growth plane; and a nitride semiconductor stacked structure formed on the principal growth plane of the nitride semiconductor substrate. Here, the principal growth plane is a plane having an off angle in an a-axis direction relative to an m plane, and the nitride semiconductor stacked structure has an active layer containing In and a GaN layer formed between the nitride semiconductor substrate and the active layer. Moreover, the GaN layer has a total thickness of 0.7 μm or less. It should be noted that the total thickness here denotes, in a case where one GaN layer is formed, the thickness of that GaN layer and, in a case where a plurality of GaN layers are formed, (the sum of) the thicknesses of those GaN layers added up.

In the nitride semiconductor chip according to the third aspect, as described above, a plane having an off-angle in the a-axis direction relative to the m plane is taken as the principal growth plane of the nitride semiconductor substrate, and this makes it possible to suppress a bright-spotted EL emission pattern; thus, it is possible to enhance the luminous efficacy of the nitride semiconductor chip. Moreover, by enhancing luminous efficacy, it is possible to obtain a high-luminance nitride semiconductor chip.

Moreover, according to the third aspect, by giving the GaN layer formed between the nitride semiconductor substrate and the active layer a total thickness of 0.7 μm or less, it is possible to obtain good surface morphology. This makes it possible to give the GaN layer a uniform thickness distribution across the plane, and also to give a semiconductor layer stacked on that nitride semiconductor layer a uniform thickness distribution across the plane. Moreover, by enhancing surface morphology, it is possible to reduce variations in device characteristics, and thus it is possible to increase manufacturing yields. This makes it possible to easily obtain chips having characteristics within the rated ranges. Moreover, by enhancing surface morphology, it is also possible to further enhance device characteristics and reliability.

In the above-described nitride semiconductor chip according to the third aspect, preferably, the absolute value of the off angle in the a-axis direction is larger than 0.1 degrees. With this structure, it is possible to easily suppress a bright-spotted EL emission pattern and variations in wavelength across the plane.

In the above-described nitride semiconductor chip according to the third aspect, preferably, the active layer has a quantum well structure including one well layer. With this structure, it is possible to obtain an effect of suppressing bright-spotted emission, and also to reduce the driving voltage easily. This too helps enhance device characteristics and reliability. Moreover, with this structure, it is possible to obtain higher luminous efficacy than with a structure where the active layer is formed to include three or more well layers. This makes it possible to obtain a high-luminance nitride semiconductor chip easily. In this case, it is preferable to give the GaN layer formed between the nitride semiconductor substrate and the well layer a total thickness of 0.7 μm or less.

In the above-described nitride semiconductor chip according to the third aspect, preferably, the active layer has a quantum well structure including two well layers. Also with this structure, it is possible to obtain an effect of suppressing bright-spotted emission, and also to reduce the driving voltage easily. Moreover, with this structure, it is possible to obtain higher luminous efficacy than with a structure where the active layer is formed to include three or more well layers. Also in this case, it is preferable to give the GaN layer formed between the substrate-side well layer and the nitride semiconductor substrate a total thickness of 0.7 μm or less.

In the above-described nitride semiconductor chip according to the third aspect, it is preferable that the active layer have a quantum well structure and have a well layer formed of a nitride semiconductor containing In, and that the well layer have an In composition ratio of 0.15 or more but 0.45 or less.

In a case where a light-emitting chip is formed by use of a nitride semiconductor substrate having the m plane as the principal growth plane, typically, the active layer is composed of a multiple-layer film including a well layer and a barrier layer. In that case, for the purposes of achieving effective light confinement and mitigating strain developing in the active layer, it is common to use a well layer of InₐGa₁₋ₐN (0<a≦1) and a barrier layer of In_{b}Ga_{1-b}N (0≦b<1, a>b). Through studies, however, the inventors have found out that using an InGaN layer as the barrier layer causes development of prominent dark lines. It has also been found out that as the In composition ratio “b” in the barrier layer increases, increasingly prominent dark lines develop. It has further been found out that, even in a case where a GaN layer is used as the barrier layer, as the In composition ratio “a” in the well layer increases, due to differences in growth conditions and structure, dark lines eventually develop. Through intensive studies, therefore, the inventors have found out that, by use of a nitride semiconductor layer containing Al as the barrier layer, it is possible to suppress development of dark lines almost completely. As a nitride semiconductor layer for the barrier layer, the best choices are layers of AlGaN and AlInGaN, the second best being AlInN. The above effect can be obtained, however, with any nitride semiconductor layer containing Al (for example, an AlGaN layer, an AlInGaN layer, an AlInN layer, etc.). In a case where a nitride semiconductor layer containing Al (for example, an AlGaN layer, an AlInGaN layer, an AlInN layer, etc.) is used, it is preferable that the well layer in the active layer be formed of InGaN.

In the above-described structure including an active layer, preferably, the active layer has a barrier layer formed of a nitride semiconductor containing Al. With this structure, it is possible to enhance the flatness of the barrier layer; thus, by forming the well layer on the barrier layer with high flatness, it is possible to suppress the well layer having a non-uniform In composition distribution across the plane. It is also possible to enhance the crystallinity of the active layer (well layer). This makes it possible to further enhance luminous efficacy.

In that case, it is preferable that the barrier layer be formed of AlGaN. Incidentally, the barrier layer may be formed of, other than AlGaN, AlInGaN, AlInN, or the like. Here, it has been found out that, when the barrier layer is formed of AlInGaN, the amount of In absorbed in the well layer formed on the barrier layer is larger than when the barrier layer is formed of AlGaN. It is therefore preferable to form the barrier layer out of AlInGaN, because doing so helps widen the range of growth conditions. Moreover, AlInGaN, which has In added to AlGaN, allows easy formation of a film with good crystallinity even when grown at lower temperature. Thus, forming the barrier layer, which is typically formed at a comparatively low growth temperature of about 600° C. to 800° C., out of AlInGaN is preferable, because by doing so, even in a case where the barrier layer is formed at comparatively low temperature as mentioned above, it is possible to obtain a barrier layer with good crystallinity. Moreover, forming the barrier layer out of AlInGaN is preferable, because doing so helps reduce the strain that the barrier layer produces in the well layer. The smaller the strain that develops in the well layer, the better, because that slows down the deterioration of the light-emitting chip during operation.

In the above-described nitride semiconductor chip according to the third aspect, the principal growth plane of the nitride semiconductor substrate may have an off angle also in a c-axis direction in addition to in the a-axis direction. In that case, it is preferable that the off angle in the a-axis direction be larger than the off angle in the c-axis direction. With this structure, it is possible to suppress a bright-spotted EL emission pattern (variations in wavelength across the plane, and development of dark lines) more effectively.

In the above-described nitride semiconductor chip according to the third aspect, it is preferable that the nitride semiconductor substrate be formed of GaN. With this structure, it is possible to easily enhance surface morphology while suppressing a bright-spotted EL emission pattern.

According to a fourth aspect of the invention, a nitride semiconductor chip includes: a nitride semiconductor substrate having a principal growth plane; and a nitride semiconductor stacked structure formed on the principal growth plane of the nitride semiconductor substrate. Here, the principal growth plane is a plane having an off angle in an a-axis direction relative to an m plane, and the nitride semiconductor stacked structure includes an active layer. Moreover, the active layer included in the nitride semiconductor stacked structure has a barrier layer formed of a nitride semiconductor containing Al.

In the nitride semiconductor chip according to the fourth aspect, as described above, a plane having an off-angle in the a-axis direction relative to the m plane is taken as the principal growth plane of the nitride semiconductor substrate, and this, as with the nitride semiconductor chips according to the first to third aspects described previously, makes it possible to suppress a bright-spotted EL emission pattern (variations in wavelength across the plane, and development of dark lines).

Moreover, according to the fourth aspect, by forming the barrier layer in the active layer out of a nitride semiconductor containing Al, it is possible to enhance the flatness of the barrier layer, and thus it is possible to enhance luminous efficacy and reliability.

In the above-described nitride semiconductor chip according to the fourth aspect, preferably, the nitride semiconductor stacked structure further includes a semiconductor layer containing Al formed in contact with the principal growth plane. With this structure, it is possible to enhance the flatness of the nitride semiconductor layer containing Al; thus, by forming the active layer on this nitride semiconductor layer with high flatness, it is possible to further enhance luminous efficacy.

In that case, it is preferable that the semiconductor layer containing Al be an AlGaN layer or an AlInGaN layer. Incidentally, AlInGaN, which has In added to AlGaN, allows easy formation of a film with good crystallinity even when grown at lower temperature. Thus, forming the barrier layer, which is typically formed at a comparatively low growth temperature of about 600° C. to 800° C., out of AlInGaN is preferable, because by doing so, even in a case where the barrier layer is formed at comparatively low temperature as mentioned above, it is possible to obtain a barrier layer with good crystallinity.

According to a fifth aspect of the invention, a method of manufacturing a nitride semiconductor chip includes: a step of preparing a nitride semiconductor substrate including as a principal growth plane a plane having an off angle in an a-axis direction relative to an m plane; and a step of forming on the principal growth plane of the nitride semiconductor substrate a nitride semiconductor layer containing Al in contact with the principal growth plane by an epitaxial growth process. Here, the nitride semiconductor layer may have n-type conductivity, may have p-type conductivity, or may be undoped.

In the nitride semiconductor chip manufacturing method according to the fifth aspect, as described above, use is made of a nitride semiconductor substrate having as a principal growth plane a plane having an off-angle in the a-axis direction relative to the m plane, and this makes it possible to obtain a nitride semiconductor chip in which a bright-spotted EL emission pattern is suppressed. That is, with that structure, it is possible to obtain a nitride semiconductor chip with an improved EL emission pattern. This makes it possible to obtain a high-luminance nitride semiconductor chip with enhanced luminous efficacy.

Moreover, according to the fifth aspect, by forming, on the principal growth plane having an off angle in the a-axis direction relative to the m plane, a nitride semiconductor layer containing Al in contact with the principal growth plane, it is possible to obtain good surface morphology. This makes it possible to give the nitride semiconductor layer a uniform thickness distribution across the plane, and thus it is possible to form a nitride semiconductor layer with high flatness. This in turn makes it possible to give individual semiconductor layers stacked on that nitride semiconductor layer a uniform thickness distribution across the plane, and thus it is possible to enhance the flatness of the individual semiconductor layers. Moreover, by enhancing surface morphology, it is possible to reduce variations in device characteristics, and thus it is possible to increase the number of chips having characteristics within the rated ranges. This makes it possible to increase manufacturing yields. Incidentally, by enhancing surface morphology, it is also possible to further enhance device characteristics and reliability.

In the above-described nitride semiconductor chip manufacturing method according to the fifth aspect, it is preferable to include a step of successively forming, on the principal growth plane of the nitride semiconductor substrate, an n-type semiconductor layer including the above-mentioned nitride semiconductor layer (nitride semiconductor layer containing Al), an active layer, and a p-type semiconductor layer. In this case, it is preferable to from the p-type semiconductor layer at a growth temperature of 700° C. or higher but 1100° C. or lower. Even in a case where the p-type semiconductor layer is formed at a high temperature of 1000° C. or higher in this way, by forming the barrier layer in the active layer out of a nitride semiconductor containing Al, it is possible to suppress blackening of the active layer (well layer). Thus, the p-type semiconductor layer can be formed at a temperature of 1000° C. or higher, and by forming the p-type semiconductor layer at high temperature, it is possible to effectively obtain an effect of reducing the driving voltage. On the other hand, by forming the p-type semiconductor layer at a growth temperature of 700° C. of higher, it is possible to suppress the inconvenience of an increased resistance in the p-type semiconductor layer due to its being formed at a growth temperature lower than 700° C. This too helps enhance device characteristics and reliability. Incidentally, by use of a nitride semiconductor substrate having a principal growth plane provided with an off angle relative to the m plane, even in a case where the p-type semiconductor layer is formed at a growth temperature lower than 900° C., it is possible to obtain p-type conductivity.

Moreover, in that case, it is preferable to form the n-type semiconductor layer at a growth temperature of 900° C. or higher but 1300° C. or lower. By forming the n-type semiconductor layer including the nitride semiconductor layer at a high temperature of 900° C. or higher in this way, it is possible to give the n-type semiconductor layer a flat surface. Thus, by forming the active layer and the p-type semiconductor layer on the n-type semiconductor layer with a flat surface, it is possible to suppress degradation of crystallinity in the active layer and the p-type semiconductor layer. This makes it possible to form a high-quality crystal. On the other hand, by forming the n-type semiconductor layer including the nitride semiconductor layer at a growth temperature lower than 1300° C., it is possible to suppress the inconvenience of the surface of the nitride semiconductor substrate re-evaporating and becoming rough during the raising of temperature due to the n-type semiconductor layer including the nitride semiconductor layer being formed at a growth temperature of 1300° C. or higher. Thus, with this scheme, it is possible to manufacture, easily and at high yields, a nitride semiconductor chip with superb device characteristics and high reliability.

Furthermore, in that case, it is preferable to form the active layer at a growth temperature of 600° C. or higher but 800° C. or lower. By forming the active layer at a growth temperature of 800° C. or lower in this way, it is possible to suppress the inconvenience of the active layer being blackened by thermal damage due to the active layer being formed at a growth temperature higher than 800° C. (for example, 830° C. or higher). On the other hand, by forming the active layer at a growth temperature of 600° C. or higher, it is possible to suppress the inconvenience of a shorter atom diffusion length and hence degraded crystallinity due to the active layer being formed at a growth temperature lower than 600° C. Thus, with this scheme, it is possible to manufacture, more easily and at high yields, a nitride semiconductor chip with superb device characteristics and high reliability.

According to a sixth aspect of the invention, a method of manufacturing a nitride semiconductor chip includes: a step of preparing a nitride semiconductor substrate including as a principal growth plane a plane having an off angle in an a-axis direction relative to an m plane; and a step of forming on the principal growth plane of the nitride semiconductor substrate a nitride semiconductor stacked structure having an active layer containing In by an epitaxial growth process. Here, the step of forming the nitride semiconductor stacked structure includes a step of forming a GaN layer between the nitride semiconductor substrate and the active layer, and the step of forming the GaN layer has a step of forming the GaN layer so that the GaN layer has a total thickness of 0.7 μm or less. Here, the GaN layer may have n-type conductivity, may have p-type conductivity, or may be undoped.

In the nitride semiconductor chip manufacturing method according to the sixth aspect, as described above, the GaN layer formed between the nitride semiconductor substrate and the active layer is given a total thickness of 0.7 μm or less, and this makes it possible to obtain good surface morphology. This makes it possible to give the GaN layer a uniform thickness distribution across the plane, and thus it is possible to form a GaN layer with high fatness. This in turn makes it possible to give individual semiconductor layers stacked on the GaN layer a uniform thickness distribution across the plane, and thus it is possible to enhance the flatness of the individual semiconductor layers. Moreover, by enhancing surface morphology, it is possible to reduce variations in device characteristics, and thus it is possible to increase the number of chips having characteristics within the rated ranges. This makes it possible to increase manufacturing yields. Incidentally, by enhancing surface morphology, it is also possible to further enhance device characteristics and reliability. In a case where the active layer includes a well layer, it is preferable to give the GaN layer formed between the nitride semiconductor substrate and the well layer a total thickness of 0.7 μm or less. In a case where a plurality of well layers are formed, it is preferable to give the GaN layer formed between the most substrate-side well layer and the nitride semiconductor substrate a total thickness of 0.7 μm or less.

In the above-described nitride semiconductor chip manufacturing method according to the sixth aspect, it is preferable to include a step of successively forming, on the principal growth plane of the nitride semiconductor substrate, an n-type semiconductor layer including the above-mentioned GaN layer, an active layer, and a p-type semiconductor layer. In this case, it is preferable to from the p-type semiconductor layer at a growth temperature of 700° C. or higher but 1100° C. or lower. Even in a case where the p-type semiconductor layer is formed at a high temperature of 1000° C. or higher in this way, by forming the barrier layer in the active layer out of a nitride semiconductor containing Al, it is possible to suppress blackening of the active layer (well layer). Thus, the p-type semiconductor layer can be formed at a temperature of 1000° C. or higher, and by forming the p-type semiconductor layer at high temperature, it is possible to effectively obtain an effect of reducing the driving voltage. On the other hand, by forming the p-type semiconductor layer at a growth temperature of 700° C. of higher, it is possible to suppress the inconvenience of an increased resistance in the p-type semiconductor layer due to its being formed at a growth temperature lower than 700° C. This too helps enhance device characteristics and reliability. Incidentally, by use of a nitride semiconductor substrate having a principal growth plane provided with an off angle relative to the m plane, even in a case where the p-type semiconductor layer is formed at a growth temperature lower than 900° C., it is possible to obtain p-type conductivity.

Moreover, in that case, it is preferable to form the n-type semiconductor layer at a growth temperature of 900° C. or higher but 1300° C. or lower. By forming the n-type semiconductor layer including the GaN layer with a total thickness of 0.7 μm or less at a high temperature of 900° C. or higher in this way, it is possible to give the n-type semiconductor layer a flat surface. Thus, by forming the active layer and the p-type semiconductor layer on the n-type semiconductor layer with a flat surface, it is possible to suppress degradation of crystallinity in the active layer and the p-type semiconductor layer. This makes it possible to form a high-quality crystal. On the other hand, by forming the n-type semiconductor layer at a growth temperature lower than 1300° C., it is possible to suppress the inconvenience of the surface of the nitride semiconductor substrate re-evaporating and becoming rough during the raising of temperature due to the n-type semiconductor layer being formed at a growth temperature of 1300° C. or higher. Thus, with this scheme, it is possible to manufacture, easily and at high yields, a nitride semiconductor chip with superb device characteristics and high reliability.

Furthermore, in that case, it is preferable to form the active layer at a growth temperature of 600° C. or higher but 800° C. or lower. By forming the active layer at a growth temperature of 800° C. or lower in this way, it is possible to suppress the inconvenience of the active layer being blackened by thermal damage due to the active layer being formed at a growth temperature higher than 800° C. (for example, 830° C. or higher). On the other hand, by forming the active layer at a growth temperature of 600° C. or higher, it is possible to suppress the inconvenience of a shorter atom diffusion length and hence degraded crystallinity due to the active layer being formed at a growth temperature lower than 600° C. Thus, with this scheme, it is possible to manufacture, more easily and at high yields, a nitride semiconductor chip with superb device characteristics and high reliability.

According to the fifth and sixth aspects described above, by suppressing a bright-spotted EL emission pattern, it is possible to make the EL emission pattern uniform, and thus it is possible to reduce the driving voltage of the nitride semiconductor chip. Incidentally, by suppressing bright-spotted emission, it is possible to obtain an EL emission pattern of uniform light emission, and thus it is possible to increase gain in the formation of a nitride semiconductor laser chip. Moreover, with the schemes described above, it is possible to suppress a bright-spotted EL emission pattern, and in addition it is possible to form individual nitride semiconductor layers with high flatness and thereby enhance luminous efficacy. This makes it possible to enhance device characteristics and reliability. That is, it is possible to obtain a reliable nitride semiconductor chip at high yields.

According to a seventh aspect of the invention, a semiconductor device includes a nitride semiconductor chip according to the first to fourth aspects described above.

As described above, according to the invention, it is possible to easily obtain a nitride semiconductor chip that offers enhanced luminous efficacy as a result of an improved EL emission pattern, a method of its manufacture, and a semiconductor device incorporating such a nitride semiconductor chip.

Moreover, according to the invention, it is possible to easily obtain a nitride semiconductor chip that has good surface morphology, a method of its manufacture, and a semiconductor device incorporating such a nitride semiconductor chip.

Furthermore, according to the invention, it is possible to easily obtain a nitride semiconductor chip that offers enhanced device characteristics, higher reliability, and increased yields, a method of its manufacture, and a semiconductor device incorporating such a nitride semiconductor chip.

### BRIEF DESCRIPTION OF THE DRAWINGS

FIG. 1 is a schematic diagram illustrating a crystal structure of a nitride semiconductor (a diagram showing a unit cell);

FIG. 2 is a sectional view showing a structure of a nitride semiconductor laser chip according to Embodiment 1 of the invention (a view corresponding to the section along line A-A in FIG. 6);

FIG. 3 is an overall perspective view of a nitride semiconductor laser chip according to Embodiment 1 of the invention;

FIG. 4 is a schematic diagram illustrating an off angle of a substrate;

FIG. 5 is a sectional view showing a structure of an active layer in a nitride semiconductor laser chip according to Embodiment 1 of the invention;

FIG. 6 is a plan view of a nitride semiconductor laser chip according to Embodiment 1 of the invention (a diagram showing the nitride semiconductor laser chip as seen from above);

FIG. 7 is a perspective view illustrating a method of manufacture of a nitride semiconductor laser chip according to Embodiment 1 of the invention (a diagram illustrating a method of manufacture of a substrate);

FIG. 8 is a perspective view illustrating a method of manufacture of a nitride semiconductor laser chip according to Embodiment 1 of the invention (a diagram illustrating a method of manufacture of a substrate);

FIG. 9 is a perspective view illustrating a method of manufacture of a nitride semiconductor laser chip according to Embodiment 1 of the invention (a diagram illustrating a method of manufacture of a substrate);

FIG. 10 is a plan view illustrating a method of manufacture of a nitride semiconductor laser chip according to Embodiment 1 of the invention (a diagram illustrating a method of manufacture of a substrate);

FIG. 11 is a sectional view illustrating a method of manufacture of a nitride semiconductor laser chip according to Embodiment 1 of the invention (a diagram illustrating a method of manufacture of a substrate);

FIG. 12 is a sectional view illustrating a method of manufacture of a nitride semiconductor laser chip according to Embodiment 1 of the invention;

FIG. 13 is a sectional view illustrating a method of manufacture of a nitride semiconductor laser chip according to Embodiment 1 of the invention;

FIG. 14 is a sectional view illustrating a method of manufacture of a nitride semiconductor laser chip according to Embodiment 1 of the invention;

FIG. 15 is a sectional view illustrating a method of manufacture of a nitride semiconductor laser chip according to Embodiment 1 of the invention;

FIG. 16 is a sectional view illustrating a method of manufacture, of a nitride semiconductor laser chip according to Embodiment 1 of the invention;

FIG. 17 is a sectional view illustrating a method of manufacture of a nitride semiconductor laser chip according to Embodiment 1 of the invention;

FIG. 18 is a sectional view illustrating a method of manufacture of a nitride semiconductor laser chip according to Embodiment 1 of the invention;

FIG. 19 is a sectional view illustrating a method of manufacture of a nitride semiconductor laser chip according to Embodiment 1 of the invention;

FIG. 20 is a perspective view of a semiconductor laser device incorporating a nitride semiconductor laser chip according to Embodiment 1 of the invention;

FIG. 21 is a perspective view of a light-emitting diode chip fabricated to verify the effects of a nitride semiconductor laser chip according to Embodiment 1 of the invention;

FIG. 22 is a microscope photograph of an EL emission pattern observed with a light-emitting diode chip fabricated to verify the effects of a nitride semiconductor laser chip according to Embodiment 1 of the invention (a microscope photograph of an EL emission pattern observed with a test chip);

FIG. 23 is a sectional view showing a structure of a nitride semiconductor laser chip according to Embodiment 2 of the invention (a view corresponding to the section along line A-A in FIG. 26);

FIG. 24 is an overall perspective view of a nitride semiconductor laser chip according to Embodiment 2 of the invention;

FIG. 25 is a sectional view showing a structure of an active layer in a nitride semiconductor laser chip according to Embodiment 2 of the invention;

FIG. 26 is a plan view of a nitride semiconductor laser chip according to Embodiment 2 of the invention (a diagram showing the nitride semiconductor laser chip as seen from above);

FIG. 27 is a sectional view illustrating a method of manufacture of a nitride semiconductor laser chip according to Embodiment 2 of the invention;

FIG. 28 is a sectional view illustrating a method of manufacture of a nitride semiconductor laser chip according to Embodiment 2 of the invention;

FIG. 29 is a sectional view illustrating a method of manufacture of a nitride semiconductor laser chip according to Embodiment 2 of the invention;

FIG. 30 is a sectional view illustrating a method of manufacture of a nitride semiconductor laser chip according to Embodiment 2 of the invention;

FIG. 31 is a sectional view illustrating a method of manufacture of a nitride semiconductor laser chip according to Embodiment 2 of the invention;

FIG. 32 is a sectional view illustrating a method of manufacture of a nitride semiconductor laser chip according to Embodiment 2 of the invention;

FIG. 33 is a sectional view illustrating a method of manufacture of a nitride semiconductor laser chip according to Embodiment 2 of the invention;

FIG. 34 is a sectional view illustrating a method of manufacture of a nitride semiconductor laser chip according to Embodiment 2 of the invention;

FIG. 35 is a perspective view of a semiconductor laser device incorporating a nitride semiconductor laser chip according to Embodiment 2 of the invention;

FIG. 36 is a perspective view of a light-emitting diode chip fabricated to verify the effects of a nitride semiconductor laser chip according to Embodiment 2 of the invention;

FIG. 37 is a microscope photograph showing a bright-spotted EL emission pattern (a microscope photograph of an EL emission pattern observed with a comparison chip in connection with Embodiment 2);

FIG. 38 is a sectional view illustrating another example of a structure of an active layer in Embodiments 1 and 2 (a sectional view showing an example of an active layer having an SQW structure);

FIG. 39 is a microscope photograph obtained when, by use of a GaN substrate having as a principal growth plane a plane having an off angle in the a-axis direction relative to the m plane, a GaN layer with a thickness of about 1 μm was formed on that principal growth plane and surface morphology was inspected under an optical microscope;

FIG. 40 is a microscope photograph obtained when, by use of a GaN substrate having as a principal growth plane a plane having an off angle in the a-axis direction relative to the m plane, a GaN layer with a thickness of about 0.1 μm was formed on that principal growth plane, then an AlGaN layer with a thickness of about 0.9 μm was formed on this GaN layer, and then surface morphology was inspected under an optical microscope;

FIG. 41 is a microscope photograph obtained when, by use of a GaN substrate having as a principal growth plane a plane having an off angle in the a-axis direction relative to the m plane, an AlGaN layer with a thickness of about 0.2 μm was formed on that principal growth plane, then a GaN layer with a thickness of about 0.9 μm was formed on this AlGaN layer, and then surface morphology was inspected under an optical microscope;

FIG. 42 is a microscope photograph obtained when, by use of a GaN substrate having as a principal growth plane a plane having an off angle in the a-axis direction relative to the m plane, an AlGaN layer with an Al composition ratio of 5% and with a thickness of about 2 μm was formed on that principal growth plane and surface morphology was inspected under an optical microscope;

FIG. 43 is a microscope photograph obtained when, by use of a GaN substrate having as a principal growth plane a plane having an off angle of +0.5 degrees in the c-axis direction relative to the m plane, an AlGaN layer with a thickness of about 1 μm was formed on that principal growth plane and surface morphology was inspected under an optical microscope;

FIG. 44 is a microscope photograph obtained when, by use of a GaN substrate having as a principal growth plane a plane having an off angle of +0.5 degrees in the c-axis direction relative to the m plane, a GaN layer with a thickness of about 1 μm was formed on that principal growth plane and surface morphology was inspected under an optical microscope;

FIG. 45 is a microscope photograph of dark lines observed in an EL emission pattern;

FIG. 46 is a microscope photograph of dark lines observed in an PL emission pattern;

FIG. 47 is a microscope photograph of a PL emission pattern of a light-emitting diode chip having a barrier layer formed of AlGaN; and

FIG. 48 is a microscope photograph showing a bright-spotted EL emission pattern (a microscope photograph of an EL emission pattern observed with a comparison chip in connection with Embodiment 1).

### DETAILED DESCRIPTION OF PREFERRED EMBODIMENTS

Prior to the description of specific embodiments of the present invention, what the inventors have found out through various studies will be explained.

As described previously, the inventors have found out that, by using as the principal growth plane of a nitride semiconductor substrate a plane having an off angle in the a-axis direction relative to the m plane, it is possible to suppress a bright-spotted EL emission pattern.

On the other hand, when, by use of a nitride semiconductor substrate having as the principal growth plane a plane having an off angle in the a-axis direction relative to the m plane, the inventors formed a GaN layer with a thickness of about 1 μm on that principal growth plane, it was found out that the thickness distribution across the plane was very poor. The thickness distribution then was very poor even in comparison with that obtained when a GaN layer with a thickness of about 1 μm was formed on an m-plane GaN substrate having no off angle in the a-axis direction. This phenomenon of a large thickness distribution across the plane occurring when a GaN layer with a thickness of about 1 μm is formed on a principal growth plane having an off angle in the a-axis direction relative to the m plane is considered to be a very peculiar one.

FIG. 39 is a microscope photograph obtained when, by use of a GaN substrate having as the principal growth plane a plane having an off angle in the a-axis direction relative to the m plane, a GaN layer with a thickness of about 1 μm was formed on that principal growth plane and the surface morphology was inspected under an optical microscope. FIG. 39 shows the surface morphology as observed with individual nitride semiconductor layers stacked on the principal growth plane starting with the GaN layer. As shown in FIG. 39, on the surface of the semiconductor layers, very distinct wave-form surface irregularities are observed in the direction parallel to the a-axis direction. Moreover, the nitride semiconductor layers shown in FIG. 39 have a thickness distribution of about 200 to 400 nm, and with nitride semiconductor layers with such a poorly uniform thickness distribution, it is extremely difficult to form a chip.

Conventionally, it is common practice to form, first, a semiconductor layer of the same composition as a substrate in contact with the surface (principal growth plane) of the substrate with a view to enhancing the flatness at the layer surface and the crystallinity of the semiconductor layer, and then form a chip on top. For example, with a GaN substrate, first, a GaN layer is formed on the substrate. This makes the composition of the substrate the same as that of the semiconductor layer (GaN layer) formed on the substrate surface (principal growth plane), eliminating differences in lattice constant, thermal expansion coefficient, etc., and thus suppressing development of strain. It is known that, by doing so, it is possible to form a semiconductor layer with high flatness and good crystallinity. In fact, it is common to do so in cases where, by use of a nitride semiconductor substrate having the c plane as the principal growth plane (for example, a c-plane GaN substrate), crystal growth is performed on that principal growth plane. In such cases (where a GaN layer is formed on a c-plane GaN substrate), very good surface morphology is obtained, and this is considered to be the normal phenomenon.

It was, however, recently found out for the first time that, with a nitride semiconductor substrate having as the principal growth plane a plane having an off angle in the a-axis direction relative to the m plane, applying the above-described structure rather degrades surface morphology.

Through intensive studies, the inventors have found out that the degradation of surface morphology is associated with the thickness of the GaN layer. Specifically, through the studies, it has been found out that, with a nitride semiconductor substrate having as the principal growth plane a plane having an off angle in the a-axis direction relative to the m plane, forming a thick film of GaN with a thickness of about 1 μm greatly degrades surface morphology, resulting in peculiar surface morphology as shown in FIG. 39.

The inventors have also found out that, the greater the total thickness of the GaN layer formed on the principal growth plane, the poorer the surface morphology. It should be noted that the total thickness here denotes, in a case where a single GaN layer is formed, the thickness of this GaN layer and, in a case where a plurality of GaN layers are formed, (the sum of) their thicknesses added up. Accordingly, forming a thick GaN layer before forming an active layer degrades surface morphology, and forming the active layer on the surface of the layer with such degraded surface morphology causes the active layer, under the influence of the degraded surface morphology, to divide into high-In-composition and low-In-composition regions across the plane. This, it has been found out, results in an across-the-plane distribution of composition. It has also been found out that, maybe not only because of the across-the-plane distribution of the active layer's composition but also because of degradation in the active layer's crystallinity, luminous intensity also lowers.

Through further studies based on the above findings, the inventors have found out that, by giving the GaN layer formed between the substrate and the active layer a total thickness of 0.7 μm or less, it is possible to dramatically improve surface morphology. It has also been found out that it is preferable that the total thickness of the GaN layer formed between the substrate and the active layer be 0.5 μm or less, and more preferably 0.3 μm or less.

It has further been revealed that, in a case where a nitride semiconductor chip is formed by use of a nitride semiconductor substrate having as the principal growth plane a plane having an off angle in the a-axis direction relative to the m plane, it is preferable to form no GaN layer at all or, if any, as little of a GaN layer as possible before forming an active layer.

As described above, by forming nitride semiconductor layers in such a way as to satisfy the above-mentioned condition that the total thickness of the GaN layer be 0.7 μm or less, it is possible to improve surface morphology and make the layer surface flat. Then, by forming an active layer (a well layer which is a nitride semiconductor layer containing In) on that flat layer surface, it is possible to suppress an across-the-plane distribution of In composition, and thereby to improve luminous efficacy.

From the viewpoint of improving luminous efficacy, it is preferable to give the GaN layer formed between the substrate and the well layer, which is a nitride semiconductor layer containing In, a total thickness of 0.7 μm or less. For example, in a case where the active layer includes a GaN layer as a barrier layer, it is preferable that the GaN layer including any barrier layer located on the substrate side of the well layer be given a thickness of 0.7 μm or less. In a case where a plurality of well layers are formed, the GaN layer formed between the most substrate-side well layer and the nitride semiconductor substrate may be given a total thickness of 0.7 μm or less, or the GaN layer formed between any other well layer and the nitride semiconductor substrate may be given a total thickness of 0.7 μm or less.

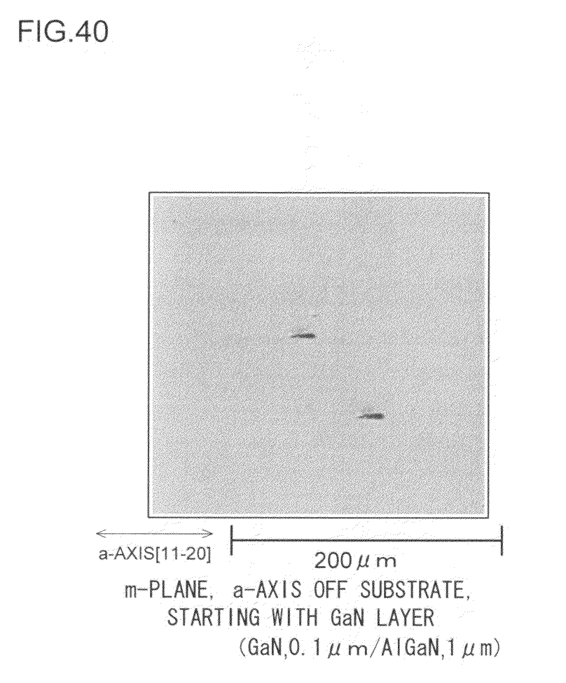

FIG. 40 is a microscope photograph obtained when, by use of a GaN substrate having as the principal growth plane a plane having an off angle in the a-axis direction relative to the m plane, a GaN layer with a thickness of about 0.1 μm was formed on that principal growth plane, then an AlGaN layer with a thickness of about 0.9 μm was formed on this GaN layer, and then the surface morphology was inspected under an optical microscope. FIG. 40 shows the surface morphology as observed with individual nitride semiconductor layers stacked on the principal growth plane starting with the GaN layer. The AlGaN layer had the composition Al_{0.05}Ga_{0.95}N. Moreover, in FIG. 40, the GaN and AlGaN layers are given a total thickness of about 1 μm so that the total thickness of the GaN and AlGaN layers is equal to the thickness of the GaN layer in FIG. 39. Specifically, in FIG. 40, instead of a GaN layer with a thickness of about 1 μm, there are formed a GaN layer with a thickness of about 0.1 μm and an AlGaN layer with a thickness of about 0.9 μm.

As shown in FIG. 40, forming a GaN layer with a thickness of about 0.1 μm gives very good surface morphology, and it is seen that the resulting flatness on the layer surface is greatly enhanced compared with that in the case shown in FIG. 39 where a GaN layer with a thickness of about 1 μm is formed. In this way, the thicker the GaN layer, the poorer the surface morphology. By contrast, a thin GaN layer suppresses degradation of surface morphology. It has also been found out that, once a thick film of GaN is formed and surface morphology degrades, forming an AlGaN layer thereafter does not help much improve the degraded surface morphology, with surface morphology becoming poorer as the number of semiconductor layers stacked increases.

Through the studies this time, it has also been found out that, in a case where use is made of a nitride semiconductor substrate having as the principal growth plane a plane having an off angle in the a-axis direction relative to the m plane, it is preferable that the semiconductor layer in contact with the principal growth plane be formed of In_{y}Ga_{1-y}N (0<y≦1), AlₓGa₁₋ₓN (0<x≦1), or AlₐIn_{b}Ga_{c}N (a+b+c=1).

With In_{y}Ga_{1-y}N (0<y≦1), as conditions for keeping better surface morphology, it is more preferable that 0<y≦0.1, and it is preferable that the layer in contact with the principal growth plane of the nitride semiconductor substrate have a thickness of 0.7 μm or less. In a case where the semiconductor in contact with the principal growth plane is InGaN, film formation is performed at a low temperature of about 700° C. to 900° C. In a case where use is made of a nitride semiconductor substrate having as the principal growth plane a plane having an off angle in the a-axis direction relative to the m plane, if, during heating of the substrate prior to film formation, the temperature is raised to above about 1100° C., depending on the atmosphere inside the furnace (the conditions such as gas flow amount, pressure, etc.), N (nitrogen) or Ga (gallium) may evaporate from the substrate surface before growth, causing asperity on the substrate surface. It has been found out that this asperity does not occur at a substrate temperature of 900° C. or less. For this reason, it is preferable to use InGaN, which allows film formation at low temperature (about 700° C. to 900° C.) and thus helps effectively suppress asperity on the substrate surface.

Likewise, AlₐIn_{b}Ga_{c}N (a+b+c=1, 0<a≦1, 0<b≦1, 0≦c<1), when it contains In, allows low-temperature film formation, and thus offers similar effects to InGaN. Also in this case, it is preferable that the layer in contact with the principal growth plane of the substrate have a thickness of 0.7 μm or less, and from the viewpoint of surface morphology, it is more preferable that the Al composition ratio “a” be 0<a≦0.1 and in addition the In composition ratio “b” be 0<b≦0.1. That is, it is preferable to use a nitride semiconductor layer containing Al and In as the semiconductor layer in contact with the principal growth plane, because doing so makes it easy to form a film with high flatness by growth at low temperature.

Also in this case, it is preferable to give the GaN layer formed between the substrate and the active layer (well layer) a total thickness of 0.7 μm or less.

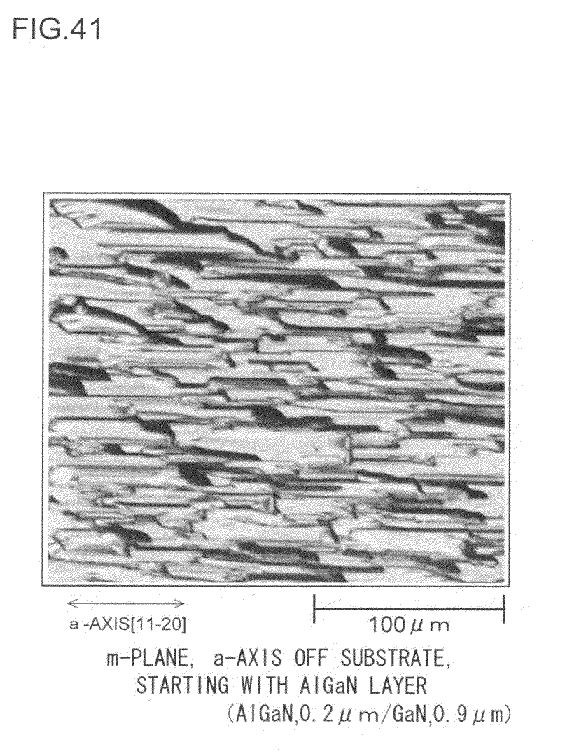

FIG. 41 is a microscope photograph obtained when, by use of a GaN substrate having as the principal growth plane a plane having an off angle in the a-axis direction relative to the m plane, an AlGaN layer with a thickness of about 0.2 μm was formed on that principal growth plane, then a GaN layer with a thickness of about 0.9 μm was formed on this AlGaN layer, and then the surface morphology was inspected under an optical microscope. FIG. 41 shows the surface morphology as observed with individual nitride semiconductor layers stacked on the principal growth plane starting with the AlGaN layer. The AlGaN layer had the composition Al_{0.05}Ga_{0.95}N.

Using an AlGaN layer as the semiconductor layer in contact with the principal growth plane gives the AlGaN layer good surface morphology. However, forming a GaN layer with a thickness of over 0.7 μm, for example about 0.9 μm, degrades surface morphology as shown in FIG. 41. That is, it has been found out that, even when an AlGaN (Al_{0.05}Ga_{0.95}N layer) with a thickness of about 0.2 μm is formed between the substrate and the GaN layer, if the GaN layer is thick, surface morphology degrades.

It has also been found out that, in a case where an AlGaN layer or the like is formed between a plurality of GaN layers (for example, in a four-layer structure of GaN/AlGaN/GaN/AlGaN layers), giving the GaN layer a total thickness more than 0.7 μm degrades surface morphology. For example, when a GaN layer with a thickness of about 1 μm was formed on the principal growth plane of the substrate and then an AlGaN layer (for example (Al_{0.05}Ga_{0.95}N layer) with a thickness of about 1 μm was formed, the surface morphology degraded as a result of the GaN layer being formed did not recover, resulting in surface morphology similar to that shown in FIG. 39.

Thus, through the studies, it has been found out that the total thickness of the GaN layer formed on the substrate (between the substrate and the active layer (well layer)) ultimately determines surface morphology, and thus that it is necessary to suppress the GaN layer having too great a total thickness before the formation of the active layer (well layer which is a nitride semiconductor layer containing In).

In a case where use is made of a nitride semiconductor substrate having as the principal growth plane a plane having an off angle in the a-axis direction relative to the m plane, it is preferable to form the layered structure stacked on the substrate (the layered structure of the light-emitting chip) in such a way that the structure contains as little of a GaN layer as possible; it is, however, also possible to use a GaN layer as an optical guide layer for light confinement or the like. It is also possible to form a very thin GaN layer into a super-lattice with AlGaN, AlInGaN, or InGaN (AlGaN/GaN/AlGaN/GaN . . . , AlInGaN/GaN/AlInGaN/GaN . . . , InGaN/GaN/InGaN/GaN . . . , etc.), thereby to increase the total GaN layer thickness while suppressing degradation of surface morphology. This super-lattice structure can then be used as an optical guide layer or an optical clad layer. Using the above structure makes it possible to form a comparatively good layer by use of a thin-film GaN layer. When a thin-film GaN layer is used in a super-lattice structure in such a case, it is particularly preferable that its thickness be 1 nm or more but 50 nm or less. Even in that case, it is necessary to suppress the total thickness of the GaN layer formed between the substrate and the active layer (well layer) to 0.7 μm or less.

To obtain a light-emitting chip or electronic device with superior characteristics, it is preferable, as described above, that the layered structure stacked on the substrate not include a GaN layer and that the layered structure be composed of semiconductor layers of compositions different from GaN, such as InGaN, AlGaN, InAlGaN, InAlN, etc. In a case where a light-emitting chip is formed, for the purpose of light confinement or the like, a GaN layer may be used as an optical guide layer; a GaN layer may also be used as a contact layer or the like.

Through the studies this time, it has also been found out that when a nitride semiconductor layer containing Al or In (for example, an AlGaN layer, an InGaN layer, an AlInGaN layer, an AlInN layer, or the like) is formed even with a thickness over 1 μm, unlike a GaN layer, deterioration of surface morphology is suppressed. Accordingly, in a case where a LD structure is fabricated by use of a nitride semiconductor substrate having as the principal growth plane a plane having an off angle in the a-axis direction relative to the m plane, it is preferable to use as an optical clad layer a nitride semiconductor layer containing Al, such as an AlGaN layer, an AlInGaN layer, an AlInN layer, or the like). Alternatively, it is preferable to use a nitride semiconductor layer containing Al and In. Moreover, it is preferable to use as an optical guide layer a nitride semiconductor layer containing In, such as an InGaN layer, an AlInGaN layer, an AlInN layer, or the like.

In a case where a nitride semiconductor substrate with a non-polar plane is used, or in a case where a nitride semiconductor layer containing Al or a nitride semiconductor layer containing Al and In is used as a barrier layer in an active layer, it is preferable, for the purposes of, among others, mitigating strain in the active layer and suppressing development of dark lines, to use as an optical clad layer a nitride semiconductor layer containing Al and In, such as an AlInGaN layer, an AlInN layer, or the like. Moreover, it is preferable to use as an optical guide layer a nitride semiconductor layer containing In or a nitride semiconductor layer containing Al and In, such as an InGaN layer, an AlInGaN layer, an AlInN layer, or the like. Needless to say, similar considerations apply in a case where use is made of a nitride semiconductor substrate having as the principal growth plane a plane having an off angle in the a-axis direction relative to the m plane.

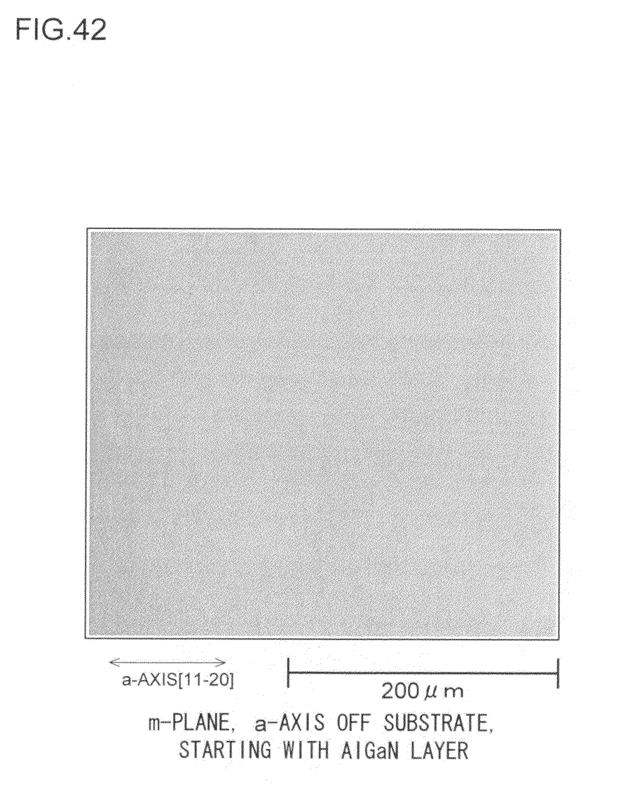

FIG. 42 is a microscope photograph obtained when, by use of a GaN substrate having as the principal growth plane a plane having an off angle in the a-axis direction relative to the m plane, an AlGaN layer with an Al composition ratio of 5% and with a thickness of about 2 μm was formed on that principal growth plane and the surface morphology was inspected under an optical microscope. FIG. 42 shows the surface morphology as observed with individual nitride semiconductor layers stacked on the principal growth plane starting with the AlGaN layer. As shown in FIG. 42, the surface morphology obtained when a nitride semiconductor layer containing Al is formed as a thick film is very good, and it is seen that the resulting flatness on the layer surface is greatly enhanced compared with that obtained when the nitride semiconductor layers are stacked starting with a GaN layer as shown in FIG. 39. It is considered that using an AlGaN layer as the semiconductor layer in contact with the substrate surface (principal growth plane) changes its growth mode in such a way as to enhance flatness and crystallinity. Thus, it has been found out that, even when a nitride semiconductor layer containing Al or In is formed as a thick film, degradation of surface morphology is suppressed.

Using as the semiconductor layer in contact with the substrate surface (principal growth plane) a nitride semiconductor layer containing Al (for example, an AlGaN layer) instead of a GaN layer containing no Al as described above brings about a marked enhancement in surface morphology. This phenomenon is peculiar to cases where use is made of a nitride semiconductor substrate having as the principal growth plane a plane having an off angle in the a-axis direction relative to the m plane; no report whatsoever has to this date been made of the phenomenon, which thus came to light for the first time through the inventors' studies this time.

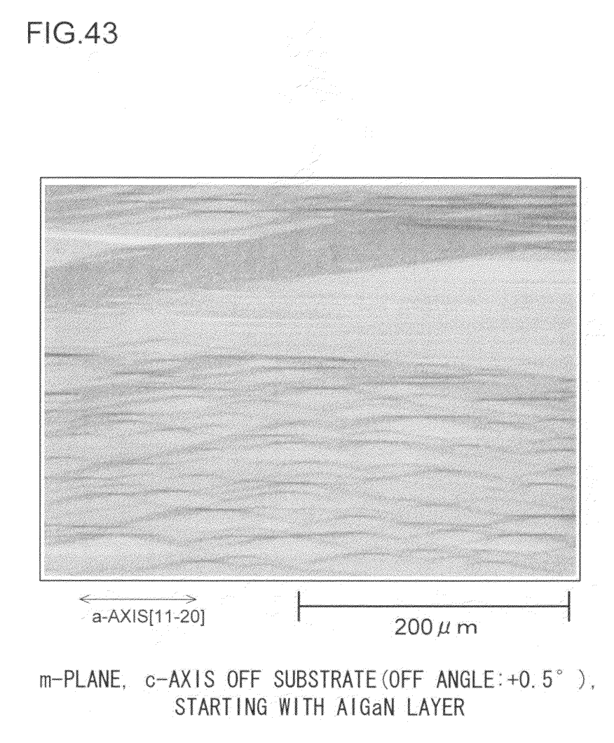

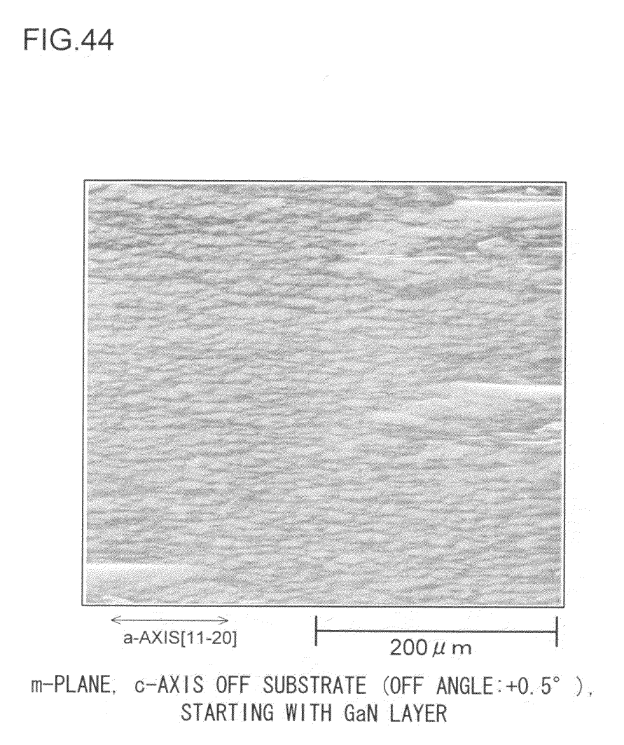

For comparison, FIG. 43 is a microscope photograph obtained when, by use of a GaN substrate having as the principal growth plane a plane having an off angle of +0.5 degrees in the c-axis direction relative to the m plane, an AlGaN layer with a thickness of about 1 μm was formed on that principal growth plane and the surface morphology was inspected under an optical microscope; FIG. 44 is a microscope photograph obtained when, by use of a GaN substrate having as the principal growth plane a plane having an off angle of +0.5 degrees in the c-axis direction relative to the m plane, a GaN layer with a thickness of about 1 μm was formed on that principal growth plane and the surface morphology was inspected under an optical microscope. FIG. 43 shows the surface morphology as observed with individual nitride semiconductor layers stacked on the principal growth plane starting with the AlGaN layer, and FIG. 44 shows the surface morphology as observed with individual nitride semiconductor layers stacked on the principal growth plane starting with the GaN layer.

As shown in FIGS. 43 and 44, surface morphology was poor in both cases, with no notable difference observed between them. In this way, there usually arises no notable difference in surface morphology between when a GaN layer is formed (semiconductor layers are stacked starting with a GaN layer) and when an AlGaN layer is formed (semiconductor layers are stacked starting with an AlGaN layer). Thus, it has been found out that the above-mentioned phenomenon is peculiar to a nitride semiconductor substrate having as the principal growth plane a plane having an off angle in the a-axis direction relative to the m plane.

Based on the foregoing, in a case where a GaN layer is formed on a nitride semiconductor substrate having as the principal growth plane a plane having an off angle in the a-axis direction relative to the m plane, it is preferable that the total thickness of the GaN layer formed between the substrate surface (principal growth plane) and the active layer (the well layer which is a nitride semiconductor layer containing In) be 0.7 μm or less, and more preferably 0.5 μm or less; it is still more preferable that the total GaN layer thickness be 0.3 μm or less. With a total GaN layer thickness of 0.5 μm or less, no significant degradation of surface morphology occurs. Thus, it is possible, as by thereafter forming an AlGaN layer, to form a plurality of GaN layers on the substrate. Even then, however, it is still necessary to fulfill the condition that the total thickness of the GaN layer formed between the substrate surface (principal growth plane) and the active layer (well layer) be 0.7 μm or less.

Even when the layered structure stacked on the substrate is formed not to include a GaN layer but out of semiconductor layers of compositions different from GaN, such as InGaN, AlGaN, InAlGaN, InAlN, etc., it is possible to form a light-emitting chip or electronic device with superb characteristics.

Through the studies described above, the inventors have also found out that, by forming a barrier layer in an active layer out of a nitride semiconductor containing Al (for example, AlGaN, AlInGaN, AlInN, etc.), it is possible to enhance luminous efficacy.

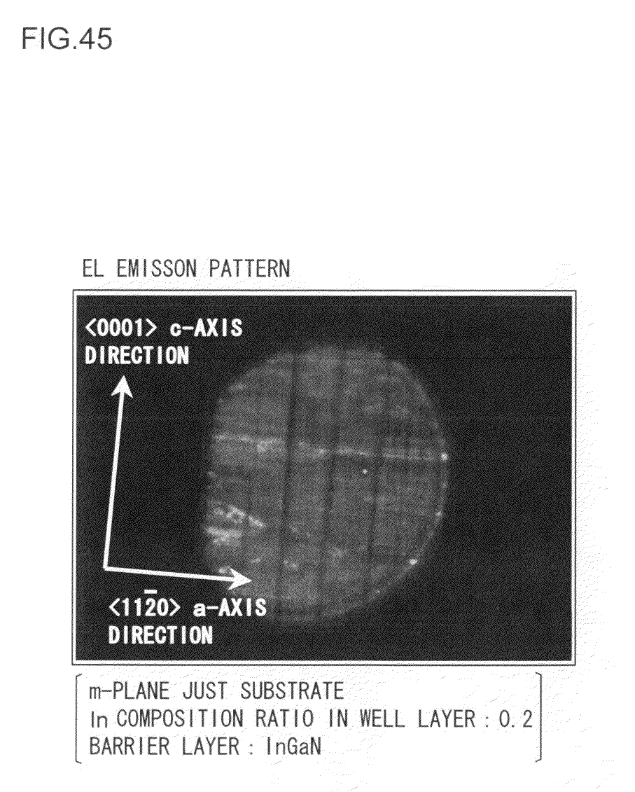

Through the studies described above, the inventors have further ascertained that, as the In composition ratio in the active layer increases, dark lines as shown in FIG. 45 may develop in the EL emission pattern of a nitride semiconductor light-emitting chip.

Such dark lines are observed not only in an EL emission pattern but also in a PL emission pattern (the light distribution across the plane as observed when light is emitted by photoexcitation). Development of dark lines is undesirable, because they lowers the luminous efficacy of a chip. The dark lines that develop with an increased In composition in the active layer run in the direction parallel to the c-axis direction of the m plane. Dark lines are considered to be defects such as misfit dislocations which result from differences in lattice constant and thermal expansion coefficient between GaN in the substrate or elsewhere and an InGaN layer in the active layer. With the c plane (0001), which has conventionally been used widely, or the like, no such dark lines develop even with increased In. Thus, development of dark lines is considered to be a phenomenon peculiar to nitride semiconductor light-emitting chips using a nitride semiconductor substrate having a non-polar plane, in particular the m plane, as the principal growth plane.

As described above, in a nitride semiconductor light-emitting chip using a nitride semiconductor substrate having the m plane as the principal growth plane, as distinct from a nitride semiconductor light-emitting chip using the c plane, whereas lowering of luminous efficacy due to spontaneous polarization and piezoelectric polarization is suppressed, there is the problem, it has been found out, that development of dark lines causes chronic degradation of luminous efficacy. Development of such dark lines poses, in a nitride semiconductor light-emitting chip using the m plane, a great problem because it hampers the lengthening of the emission wavelength. In particular, in semiconductor laser chips, low luminous efficacy is a serious problem because it leads to low gain.

Bright-spotted emission can be observed in an EL emission pattern, but cannot be observed distinctly in a PL emission pattern. Thus, bright-spotted emission is considered to be caused by a phenomenon arising from non-uniform current injection. It is observed particularly distinctly when the amount of injected current is small, for example, as current is gradually increased, when the current injection density is in the range between a level at which light emission starts and, in a case where the p-side electrode has a diameter of about 20 μm, about 50 mA. Even in a large-current region, bright-spotted emission is undesirable because it suppresses luminous efficacy.

In contrast, dark lines are observed distinctly both in a PL emission pattern and in an EL emission pattern. Thus, it has been found out that bright-spotted emission and dark lines have different causes, and occur by different mechanisms.

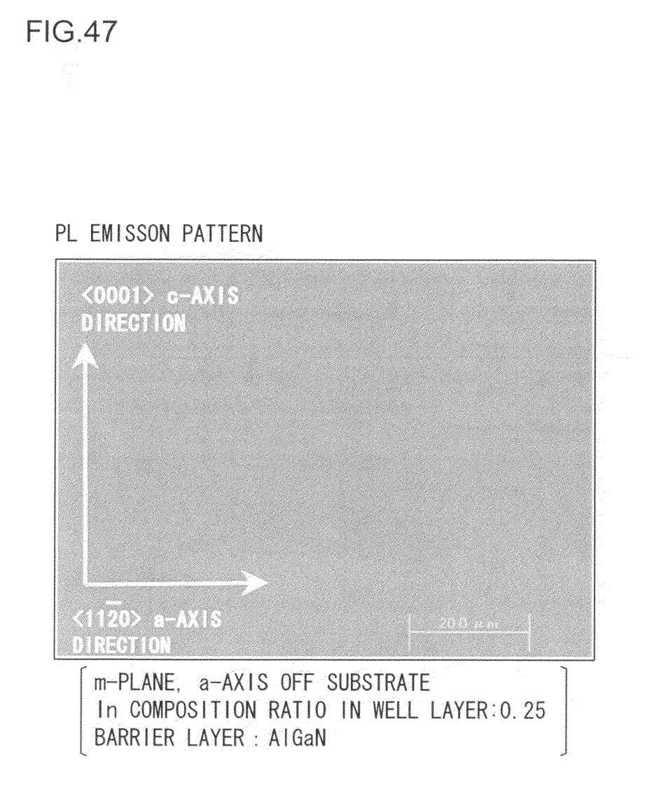

Through intensive studies based on the above findings, the inventors have found out that, by forming a barrier layer in an active layer out of a nitride semiconductor containing Al (for example, AlGaN, AlInGaN, AlInN, etc.), it is possible to suppress development of dark lines as well. That is, it has been found out that, by forming a barrier layer out of a nitride semiconductor containing Al, it is possible to almost completely suppress development of dark lines as shown in FIG. 47.

FIG. 45 referred to above is a microscope photograph of dark lines observed in an EL emission pattern, and the EL emission pattern in FIG. 45 is that of a light-emitting diode chip fabricated by use of a GaN substrate having the m plane as the principal growth plane (a m-plane just substrate). This light-emitting diode chip has a well layer formed of In_{0.2}Ga_{0.8}N and a barrier layer formed of In_{0.02}Ga_{0.98}N.

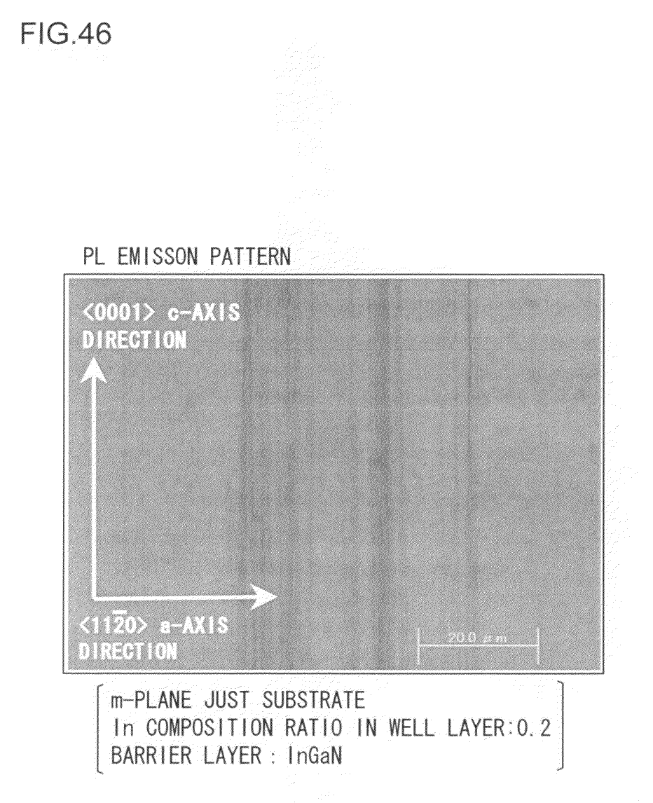

FIG. 46 referred to above is a microscope photograph of dark lines observed in a PL emission pattern, and the PL emission pattern in FIG. 46 is that of a light-emitting diode chip fabricated by use of a GaN substrate having the m plane as the principal growth plane (a m-plane just substrate). This light-emitting diode chip has a well layer formed of In_{0.2}Ga_{0.8}N and a barrier layer formed of In_{0.02}Ga_{0.98}N.

FIG. 47 is a microscope photograph of a PL emission pattern of a light-emitting diode chip having a barrier layer formed of AlGaN. This light-emitting diode chip has a well layer formed of In_{0.25}Ga_{0.75}N and has the barrier layer formed of Al_{0.01}Ga_{0.99}N. Used as a nitride semiconductor substrate here is an m-plane, a-axis off substrate (with an off angle of 1.7 degrees in the a-axis direction, and with an off angle of +0.1 degrees in the c-axis direction).

Hereinafter, specific embodiments of the present invention will be described in detail with reference to the accompanying drawings. The embodiments presented below deal with cases where the invention is applied to a nitride semiconductor laser chip as one example of a nitride semiconductor chip. In the following embodiments, a “nitride semiconductor” denotes a semiconductor of the composition AlₓGa_{y}In_{z}N (where 0≦x≦1, 0≦y≦1, 0≦z≦1, and x+y+z=1).

### Embodiment 1

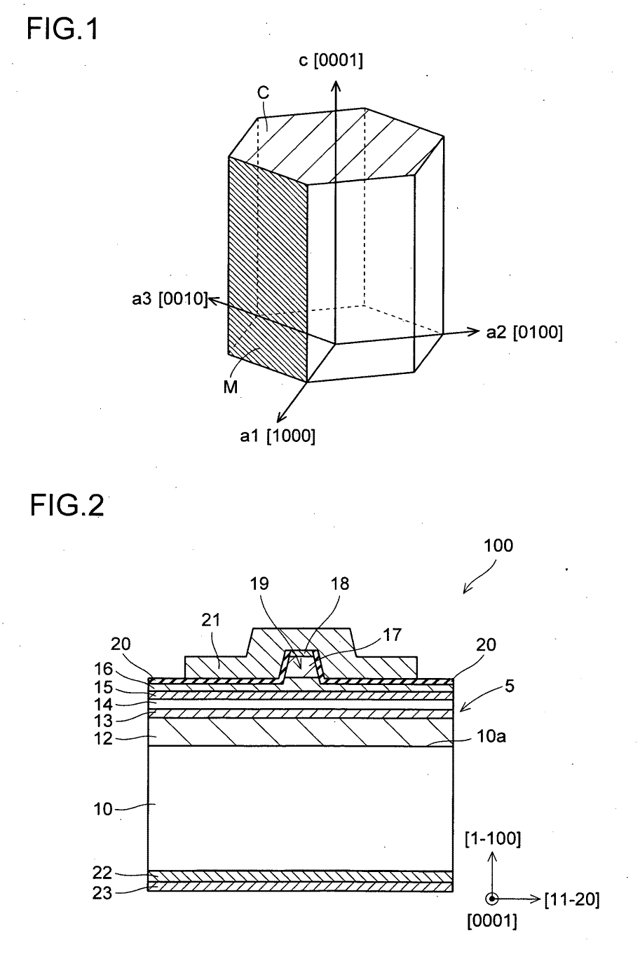

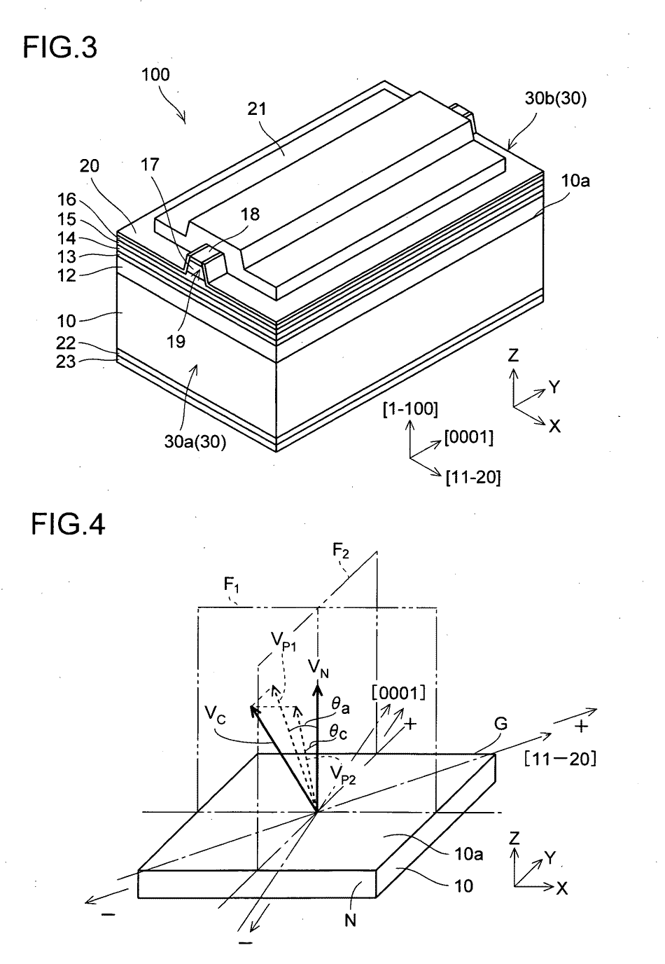

FIG. 1 is a schematic diagram illustrating a crystal structure of a nitride semiconductor. FIG. 2 is a sectional view showing the structure of a nitride semiconductor laser chip according to a first embodiment (Embodiment 1) of the invention. FIG. 3 is an overall perspective view of a nitride semiconductor laser chip according to Embodiment 1 of the invention. FIGS. 4 to 6 are diagrams illustrating the structure of a nitride semiconductor laser chip according to Embodiment 1 of the invention. First, with reference to FIGS. 1 to 6, the structure of a nitride semiconductor laser chip 100 according to Embodiment 1 of the invention will be described.

The nitride semiconductor laser chip 100 according to Embodiment 1 is formed of a nitride semiconductor having a crystal structure of a hexagonal crystal system as shown in FIG. 1. In this crystal structure, when the hexagonal crystal system is considered to be a hexagonal column about a c axis [0001], the plane (the top face C of the hexagonal column) to which the c axis is normal is called the c plane (0001), and any of the side wall faces M of the hexagonal column is called the m plane {1-100}. In a nitride semiconductor, no plane of symmetry exists in the c-axis direction, and therefore a direction of polarization rims along the c-axis direction. Thus, the c plane exhibits different properties between the +c axis side and the −c axis side. Specifically, the +c plane (the (0001) plane, a Ga polar plane G) and the −c plane (the (000-1) plane, a N polar plane N) are not equivalent planes, and have different chemical properties. On the other hand, the m plane is a crystal plane perpendicular to the c plane, and therefore a normal to the m plane is perpendicular to the direction of polarization. Thus, the m plane is a non-polar plane, that is, a plane having no polarity. Since, as described above, the side wall faces of the hexagonal column are each the m plane, the m plane can be represented by six plane orientations, namely (1-100), (10-10), (01-10), (−1100), (−1010), and (0-110); these plane orientations are equivalent in terms of crystal geometry, and are therefore collectively represented by {1-100}.

As shown in FIGS. 2 and 3, the nitride semiconductor laser chip 100 according to Embodiment 1 is provided with a GaN substrate 10 as a nitride semiconductor substrate. The principal growth plane 10a of the GaN substrate 10 is a plane having an off-angle relative to the m plane. Specifically, the GaN substrate 10 of the nitride semiconductor laser chip 100 has an off-angle in the a-axis direction (the [11-20] direction) relative to the m plane. The GaN substrate 10 may have, in addition to the off-angle in the a-axis direction, an off-angle in the c-axis direction (the [0001] direction) as well.

Now, with reference to FIG. 4, the off-angle of the GaN substrate 10 will be described in more detail. First, with respect to the m plane, two crystal axis directions are defined, namely the a-axis [11-20] direction and the c-axis [0001] direction. These axes, namely the a and c axes, are perpendicular to each other, and in addition are both perpendicular to the m axis. Moreover, the directions that are parallel to the a-, c-, and m-axis directions when the crystal axis vector (the m axis [1-100]) V_{C} of the GaN substrate 10 coincides with the normal vector V_{N} of the substrate surface (principal growth plane 10a) (that is, when the off-angle is 0 in all directions) are taken as the X, Y, and Z directions respectively. Next, a first plane F₁ a normal to which runs in the Y direction and a second plane F₂ a normal to which runs in the X direction are considered. Then, the crystal axis vectors that appear when the crystal axis vector V_{C} is projected on the first and second planes F₁ and F₂ are taken as a first and a second projected vector V_{P1} and V_{P2} respectively. Here, the angle θa between the first projected vector V_{P1} and the normal vector V_{N} is the off-angle in the a-axis direction, and the angle θc between the second projected vector V_{P2} and the normal vector V_{N} is the off-angle in the c-axis direction. An off-angle in the a-axis direction, irrespective of whether it is in the + or − direction, indicates the same surface status from a crystallographic point of view, and thus behaves in the same manner in the + and − directions; this permits an off-angle in the a-axis direction to be stated in terms of an absolute value. On the other hand, an off-angle in the c-axis direction makes either the Ga polar plane G or the N polar plane N stronger depending on whether it is in the + or − direction, and thus behaves differently depending on the direction; therefore, an off-angle in the c-axis direction is stated with a distinction made between the + and − directions.

As described above, the GaN substrate 10 according to Embodiment 1 has, as the principal growth plane 10a, a plane inclined in the a-axis direction relative to the m plane {1-100}.

In the above-described GaN substrate 10, the absolute value of the off-angle in the a-axis direction relative to the m plane is adjusted to be more than 0.1 degrees. As the off angle in the a-axis direction increases, however, the amount of In absorbed in the active layer (an InGaN layer such as a well layer) tends to decrease, and accordingly, from the perspective of source material efficiency and the like, it is preferable that the absolute value of the off angle in the a-axis direction be 10 degrees or smaller. Incidentally, even with an off angle of 10 degrees or larger in the a-axis direction, film formation is possible. In a case where an off angle is provided also in the c-axis direction, it is preferable that the off angle in the c-axis direction be adjusted to be smaller than ±0.1 degrees. It is preferable that the off angle in the c-axis direction be adjusted to be smaller than the off angle in the a-axis direction.

In the case described above, it is preferable that the off-angle in the a-axis direction be adjusted to be larger than 1 degree but 10 degrees or smaller. Adjusting the off-angle in the a-axis direction in that range is more preferable, because it is then possible to obtain a marked effect of reducing the driving voltage and in addition an effect of improving surface morphology.

The nitride semiconductor laser chip 100 according to Embodiment 1 has, formed on the principal growth plane 10a of the above-described GaN substrate 10, a nitride semiconductor stacked structure 5 having a plurality of nitride semiconductor layers stacked together.

Here, in Embodiment 1, the semiconductor layer in contact with the principal growth plane 10a of the GaN substrate 10 is formed of a nitride semiconductor layer containing Al. Specifically, in the nitride semiconductor laser chip 100 according to Embodiment 1, as shown in FIGS. 2 and 3, on the principal growth plane 10a of the GaN substrate 10, a lower clad layer 12 of n-type Al_{0.06}Ga_{0.94}N with a thickness of about 2.2 μm is formed in contact with the principal growth plane 10a. The lower clad layer 12 is an example of a “nitride semiconductor layer” according to the invention. The GaN substrate 10 is formed to be of the n type.

On the lower clad layer 12, a lower guide layer 13 of Al_{0.005}Ga_{0.995}N with a thickness of about 0.1 μm is formed. On the lower guide layer 13, an active layer 14 is formed.

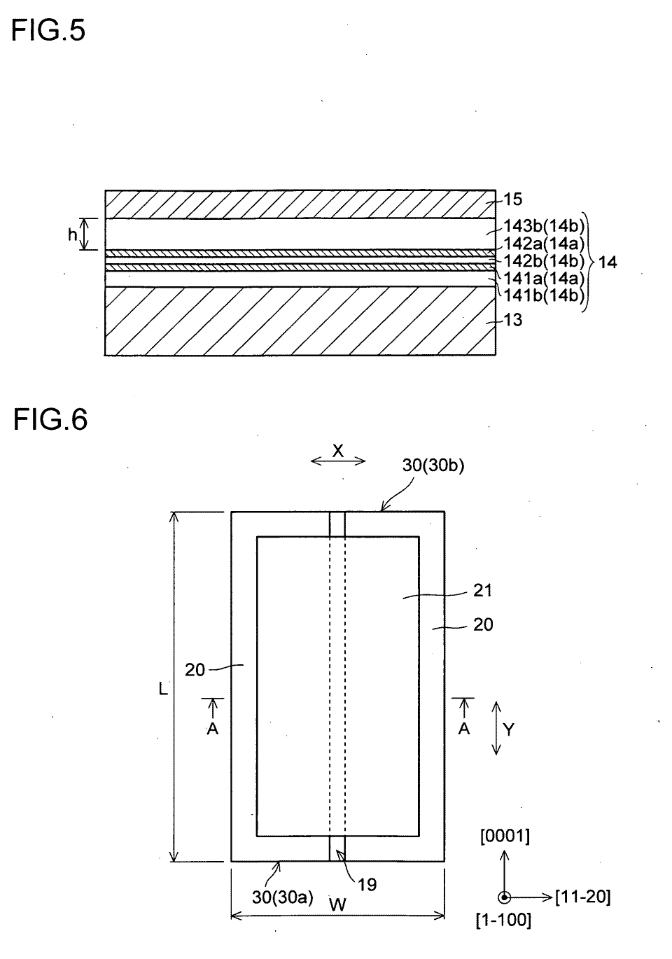

As shown in FIG. 5, the active layer 14 has a quantum well (DQW, double quantum well) structure having two well layers 14a of Inₓ₁Ga₁₋ₓ₁N and three barrier layers 14b of Alₓ₂Ga₁₋ₓ₂N stacked alternately. Specifically, the active layer 14 is formed by successively stacking, from the lower guide layer 13 side, a first barrier layer 141b, a first well layer 141a, a second barrier layer 142b, a second well layer 142a, and a third barrier layer 143b. The two well layers 14a (first and second well layers 141a and 142a) are each formed to have a thickness of about 3 nm to 4 nm. The first barrier layer 141b is formed to have a thickness of about 30 nm, the second barrier layer 142b is formed to have a thickness of about 16 nm, and the third barrier layer 143b is formed to have a thickness of about 60 nm. Thus, the three barrier layers 14b are each formed to have a different thickness.

In Embodiment 1, the well layers 14a (active layer 14) are formed to have an In composition ratio x1 of 0.15 or more but 0.45 or less (for example, from 0.2 to 0.25). The barrier layers 14b are formed of AlGaN, and are given an Al composition ratio x2 of, for example, 0<x2≦0.08. Giving the barrier layers 14b, which are formed of AlGaN, an Al composition ratio x2 of 0.08 or less makes efficient light confinement possible. Moreover, forming the barrier layers 14b out of AlGaN helps enhance luminous efficacy.

The reasons that forming the barrier layers 14b out of AlGaN enhances luminous efficacy are considered to be as follows. With a nitride semiconductor substrate having as the principal growth plane a plane having an off angle in the a-axis direction relative to the m plane, as described above, whereas forming a GaN layer on its principal growth plane tends to degrade surface morphology, forming a nitride semiconductor layer containing Al (for example an AlGaN layer, an AlInGaN layer, an AlInN layer, or the like) improves surface morphology. Accordingly, forming a barrier layer in an active layer out of a nitride semiconductor containing Al enhances the flatness of the barrier layer, and forming a well layer on the barrier layer with high flatness enhances the crystallinity of the well layer. Largely these are considered to be the reasons.

As shown in FIGS. 2 and 3, on the active layer 14, a carrier block layer 15 of p-type Al_{y}Ga_{1-y}N with a thickness of 40 nm or less (for example, about 12 nm) is formed. The carrier block layer 15 is formed to have an Al composition ratio y of 0.08 or more but 0.35 or less (for example, about 0.15). On the carrier block layer 15, an upper guide layer 16 of p-type Al_{0.01}Ga_{0.99}N is formed which has an elevated portion and, elsewhere than there, a flat portion. The upper guide layer 16 is formed to have a lower Al composition ratio than a clad layer. On the elevated portion of the upper guide layer 16, an upper clad layer 17 of p-type Al_{0.06}Ga_{0.94}N with a thickness of about 0.5 μm is formed. On the upper clad layer 17, a contact layer 18 of p-type Al_{0.01}Ga_{0.99}N with a thickness of about 0.1 μm is formed. Together the contact layer 18, the upper clad layer 17, and the elevated portion of the upper guide layer 16 constitute a stripe-shaped (elongate) ridge portion 19 with a width of about 1 μm to 3 μm (for example, about 1.5 μm). As shown in FIG. 6, the ridge portion 19 is formed so as to extend in the Y direction (approximately the c-axis [0001] direction). The p-type semiconductor layers (the carrier block layer 15, the upper guide layer 16, the upper clad layer 17, and the contact layer 18) are doped with Mg as a p-type impurity.

As shown in FIG. 5, for enhanced efficiency of carrier injection into the well layers 14a, the distance h between the carrier block layer 15 and the well layers 14a (the most carrier block layer 15 side one of the well layers 14a (142a)) is set to be about 60 nm. It is preferable that the distance h between the carrier block layer 15 and the well layers 14a be set to be 80 nm or less, and more preferably 30 nm or less. In Embodiment 1, the distance h is equal to the thickness of the third barrier layer 143b.

As described above, the nitride semiconductor laser chip 100 according to Embodiment 1 is so formed that the individual nitride semiconductor layers stacked on the GaN substrate 10 do not include a GaN layer.

Moreover, in the nitride semiconductor laser chip 100 according to Embodiment 1, as shown in FIGS. 2 and 3, on each side of the ridge portion 19, an insulating layer 20 for current constriction is formed. Specifically, on top of the upper guide layer 16, on the side faces of the upper clad layer 17, and on the side faces of the contact layer 18, an insulating layer 20 of SiO₂ with a thickness of about 0.1 μm to 0.3 μm (for example, about 0.15 μm) is formed.

On the top faces of the insulating layer 20 and of the contact layer 18, a p-side electrode 21 is formed so as to cover part of the contact layer 18. The p-side electrode 21, in its part covering the contact layer 18, makes direct contact with the contact layer 18. The p-side electrode 21 has a multiple-layer structure having the following layers stacked successively in order from the insulating layer 20 (the contact layer 18) side: a Pd layer (unillustrated) with a thickness of about 15 nm; a Pt layer (unillustrated) with a thickness of about 15 nm; and a Au layer (unillustrated) with a thickness of about 200 nm.

On the back face of the GaN substrate 10, an n-side electrode 22 is formed, which has a multiple-layer structure having the following layers stacked successively in order from the GaN substrate 10's back face side: a Hf layer (unillustrated) with a thickness of about 5 nm; and an Al layer (unillustrated) with a thickness of about 150 nm. On the n-side electrode 22, a metallized layer 23 is formed, which has a multiple-layer structure having the following layers stacked successively in order from the n-side electrode 22 side: a Mo layer (unillustrated) with a thickness of about 36 nm; a Pt layer (unillustrated) with a thickness of about 18 nm; and a Au layer (unillustrated) with a thickness of about 200 nm.

As shown in FIGS. 3 and 6, the nitride semiconductor laser chip 100 according to Embodiment 1 has a pair of resonator (cavity) faces 30, which include a light emission face 30a from which laser light is emitted and a light reflection face 30b opposite from the light emission face 30a. On the light emission face 30a, an emission-side coating (unillustrated) with a reflectance of, for example, 5% to 80% is formed. On the other hand, on the light reflection face 30b, a reflection-side coating (unillustrated) with a reflectance of, for example, 95% is formed. The reflectance of the emission-side coating is adjusted to be a desired value according to the laser output. The emission-side coating is composed of, in order from the semiconductor's emission facet side, for example, a film of aluminum oxynitride (oxide-nitride) or aluminum nitride AlOₓN₁₋ₓ (where 0≦x≦1) with a thickness of 30 nm, and a film of Al₂O₃ with a thickness of 215 nm. The reflection-side coating is composed of multiple-layered films of, for example, SiO₂, TiO₂, etc. Other than the materials just mentioned, films of dielectric materials such as SiN, ZrO₂, Ta₂O₅, MgF₂, etc. may be used. The coating on the light emission face side may instead be composed of a film of AlOₓN₁₋ₓ (where 0≦x≦1) with a thickness of 12 nm, and a film of silicon nitride SiN with a thickness of 100 nm.

By forming a film of aluminum oxynitride or aluminum nitride AlOₓN₁₋ₓ (where 0≦x≦1) on a cleaved facet (in Embodiment 1, the c plane), or an etched facet etched by vapor-phase etching or liquid-phase etching, of an m-plane nitride semiconductor substrate as described above, it is possible to greatly reduce the rate of non-radiative recombination at the interface between the semiconductor and the emission-side coating, and thereby to greatly improve the COD (catastrophic optical damage) level. More preferably, the film of aluminum oxynitride or aluminum nitride AlOₓN₁₋ₓ (where 0≦x≦1) has a crystal of the same hexagonal crystal system as the nitride semiconductor; further preferably, it is crystallized with its crystal axes aligned with those of the nitride semiconductor, because that further reduces the rate of non-radiative recombination and further improves the COD level. To increase the reflectance on the light emission face side, there may be formed, on the above-mentioned coating, stacked films having films of silicon oxide, aluminum oxide, titanium oxide, tantalum oxide, zirconium oxide, silicon oxide, etc. stacked together.

As shown in FIG. 6, the nitride semiconductor laser chip 100 according to Embodiment 1 has a length L (chip length L (resonator length L)) of about 300 μm to 1800 μm (for example, about 600 μm) in the direction (the Y direction (approximately the c-axis [0001] direction)) perpendicular to the resonator faces 30, and has a width W (chip width W) of about 150 μm to about 600 μm in the direction (the X direction (approximately the a-axis [11-20] direction)) along the resonator faces 30.

In Embodiment 1, as described above, a plane having an off-angle in the a-axis direction relative to the m plane is taken as the principal growth plane 10a of the GaN substrate 10, and this makes it possible to suppress a bright-spotted EL emission pattern. That is, with that structure, it is possible to improve the EL emission pattern. This makes it possible to enhance the luminous efficacy of the nitride semiconductor laser chip. By enhancing luminous efficacy, it is possible to obtain a high-luminance nitride semiconductor laser chip. One reason that an effect of suppressing bright-spotted emission as described above is obtained is considered to be as follows: as a result of the principal growth plane 10a of the GaN substrate 10 having an off-angle in the a-axis direction relative to the m plane, when the active layer 14 (the well layers 14a) is grown on the principal growth plane 10a, the direction of migration of In atoms changes so that, even under conditions with a high In composition ratio (with a large supply of In), agglomeration of In is suppressed. Another reason is considered to be that the growth mode of the p-type nitride semiconductor layers formed on the active layer 14 also changes so as to enhance the activation rate of Mg as a p-type impurity and reduce the resistance of the p-type nitride semiconductor layers. Reducing the resistance of the p-type nitride semiconductor layers makes uniform injection of current easier, and thus makes the EL emission pattern uniform.

In Embodiment 1, by suppressing a bright-spotted EL emission pattern, it is possible to make the EL emission pattern uniform, and thus it is possible to reduce the driving voltage. Incidentally, by suppressing bright-spotted emission, it is possible to obtain a uniform EL emission pattern, and thus it is possible to increase gain in the formation of the nitride semiconductor laser chip.

In Embodiment 1, with the structure described above, it is possible to suppress a bright-spotted EL emission pattern, and thus it is possible to enhance luminous efficacy. This makes it possible to enhance device characteristics and reliability. That is, it is possible to obtain a nitride semiconductor laser chip with superb device characteristics and high reliability.

In Embodiment 1, by forming, on the principal growth plane 10a having an off angle in the a-axis direction relative to the m plane, the lower clad layer 12 of AlGaN in contact with the principal growth plane 10a, it is possible to greatly improve surface morphology and to enhance flatness on the layer surface. This makes it possible to give the individual nitride semiconductor layers formed on the GaN substrate 10 a uniform thickness distribution across the plane. Moreover, by improving surface morphology, it is possible to reduce variations in device characteristics (for example, I-L response, I-V response, far-field pattern, wavelength, etc.), and thus it is possible to increase manufacturing yields. It is thus possible to easily obtain chips having characteristics within the rated ranges. Moreover, by enhancing surface morphology, it is also possible to further enhance device characteristics and reliability.

In Embodiment 1, by making the absolute value of the off angle in the a-axis direction larger than 0.1 degrees, it is possible to suppress a bright-spotted EL emission pattern easily.

In a case where the principal growth plane 10a of the GaN substrate 10 has an off angle also in the c-axis direction relative to the m plane, by making the off angle in the a-axis direction larger than the off angle in the c-axis direction, it is possible to suppress a bright-spotted EL emission pattern effectively. That is, with that structure, it is possible to suppress the inconvenience of the effect of suppressing bright-spotted emission being diminished due to the off angle in the c-axis direction being too large. It is thus possible to enhance luminous efficacy easily.

In Embodiment 1, by forming the barrier layers 14b of the active layer 14 out of AlGaN, it is possible to enhance the flatness of the barrier layers 14b; thus, by forming the well layers 14a on the barrier layers 14b with high flatness, it is possible to enhance the crystallinity of the well layers 14a, and also to suppress In layer separation or the like in the well layers. It is thus possible to further enhance luminous efficacy.

In Embodiment 1, by giving the active layer 14 of the nitride semiconductor laser chip 100 a DQW structure, it is possible to reduce the driving voltage easily. This too helps enhance device characteristics and reliability. Even when the active layer 14 is given a DQW structure, it is possible to suppress a bright-spotted EL emission pattern. In a case where the above-described GaN substrate 10 having a principal growth plane 10a provided with an off-angle relative to the m plane is used, by giving the active layer 14 formed on the GaN substrate 10 a DQW structure, as compared with giving the active layer 14 a multiple quantum well (MQW) structure, helps enhance luminous efficacy. This makes it possible to obtain a high-luminance nitride semiconductor laser chip easily.

In Embodiment 1, by giving the carrier block layer 15 an Al composition ratio y of 0.08 or more but 0.35 or less, it is possible to form an energy barrier sufficiently high with respect to carriers (electrons), and thus it is possible to more effectively prevent the carriers injected into the active layer 14 from flowing into the p-type nitride semiconductor layers. This makes it possible to suppress a bright-spotted EL emission pattern effectively. Giving the carrier block layer 15 an Al composition ratio y of 0.35 or less helps suppress an increase in the resistance of the carrier block layer 15 due to the Al composition ratio y being too high. Incidentally, in a region with a high In composition ratio x1 (x1≧0.15) in the well layers 14a, an Al composition ratio y of 0.08 or more in the carrier block layer 15 formed on the active layer 14 makes it extremely difficult to grow the carrier block layer 15 satisfactorily. This is because, as the In concentration in the well layers 14a increases, the flatness of the surface of the active layer 14 deteriorates, and this makes it difficult to form a film with a high Al composition ratio y with good crystallinity. However, by use of the GaN substrate 10 having as the principal growth plane 10a a plane having an off-angle in the a-axis direction relative to the m plane, even in a case where the In composition ratio x1 in the active layer 14 (the well layers 14a) is 0.15 or more but 0.45 or less, it is possible to form on that active layer 14 a carrier block layer 15 with an Al composition ratio y of 0.08 or more but 0.35 or less with good crystallinity. This makes it possible to suppress a bright-spotted EL emission pattern effectively and make the EL emission pattern uniform.

By use of the above-described GaN substrate 10 having a principal growth plane 10a provided with an off-angle in the a-axis direction relative to the m plane, even in a case where the In composition ratio x1 in the well layers 14a is 0.15 or more, that is, even under conditions where a bright-spotted EL emission pattern is prominent, it is possible to effectively suppress a bright-spotted EL emission pattern. Thus, by giving the well layers 14a of the active layer 14 an In composition ratio x1 of 0.15 or more, it is possible to obtain a prominent effect of suppressing bright-spotted emission. On the other hand, by giving the well layers 14a an In composition ratio x1 of 0.45 or less, it is possible to effectively suppress the inconvenience of a large number of dislocations developing in the active layer 14 as a result of strain such as lattice mismatch due to the In composition ratio x1 in the well layers 14a being more than 0.45.

In Embodiment 1, by forming the barrier layer 14b formed under (on the GaN substrate 10 side of) the well layers 14a out of AlGaN and giving it an Al composition ratio x2 of 0<x2≦0.08, it is possible to obtain effects such as an effect of enhancing the flatness on the barrier layers 14b. This makes it possible to enhance the luminous efficacy of the well layers 14a, and thus it is possible to obtain a semiconductor laser chip with superb device characteristics and high reliability.

Incidentally, setting the distance h between the carrier block layer 15 and the well layers 14a to be 200 nm or more permits current to spread when carriers diffuse from the carrier block layer 15 to the active layer 14, and thus helps slightly suppress bright-spotted emission. On the other hand, by use of the above-described GaN substrate 10 having a principal growth plane 10a provided with an off-angle relative to the m plane, even when the distance h between the carrier block layer 15 and the well layers 14a is not set to be 200 nm or more, it is possible to suppress bright-spotted emission effectively. For example, even when the distance h between the carrier block layer 15 and the well layers 14a is set to be less than 120 nm, it is possible to suppress bright-spotted emission effectively. The smaller the distance h between the carrier block layer 15 and the well layers 14a, the more preferable, because that enhances the efficiency of carrier injection into the well layers 14a. Accordingly, by making the distance h between the carrier block layer 15 and the well layers 14a smaller than 120 nm, it is possible to enhance the efficiency of carrier injection into the well layers 14a.

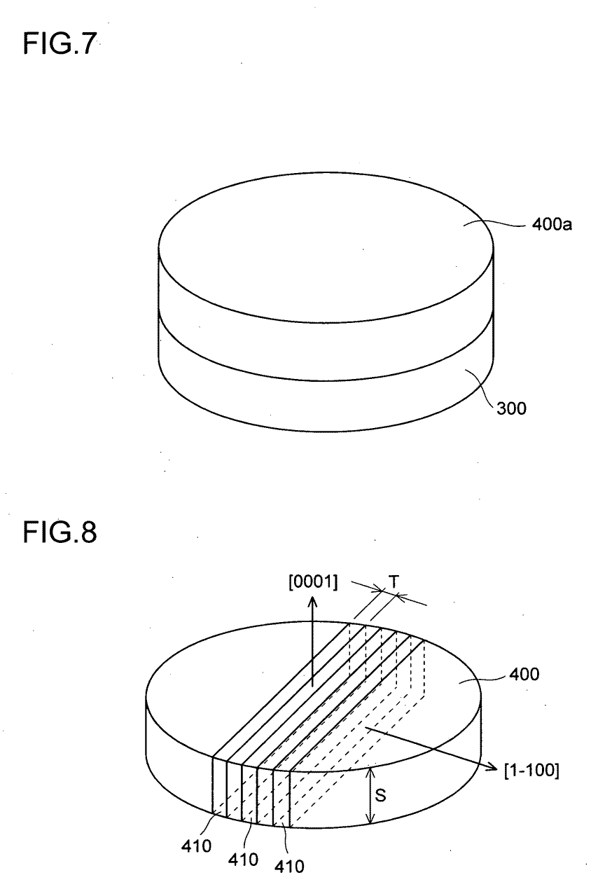

FIGS. 7 to 19 are diagrams illustrating a method of manufacture of a nitride semiconductor laser chip according to Embodiment 1 of the invention. Next, with reference to FIGS. 2, 3, and 5 to 19, a method of manufacture of the nitride semiconductor laser chip 100 according to Embodiment 1 of the invention will be described.

First, a GaN substrate 10 having as a principal growth plane 10a a plane having an off-angle relative to the m plane is prepared. This GaN substrate 10 is fabricated by, for example, using as a seed substrate a substrate cut out of a GaN bulk crystal having the c plane (0001) as a principal plane and growing a GaN crystal on that seed substrate. Specifically, as shown in FIG. 7, a protective film (unillustrated) of SiO₂ is formed on part of a base substrate 300, and then on the base substrate 300, over the protective film, a GaN bulk crystal is grown by an epitaxial growth process such as an MOCVD (metal organic chemical vapor deposition) process. This causes growth to start in the part where the protective film is not formed, and over the protective film, the GaN crystal grows laterally. The parts of the GaN crystal grown laterally meet over the protective film and continue to grow, and thus a GaN crystal layer 400a is formed on the base substrate 300. The GaN crystal layer 400a is formed sufficiently thick so that it may be handled independently even after removal of the base substrate 300. Next, from the GaN crystal layer 400a thus formed, the base substrate 300 is removed, for example, by etching. This leaves, as shown in FIG. 8, a GaN bulk crystal 400 having the c plane (0001) as a principal plane. As the base substrate 300, it is possible to use, for example, a GaAs substrate, a sapphire substrate, a ZnO substrate, a SiC substrate, a GaN substrate, etc. The GaN bulk crystal 400 is given a thickness S of, for example, about 3 mm.

Next, both principal planes, that is, the (0001) and (000-1) planes, of the GaN bulk crystal 400 thus obtained are ground and polished so as to each have an average roughness Ra of 5 nm. The average roughness Ra here conforms to the arithmetic average roughness Ra defined in JIS B 0601, and can be measured on an AFM (atomic force microscope).

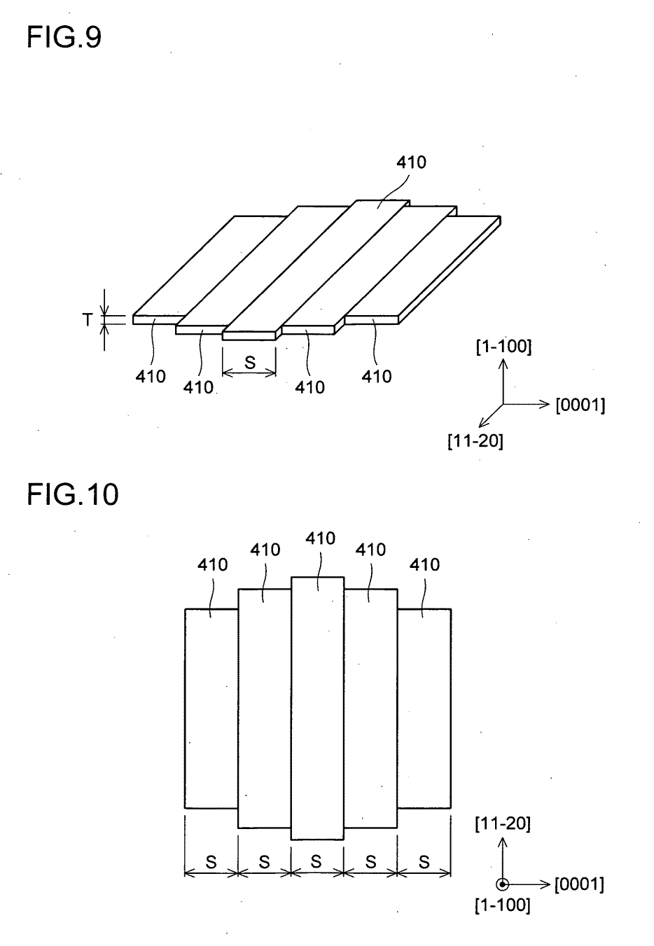

Next, the GaN bulk crystal 400 is sliced at a plurality of planes perpendicular to the [1-100] direction so that a plurality of GaN crystal substrates 410 having the m plane {1-100} as a principal plane are cut out each with a thickness T (for example, 1 mm) (and with a width S of 3 mm). Then, with each of the GaN crystal substrates 410 thus cut out, the four faces that have not yet been ground or polished are ground and polished so as to have an average roughness Ra of 5 nm. Thereafter, as shown in FIGS. 9 and 10, the plurality of GaN crystal substrates 410 are arranged side by side in such a way that their respective principal planes are parallel to one another and that their respective [0001] directions are aligned with one another.

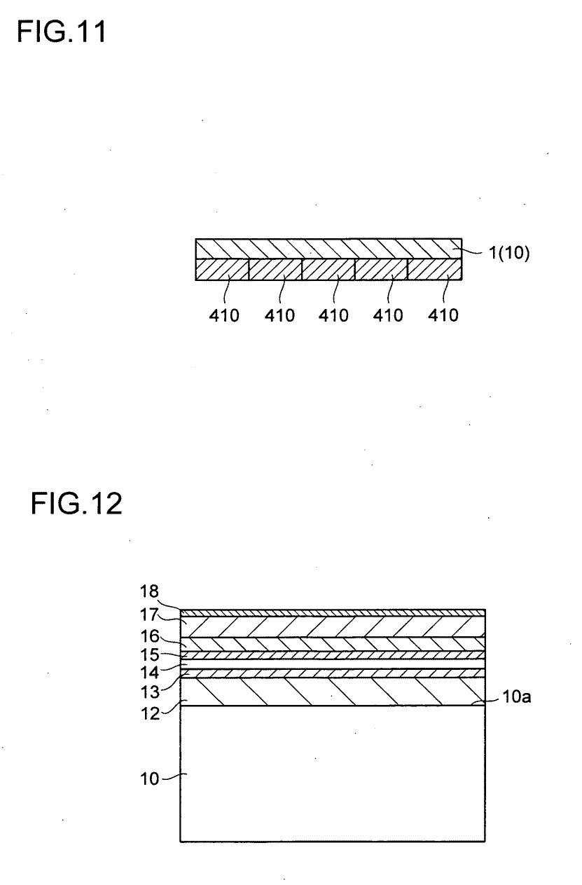

Subsequently, as shown in FIG. 11, the plurality of GaN crystal substrates 410 thus arranged side by side are taken as a seed substrate, and on the m plane {1-100} of those GaN crystal substrates 410, a GaN crystal is grown by an epitaxial growth process such as an HVPE process. In this way, a GaN substrate 1 having the m plane as a principal growth plane is obtained. Next, the principal plane of the GaN substrate 1 thus obtained is polished by chemical and mechanical polishing so as to control the off-angles in the a- and c-axis directions independently, thereby to set the off-angles in the a- and c-axis directions relative to the m plane at desired off-angles. These off-angles can be measured by an X-ray diffraction method. In this way, a GaN substrate 10 having as the principal growth plane a plane having off-angles in both the a- and c-axis directions relative to the m plane is obtained.

In the above-described fabrication of the GaN substrate 10, in a case where a substrate with a large off-angle is fabricated, when a plurality of GaN crystal substrates 410 are cut out of the GaN bulk crystal 400, they may be cut out at a predetermined cut-out angle relative to the [1-100] direction so that the principal plane of the GaN crystal substrates 410 has a desired off-angle relative to the m plane {1-100}. Doing so permits the principal plane of the GaN crystal substrates 410 to have a desired off-angle relative to the m plane {1-100}, and accordingly the principal plane (principal growth plane) of the GaN substrate 1 (10) formed on that principal plane comes to have the desired off-angle relative to the m plane {1-100}.

Polishing the principal plane of the GaN crystal substrates 410 cut out of the GaN bulk crystal 400 (see FIG. 8) by chemical and mechanical polishing makes it possible to use the GaN crystal substrates 410 as the GaN substrate 10. In that case, the width S of the GaN crystal substrates 410 may be 3 mm or more.

Here, in Embodiment 1, the off-angle in the a-axis direction in the above-described GaN substrate 10 is adjusted to be larger than 0.1 degrees. In a case where an off-angle is provided also in the c-axis direction, it is preferable that the off-angle in the c-axis direction be adjusted to be larger than ±0.1 degrees. Moreover, it is preferable that the off-angle in the c-axis direction be adjusted to be smaller than the off-angle in the a-axis direction.

Subsequently, as shown in FIG. 12, on the principal growth plane 10a of the GaN substrate 10 obtained, individual nitride semiconductor layers 12 to 18 are grown by an MOCVD process. Specifically, on the principal growth plane 10a of the GaN substrate 10, the following layers are grown successively: a lower clad layer 12 of n-type Al_{0.06}Ga_{0.94}N with a thickness of about 2.2 μm; a lower guide layer 13 of n-type Al_{0.005}G_{0.995}N with a thickness of about 0.1 μm; and an active layer 14. When the active layer 14 is grown, as shown in FIG. 5, two well layers 14a of Inₓ₁Ga₁₋ₓ₁N and three barrier layers 14b of AlₓGa₁₋ₓ₂N are alternately grown. Specifically, on the lower guide layer 13, the following layers are grown successively from bottom up: a first barrier layer 141b with a thickness of about 30 nm; a first well layer 141a with a thickness of about 3 nm to 4 nm; a second barrier layer 142b with a thickness of about 16 nm; a second well layer 142a with a thickness of about 3 nm to 4 nm; and a third barrier layer 143b with a thickness of about 60 nm. In this way, on the lower guide layer 13, an active layer 14 having a DQW structure composed of two well layers 14a and three barrier layers 14b is formed. At this time, the well layers 14a are so formed that the In composition ratio x1 there is 0.15 or more but 0.45 or less (for example, 0.2 to 0.25). On the other hand, the barrier layers 14b are so formed that the Al composition ratio x2 there is, for example, in the range of 0<x2≦0.08.

Next, as shown in FIG. 12, on the active layer 14, the following layers are grown successively: a carrier block layer 15 of p-type Al_{y}Ga_{1-y}N; an upper guide layer 16 of p-type Al_{0.01}Ga_{0.99}N with a thickness of about 0.05 μm; an upper clad layer 17 of p-type Al_{0.06}Ga_{0.94}N with a thickness of about 0.5 μm; and a contact layer 18 of p-type Al_{0.01}Ga_{0.99}N with a thickness of about 0.1 μm. At this time, it is preferable that the carrier block layer 15 be formed so as to have a thickness of 40 nm or less (for example, about 12 nm). Moreover, the carrier block layer 15 is so formed that the Al composition ratio y there is 0.08 or more but 0.35 or less (for example, about 0.15). The n-type semiconductor layers (the lower clad layer 12 and the lower guide layer 13) are doped with, for example, Si as an n-type impurity, and the p-type nitride semiconductor layers (the carrier block layer 15, the upper guide layer 16, the upper clad layer 17, and the contact layer 18) are doped with, for example, Mg as a p-type impurity.

In Embodiment 1, the n-type semiconductor layers are formed at a growth temperature of 900° C. or higher but lower than 1300° C. (for example, 1075° C.). The well layers 14a of the active layer 14 are formed at a growth temperature of 600° C. or higher but 800° C. or lower (for example, 700° C.). The barrier layers 14b, which are contiguous with the well layers 14a, are formed at the same growth temperature (for example, 700° C.) as the well layers 14a. The p-type nitride semiconductor layers are formed at a growth temperature of 700° C. or higher but lower than 900° C. (for example, 880° C.). The growth temperature of the n-type semiconductor layers is preferably 900° C. or higher but lower than 1300° C., and more preferably 1000° C. or higher but lower than 1300° C. The growth temperature of the well layers 14a of the active layer 14 is preferably 600° C. or higher but 830° C. or lower, and in a case where the In composition ratio x1 in the well layers 14a is 0.15 or more, preferably 600° C. or higher but 770° C. or lower; more preferably, 630° C. or higher but 740° C. or lower. The growth temperature of the barrier layers 14b of the active layer 14 is preferably the same as or higher than that of the well layers 14a. The growth temperature of the p-type nitride semiconductor layers is preferably 700° C. or higher but lower than 900° C., and more preferably 700° C. or higher but 880° C. or lower. Needless to say, since even forming the p-type nitride semiconductor layers at a temperature of 900° C. or higher gives p-type conductivity, the p-type nitride semiconductor layers may be formed at a temperature of 900° C. or higher.

As source materials for the growth of these nitride semiconductors, for example, the following materials can be used: as a source material of Ga, trimethylgallium ((CH₃)₃Ga; TMGa); as a source material of Al, trimethylaluminium ((CH₃)₃Al; TMAl); as a source material of In, trimethylindium ((CH₃)₃In; TMIn); as a source material of N, NH₃. As a carrier gas, for example, H₂ can be used. As for dopants, as an n-type dopant (n-type impurity), for example, monosilane (SiH₄) can be used; as a p-type dopant (p-type impurity), for example, cyclopentadienylmagnesium (CP₂Mg) can be used.

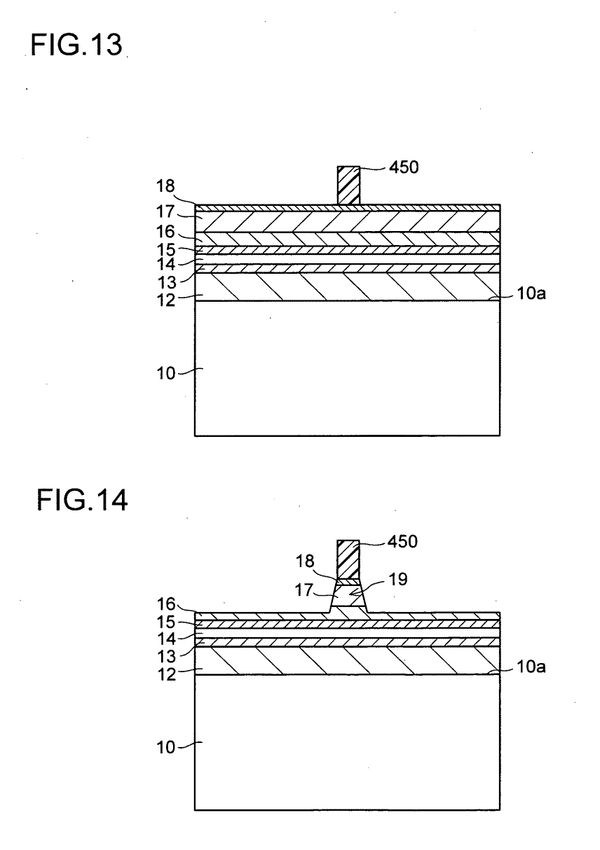

Next, as shown in FIG. 13, by use of a photolithography technology, on the contact layer 18, a stripe-shaped (elongate) resist layer 450 is formed that has a width of about 1 μm to 10 μm (for example, about 1.5 μm) and that extends parallel to the Y direction (approximately the c-axis [0001] direction). Then, as shown in FIG. 14, by a RIE (reactive ion etching) process using chlorine-based gas such as SiCl₄ or Cl₂ or Ar gas, and with the resist layer 450 used as a mask, etching is performed halfway into the depth of (meaning, so as to leave a small part of, and thus not to completely penetrate) the upper guide layer 16. In this way, a stripe-shaped (elongate) ridge portion 19 (see FIGS. 3 and 6) is formed which is constituted by an elevated portion of the upper guide layer 16, the upper clad layer 17, and the contact layer 18 and which extends parallel to the Y direction (approximately the c-axis direction), with each ridge portion 19 parallel to another.

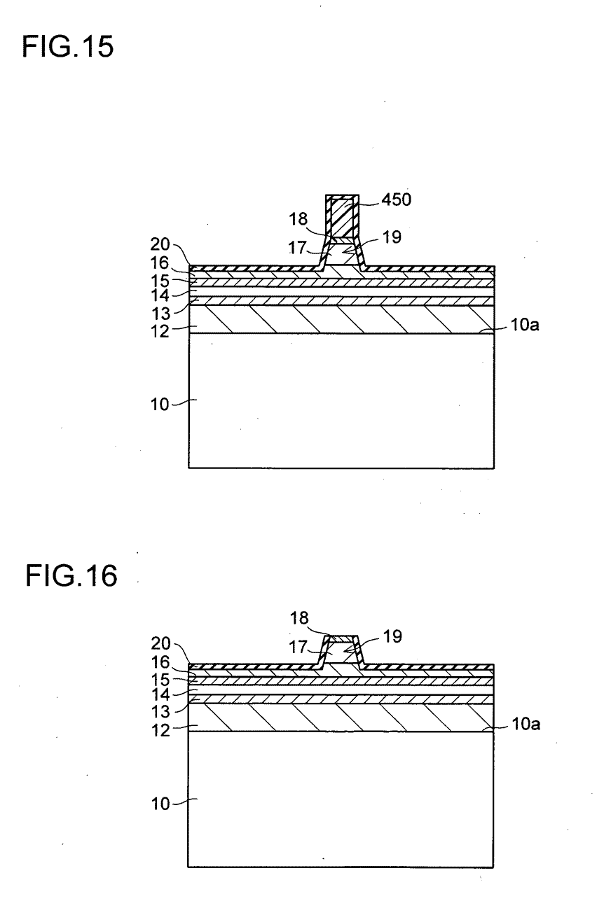

Subsequently, as shown in FIG. 15, with the resist layer 450 left on the ridge portion 19, by a sputtering process or the like, an insulating layer 20 of SiO₂ with a thickness of about 0.1 μm to 0.3 μm (for example, about 0.15 μm) is formed to bury the ridge portion 19. Then, the resist layer 450 is removed by lift-off so that the contact layer 18 at the top of the ridge portion 19 is exposed. In this way, on each side of the ridge portion 19, an insulating layer 20 as shown in FIG. 16 is formed.

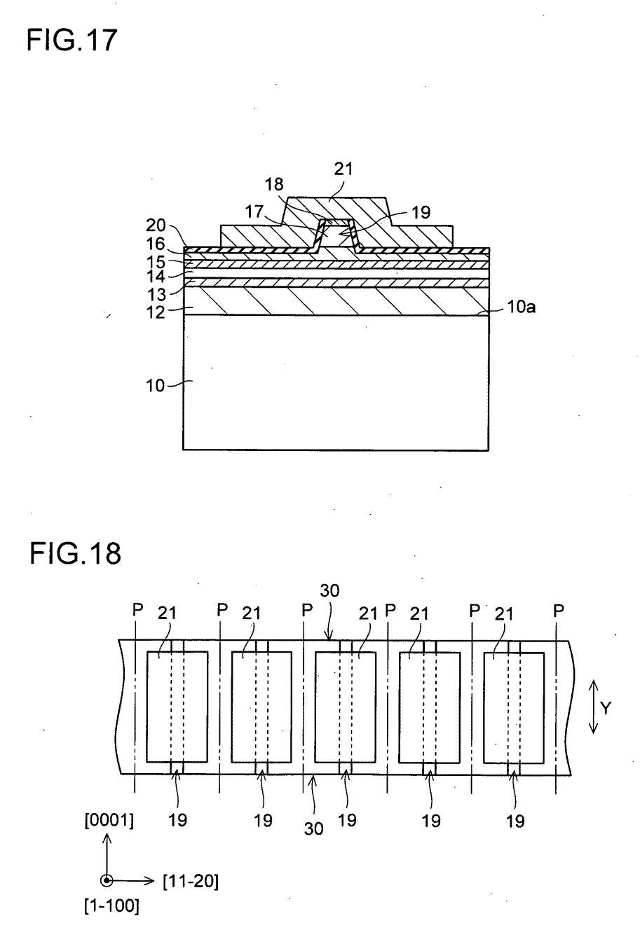

Next, as shown in FIG. 17, by a vacuum deposition process or the like, the following layers are formed successively from the substrate side (the insulating layer 20 side): a Pd layer (unillustrated) with a thickness of about 15 μm; and a Au layer (unillustrated) with a thickness of about 200 nm. Thus, on the insulating layer 20 (the contact layer 18), a p-side electrode 21 having a multiple-layer structure is formed.

Next, to make the substrate easy to split, the back face of the GaN substrate 10 is ground or polished until the thickness of the GaN substrate 10 is reduced to about 100 μm. Thereafter, as shown in FIG. 2, on the back face of the GaN substrate 10, by a vacuum deposition process or the like, the following layers are formed successively from the GaN substrate 10's back face side: a Hf layer (unillustrated) with a thickness of about 5 nm; and an Al layer (unillustrated) with a thickness of about 150 nm. Thus, an n-side electrode 22 having a multiple-layer structure is formed. Then, on the n-side electrode 22, the following layers are formed successively from the n-side electrode 22 side: a Mo layer (unillustrated) with a thickness of about 36 nm; a Pt layer (unillustrated) with a thickness of about 18 nm; and a Au layer (unillustrated) with a thickness of about 200 nm. Thus, a metallized layer 23 having a multiple-layer structure is formed. Before the n-side electrode 22 is formed, dry etching or wet etching may be performed for the purpose of, for example, adjusting the n-side electrical characteristics.

Subsequently, as shown in FIG. 18, by a technique such as a scribing-breaking process or laser scribing, the wafer is split into bars. This produces a bar-shaped array of chips having resonator faces 30 at the split facets. Next, by a technique such as a vacuum deposition process or a sputtering process, a coating is applied to the facets (resonator faces 30) of the bar-shaped array of chips. Specifically, on one of the facets which will serve as a light emission face, an emission-side coating (unillustrated) of, for example, a film of aluminum oxynitride or the like is formed. On the facet opposite from it, which will serve as a light reflection face, a reflection-side coating (unillustrated) of, for example, multiple-layered films of SiO₂, TiO₂, etc. is formed.

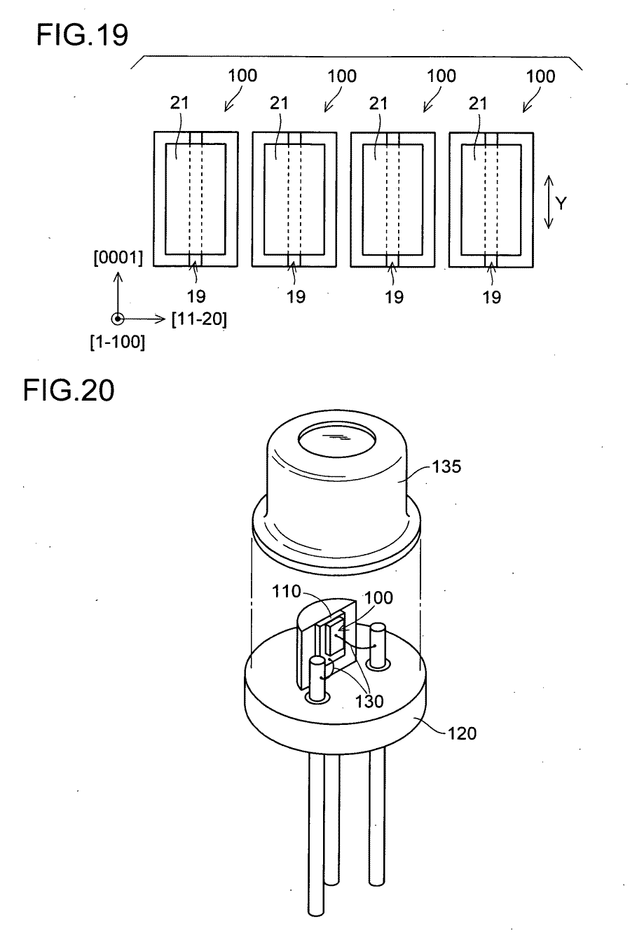

Lastly, the bar-shaped array of chips is split along planned splitting lines P along the Y direction (approximately the c-axis [0001] direction) into separate pieces of individual nitride semiconductor laser chips as shown in FIG. 19. In this way, the nitride semiconductor laser chip 100 according to Embodiment 1 of the invention is manufactured.

The nitride semiconductor laser chip 100 according to Embodiment 1 manufactured as described above is, as shown in FIG. 20, mounted on a stem 120 with a sub-mount 110 interposed in between and is electrically connected to lead pins by wires 130. Then, a cap 135 is welded on the stem 120 to complete assemblage into a can-packaged semiconductor laser device (semiconductor device).

In the manufacturing method of the nitride semiconductor laser chip 100 according to Embodiment 1, as described above, on the principal growth plane 10a having an off angle in the a-axis direction relative to the m plane, the lower clad layer 12 of n-type Al_{0.06}Ga_{0.94}N is formed in contact with the principal growth plane 10a, and this makes it possible to obtain good surface morphology. This makes it possible to give the individual nitride semiconductor layers a uniform thickness distribution across the plane, and thereby to enhance the flatness of the individual nitride semiconductor layers. Moreover, by enhancing surface morphology, it is possible to reduce variations in device characteristics, and thus to increase the number of chips having characteristics within the rated ranges. Thus, it is possible to increase manufacturing yields. By enhancing surface morphology, it is also possible to further enhance device characteristics and reliability.

In Embodiment 1, by forming the n-type semiconductor layers at a high temperature of 900° C. or higher, it is possible to give the n-type semiconductor layers a flat surface. Thus, by forming the active layer 14 and the p-type nitride semiconductor layers on the n-type semiconductor layers with a flat surface, it is possible to suppress degradation of crystallinity in the active layer 14 and the p-type nitride semiconductor layers. This too makes it possible to form a high-quality crystal. On the other hand, by forming the n-type semiconductor layers at a growth temperature lower than 1300° C., it is possible to suppress the inconvenience of the surface of the GaN substrate 10 re-evaporating and becoming rough during the raising of temperature due to the n-type semiconductor layers being formed at a growth temperature of 1300° C. or higher. Thus, with this scheme, it is possible to easily manufacture a nitride semiconductor laser chip 100 with superb device characteristics and high reliability.

In Embodiment 1, by forming the well layers 14a of the active layer 14 at a growth temperature of 600° C. or higher, it is also possible to suppress the inconvenience of a shorter atom diffusion length and hence degraded crystallinity due to the well layers 14a being formed at a growth temperature lower than 600° C. On the other hand, by forming the well layers 14a of the active layer 14 at a growth temperature of 800° C. or lower, it is possible to suppress the inconvenience of the active layer 14 being blackened by thermal damage due to the well layers 14a of the active layer 14 being formed at a growth temperature higher than 800° C. (for example, 830° C. or higher). The growth temperature of the barrier layers 14b, which are contiguous with the well layers 14a, is preferably the same as or higher than that of the well layers 14a.

In Embodiment 1, by forming the p-type nitride semiconductor layers at a growth temperature of 700° C. or higher, it is possible to suppress the inconvenience of the p-type nitride semiconductor layers having a high resistance due to their growth temperature being too low. On the other hand, by forming the p-type nitride semiconductor layers at a growth temperature lower than 1100° C., it is possible to reduce thermal damage to the active layer 14. Incidentally, forming the barrier layers out of AlGaN makes the active layer more resistant to thermal damage occurring during formation of the p-type semiconductor layers. That is, even when the p-type semiconductor layers are formed at a growth temperature of 1000° C. or higher, it is possible to suppress the active layer being blackened by thermal damage.

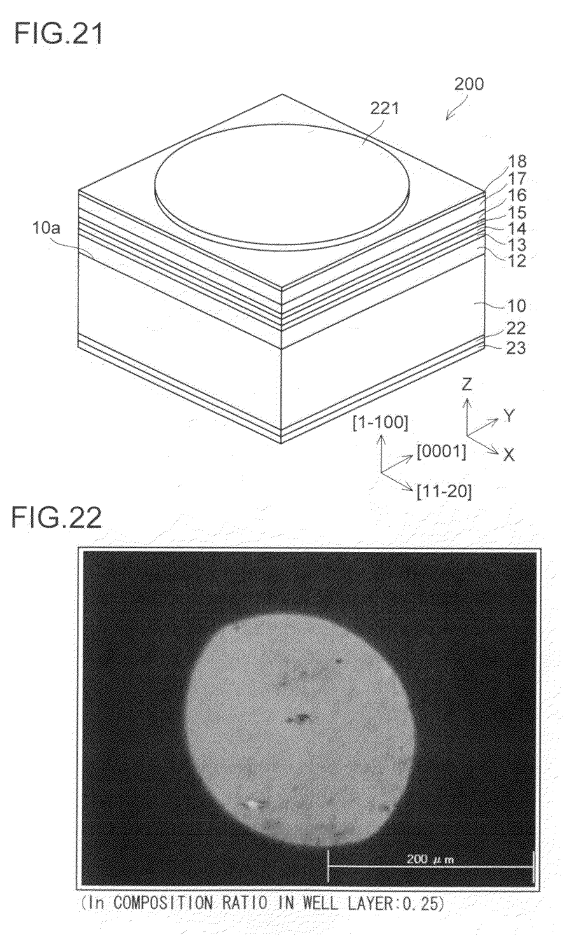

Next, a description will be given of experiments conducted to verify the effects of a nitride semiconductor laser chip 100 according to the embodiment described above. In these experiments, first, a light-emitting diode chip 200 as shown in FIG. 21 was fabricated as a test chip, and the EL emission pattern was inspected. The reason that a light-emitting diode chip was used for the inspection of the EL emission pattern is that, with a nitride semiconductor laser chip, which has a constricted current injection region as a result of a ridge portion being formed, it is difficult to inspect the EL emission pattern.

The test chip (light-emitting diode chip 200) was fabricated by forming nitride semiconductor layers similar to those in the embodiment described above on a GaN substrate 10 similar to that in the embodiment described above. The formation of the nitride semiconductor layers was conducted in a similar manner as in the embodiment described above. Specifically, as shown in FIG. 21, by use of a GaN substrate 10 having as a principal growth plane 10a a plane having an off-angle relative to the m plane, on its principal growth plane 10a, the following layers were formed successively: a lower clad layer 12; a lower guide layer 13; an active layer 14; a carrier block layer 15; an upper guide layer 16; an upper clad layer 17; and a contact layer 18. Next, on the contact layer 18, a p-side electrode 221 was formed. The p-side electrode 221 was formed transparent to allow inspection of the EL emission pattern. On the back face of the GaN substrate 10, an n-side electrode 22 and a metallized layer 23 were formed. In the test chip, the GaN substrate 10 had an off-angle of 1.7 degrees in the a-axis direction and an off-angle of +0.1 degrees in the c-axis direction. In the test chip, the In composition ratio in the well layers was 0.25, and the Al composition ratio in the barrier layers was 2%. Current was injected into the thus fabricated test chip (the light-emitting diode chip 200) to make it emit light, and the light distribution across the plane was inspected. FIG. 22 shows a microscope photograph of the EL emission pattern observed in the test chip.

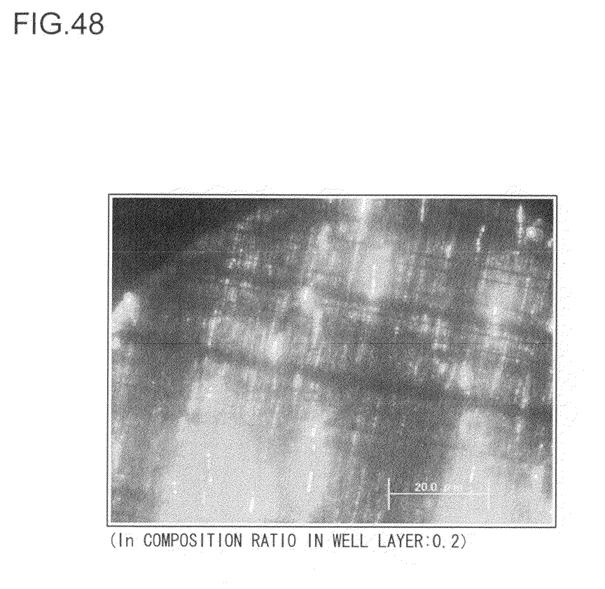

On the other hand, as a comparison chip, a light-emitting diode chip employing a GaN substrate having the m plane as a principal growth plane (substantially an m-plane just substrate, with an off angle of 0 degrees in the a-axis direction and an off angle of +0.05 degrees in the c-axis direction) was fabricated. This comparison chip was fabricated in the same manner as the test chip described above. The gas flow amount of In was the same as for the test chip, but in the comparison chip, the In composition ratio in the well layers was 0.2. In the comparison chip, the barrier layers were formed of In_{0.02}Ga_{0.98}N. As with the test chip, the light distribution across the plane was inspected. Except employing an m-plane just substrate as the GaN substrate, having an In composition ratio of 0.2 in the well layers, and having the barrier layers formed of InGaN, the comparison chip had a similar structure to the test chip (the light-emitting diode chip 200). The EL emission pattern shown in FIG. 48 is (a microscope photograph of) the EL emission pattern observed in the comparison chip.

Whereas as shown in FIG. 48 the comparison chip exhibited a bright-spotted EL emission pattern, as shown in FIG. 22 the test chip, despite having a higher In composition ratio in the well layers, exhibited an EL emission pattern of uniform light emission as a result of a bright-spotted EL emission pattern being suppressed. It was thus confirmed that using a GaN substrate 10 having as a principal growth plane 10a a plane having an off-angle in the a-axis direction relative to the m plane helped suppress a bright-spotted EL emission pattern. On the other hand, through measurement of luminous efficacy with the test chip and the comparison chip, it was confirmed that the luminous efficacy of the test chip was increased to 1.5 times that of the comparison chip. The emission wavelength of the test chip was 530 nm, and the emission wavelength of the comparison chip was 500 nm. It was thus confirmed that the test chip, in which the off-angle was controlled, was more efficient also in terms of In absorption than the comparison chip, which used an m-plane just substrate. The foregoing confirms that providing an off-angle in the a-axis direction relative to the m plane helps suppress bright-spotted emission and increase luminous efficacy in a wavelength region of green. It is also confirmed that, by forming the barrier layers of the active layer out of a nitride semiconductor layer containing Al, it is possible to obtain a chip offering uniform, high luminous intensity even in a very long emission wavelength region of 530 nm. Also confirmed is that the increase in luminous intensity in a long wavelength region, which is the effect obtained by forming the barrier layers of the active layer out of a nitride semiconductor layer containing Al, is achieved in a preferable way when use is made of a non-polar substrate having the m plane, the a plane, or the like as the principal growth plane. This, it has been found out, is more preferable because, then, using a substrate having an off angle in the a-axis direction relative to the m plane, which permits formation of a nitride semiconductor layer containing Al with satisfactory flatness and satisfactory crystallinity, it is possible even to give the EL emission pattern extremely good uniformity.

Subsequently, by use of a plurality of GaN substrates with different off-angles in the a- and c-axis directions, a plurality of chips like the light-emitting diode chip 200 shown in FIG. 21 were fabricated, and were subjected to experiments including inspection of the EL emission pattern.

The results reveal that providing an off-angle in the a-axis direction relative to the m plane gives an effect of suppressing a bright-spotted EL emission pattern. It is found out that, whereas the effect of suppressing bright-spotted emission is weak with the off-angle in the a-axis direction in the range of 0.1 degrees or smaller, the effect of suppressing a bright-spotted EL emission pattern is prominent with the off-angle in the a-axis direction equal to 0.1 degrees or larger. Thus, it is confirmed that by using as the principal growth plane of a GaN substrate a plane having an off-angle in the a-axis direction relative to the m plane, it is possible to suppress a bright-spotted EL emission pattern. It is also confirmed that making the off angle in the a-axis direction larger than the off angle in the c-axis direction helps suppress a bright-spotted EL emission pattern more effectively.

### Practical Example 1

As a nitride semiconductor laser chip according to Practical Example 1, a nitride semiconductor laser chip similar to the one according to Embodiment 1 described above was fabricated by use of a GaN substrate having an off-angle of 1.7 degrees in the a-axis direction and an off-angle of +0.1 degrees in the c-axis direction relative to the m plane {1-100}. In other respects, the structure of Practical Example 1 was similar to that of Embodiment 1 described above. Another nitride semiconductor laser chip fabricated in a similar manner to the one according to Embodiment 1 described above but by using a GaN substrate having no off-angle (an m-plane just substrate) was taken as Comparative Example 1. In other respects, the structure of the nitride semiconductor laser chip of Comparison Example 1 was similar to that of Embodiment 1.

With respect to Practical Example 1 and Comparison Example 1, the threshold current was measured. Whereas with the nitride semiconductor laser chip of Comparison Example 1 the value of the threshold current was about 100 mA, with the nitride semiconductor laser chip of Practical Example 1 the value of the threshold current was 60 mA; thus, it was confirmed that the threshold current was far lower with the nitride semiconductor laser chip of Practical Example 1 than with that of Comparison Example 1. The reason is considered to be that suppressed bright-spotted emission leads to uniform light emission across the plane and hence a higher gain. Also with regard to the driving voltage, it was confirmed that the driving voltage as observed when a current of 50 mA was injected was about 0.4 V lower with the nitride semiconductor laser chip of Practical Example 1 than with that of Comparison Example 1. One reason for these results is considered to be that using as the principal growth plane of a GaN substrate a plane having an off-angle in the a-axis direction relative to the m plane changes how Mg is absorbed into the p-type semiconductor layers in such a way as to enhance the activation rate. The emission wavelength of the nitride semiconductor laser chip according to Embodiment 1 was 505 nm. The reason that lasing was possible with a comparatively low threshold current density even in lasing at a long wavelength of 500 nm or more is considered to be that surface morphology was improved and film flatness too was improved.

### Embodiment 2

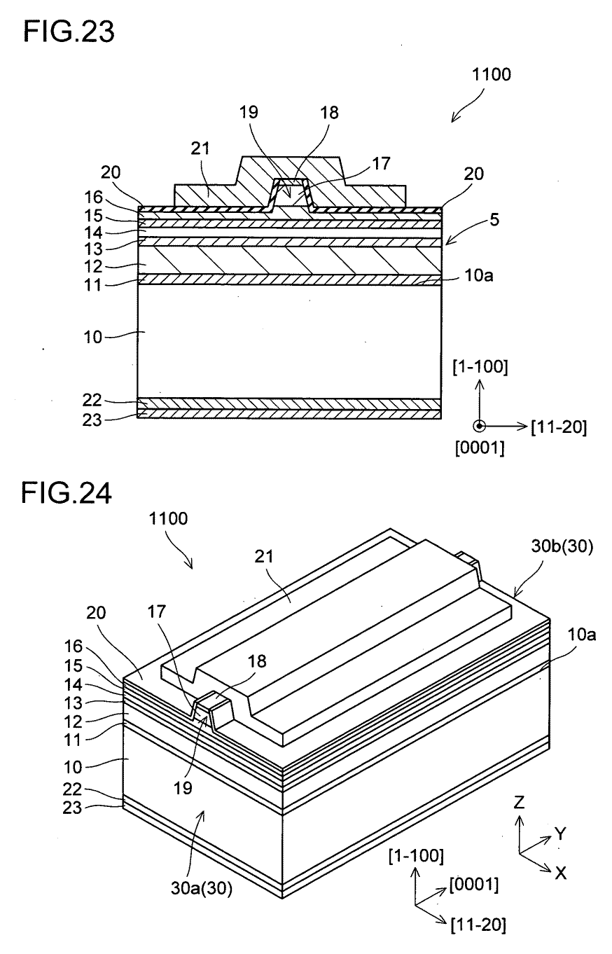

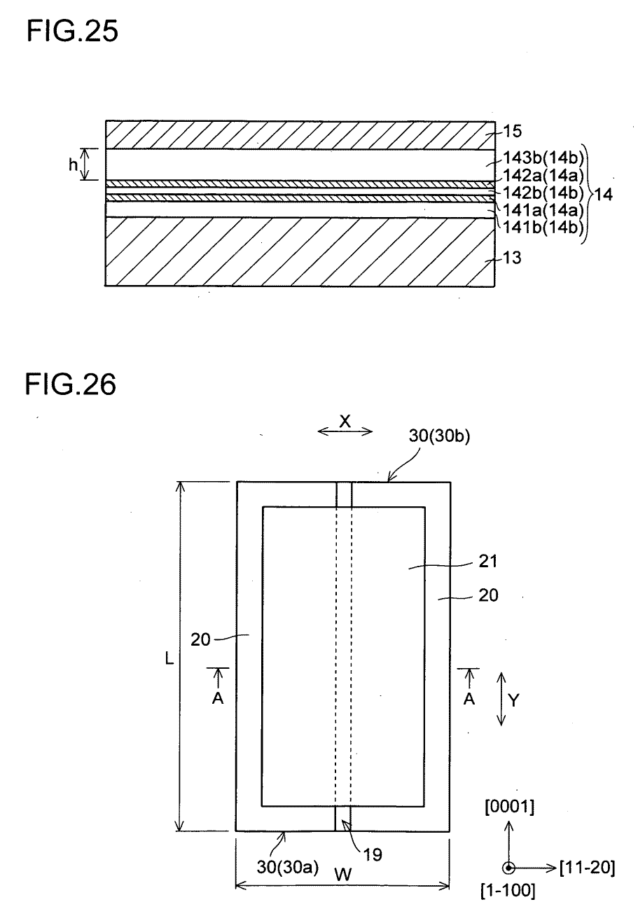

FIG. 23 is a sectional view showing the structure of a nitride semiconductor laser chip according to a second embodiment (Embodiment 2) of the invention. FIG. 24 is an overall perspective view of the nitride semiconductor laser chip according to Embodiment 2 of the invention. FIGS. 25 and 26 are diagrams illustrating the structure of the nitride semiconductor laser chip according to Embodiment 2 of the invention. Next, with reference to FIGS. 23 to 26, the structure of the nitride semiconductor laser chip 1100 according to Embodiment 2 of the invention will be described.

As shown in FIGS. 23 and 24, the nitride semiconductor laser chip 1100 according to Embodiment 2 is formed by use of a GaN substrate 10 similar to that in Embodiment 1 described previously, and has a plurality of nitride semiconductor layers stacked on the principal growth plane 10a of the GaN substrate 10. That is, in Embodiment 2, as in Embodiment 1 described previously, on the principal growth plane 10a of the GaN substrate 10, a nitride semiconductor stacked structure 5 having a plurality of nitride semiconductor layers stacked together is formed.

Specifically, in the nitride semiconductor laser chip 1100 according to Embodiment 2, on the principal growth plane 10a of the GaN substrate 10, an n-type GaN layer 11 with a thickness of about 0.1 μm is formed. On the n-type GaN layer 11, a lower clad layer 12 of n-type Al_{0.06}Ga_{0.94}N with a thickness of about 2.2 μm is formed. On the lower clad layer 12, a lower guide layer 13 of n-type GaN with a thickness of about 0.1 μm is formed. On the lower guide layer 13, an active layer 14 is formed.

As shown in FIG. 25, the active layer 14 has a quantum well (DQW, double quantum well) structure having two well layers 14a of Inₓ₁Ga₁₋ₓ₁N and three barrier layers 14b of Alₓ₂Ga₁₋ₓ₂N stacked alternately. Specifically, the active layer 14 is formed by successively stacking, from the lower guide layer 13 side, a first barrier layer 141b, a first well layer 141a, a second barrier layer 142b, a second well layer 142a, and a third barrier layer 143b. The two well layers 14a (first and second well layers 141a and 142a) are each formed to have a thickness of about 3 nm to 4 nm. The first barrier layer 141b is formed to have a thickness of about 30 nm, the second barrier layer 142b is formed to have a thickness of about 16 nm, and the third barrier layer 143b is formed to have a thickness of about 60 nm. Thus, the three barrier layers 14b are each formed to have a different thickness.

The barrier layers may be formed of AlInGaN instead of AlGaN. This applies also to Embodiment 1 described previously. A barrier layer containing Al and In offers the advantage of easy formation of a film with high flatness at low temperature. Moreover, in a case where two or more well layers are provided, when a GaN layer is not used as a barrier layer interposed between well layers (in Embodiment 2, the second barrier layer), the barrier layer may be given a two-layer structure such as AlGaN/AlInGaN, AlInGaN/AlGaN, or the like, or a multiple-layer structure such as AlInGaN/AlGaN/AlInGaN, AlInGaN/InGaN/AlInGaN, AlGaN/InGaN/AlGaN, or the like. In a case where one well layer is provided, it is preferable that the layer in contact with it from above (on the opposite side of it from the substrate, specifically the second barrier layer) be an AlInGaN layer. By forming the barrier layer in that way, it is possible to effectively suppress development of dark lines.

Here, in Embodiment 2, as described above, the structure is such that the total thickness of the GaN layer formed between the principal growth plane 10a of the GaN substrate 10 and the active layer 14 (well layers 14a) is 0.7 μm or less. Specifically, between the principal growth plane 10a of the GaN substrate 10 and the active layer 14 (well layers 14a), as described above, two GaN layers (the n-type GaN layer 11 and the lower guide layer 13) are formed, and their total thickness is about 0.2 μm (=about 0.1 μm+about 0.1 μm). It is more preferable that the total thickness of the GaN layer be 0.5 μm or less, and further preferably 0.3 μm or less. In Embodiment 2, the semiconductor layer in contact with the principal growth plane 10a of the GaN substrate 10 is a GaN layer.

In Embodiment 2, the well layers 14a (active layer 14) constituting the active layer 14 are formed to have an In composition ratio x1 of 0.15 or more but 0.45 or less (for example, from 0.2 to 0.25). The barrier layers 14b of the active layer 14 are formed of AlGaN (Alₓ₂Ga₁₋ₓ₂N), and are given an Al composition ratio x2 of, for example, 0<x2≦0.08. Giving the barrier layers 14b, which are formed of AlGaN (Alₓ₂Ga₁₋ₓ₂N), an Al composition ratio x2 of 0.08 or less makes efficient light confinement possible. Moreover, forming the barrier layers 14b out of AlGaN helps enhance luminous efficacy.

The reasons that forming the barrier layers 14b out of AlGaN, AlInGaN, or the like enhances luminous efficacy are considered to be as follows. With a nitride semiconductor substrate having as the principal growth plane a plane having an off angle in the a-axis direction relative to the m plane, as described above, whereas forming a GaN layer with a thickness over 1 μm on its principal growth plane tends to degrade surface morphology, forming a nitride semiconductor layer containing Al (for example an AlGaN layer, an AlInGaN layer, an AlInN layer, or the like) improves surface morphology. Accordingly, forming a barrier layer in an active layer out of a nitride semiconductor containing Al (for example an AlGaN layer, an AlInGaN layer, an AlInN layer, or the like) enhances the flatness of the barrier layer, and forming a well layer on the barrier layer with high flatness enhances the crystallinity of the well layer. Moreover, forming the barrier layer in that way makes it possible to effectively suppress development of dark lines. In a case where the barrier layer in the active layer is formed of a nitride semiconductor layer containing Al (for example an AlGaN layer, an AlInGaN layer, an AlInN layer, or the like), it is preferable that, as described above, the well layer be formed of InGaN.

As shown in FIGS. 23 and 24, on the active layer 14, a carrier block layer 15 of p-type Al_{y}Ga_{1-y}N with a thickness of 40 nm or less (for example, about 12 nm) is formed. The carrier block layer 15 is formed to have an Al composition ratio y of 0.08 or more but 0.35 or less (for example, about 0.15). On the carrier block layer 15, an upper guide layer 16 of p-type Al_{0.01}Ga_{0.99}N is formed which has an elevated portion and, elsewhere than there, a flat portion. The upper guide layer 16 is formed to have a lower Al composition ratio than a clad layer. On the elevated portion of the upper guide layer 16, an upper clad layer 17 of p-type Al_{0.06}Ga_{0.94}N with a thickness of about 0.5 μm is formed. On the upper clad layer 17, a contact layer 18 of p-type Al_{0.01}Ga_{0.99}N with a thickness of about 0.1 μm is formed. Together the contact layer 18, the upper clad layer 17, and the elevated portion of the upper guide layer 16 constitute a stripe-shaped (elongate) ridge portion 19 with a width of about 1 μm to 10 μm (for example, about 1.5 μm). As shown in FIG. 26, the ridge portion 19 is formed so as to extend in the Y direction (approximately the c-axis [0001] direction). The p-type semiconductor layers (the carrier block layer 15, the upper guide layer 16, the upper clad layer 17, and the contact layer 18) are doped with Mg as a p-type impurity.

It is preferable to form the contact layer out of a nitride semiconductor layer containing Al (for example, AlGaN, AlInGaN, or AlInN), because doing so helps enhance surface morphology and improve the thickness distribution across the plane.

Moreover, in the nitride semiconductor laser chip 1100 according to Embodiment 2, as shown in FIGS. 23 and 24, on each side of the ridge portion 19, an insulating layer 20 for current constriction is formed. Specifically, on top of the upper guide layer 16, on the side faces of the upper clad layer 17, and on the side faces of the contact layer 18, an insulating layer 20 of SiO₂ with a thickness of about 0.1 μm to 0.3 μm (for example, about 0.15 μm) is formed.

On the top faces of the insulating layer 20 and of the contact layer 18, a p-side electrode 21 is formed so as to cover part of the contact layer 18. The p-side electrode 21, in its part covering the contact layer 18, makes direct contact with the contact layer 18. The p-side electrode 21 has a multiple-layer structure having the following layers stacked successively in order from the insulating layer 20 (the contact layer 18) side: a Pd layer (unillustrated) with a thickness of about 15 nm; a Pt layer (unillustrated) with a thickness of about 15 nm; and a Au layer (unillustrated) with a thickness of about 200 nm.

On the back face of the GaN substrate 10, an n-side electrode 22 is formed, which has a multiple-layer structure having the following layers stacked successively in order from the GaN substrate 10's back face side: a Hf layer (unillustrated) with a thickness of about 5 nm; and an Al layer (unillustrated) with a thickness of about 150 nm. On the n-side electrode 22, a metallized layer 23 is formed, which has a multiple-layer structure having the following layers stacked successively in order from the n-side electrode 22 side: a Mo layer (unillustrated) with a thickness of about 36 nm; a Pt layer (unillustrated) with a thickness of about 18 nm; and a Au layer (unillustrated) with a thickness of about 200 nm.

As shown in FIGS. 24 and 26, the nitride semiconductor laser chip 1100 according to Embodiment 2 has a pair of resonator (cavity) faces 30, which include a light emission face 30a from which laser light is emitted and a light reflection face 30b opposite from the light emission face 30a. On the light emission face 30a, an emission-side coating (unillustrated) with a reflectance of, for example, 5% to 80% is formed. On the other hand, on the light reflection face 30b, a reflection-side coating (unillustrated) with a reflectance of, for example, 95% is formed. The reflectance of the emission-side coating is adjusted to be a desired value according to the laser output. The emission-side coating is composed of, in order from the semiconductor's emission facet side, for example, a film of aluminum oxynitride (oxide-nitride) or aluminum nitride AlOₓN₁₋ₓ (where 0≦x≦1) with a thickness of 30 nm, and a film of Al₂O₃ with a thickness of 215 nm. The reflection-side coating is composed of multiple-layered films of, for example, SiO₂, TiO₂, etc. Other than the materials just mentioned, films of dielectric materials such as SiN, ZrO₂, Ta₂O₅, MgF₂, etc. may be used. The coating on the light emission face side may instead be composed of a film of AlOₓN₁₋ₓ (where 0≦x≦1) with a thickness of 12 nm, and a film of silicon nitride SiN with a thickness of 100 nm.

By forming a film of aluminum oxynitride or aluminum nitride AlOₓN₁₋ₓ (where 0≦x≦1) on a cleaved facet (in Embodiment 2, the c plane), or an etched facet etched by vapor-phase etching or liquid-phase etching, of an m-plane nitride semiconductor substrate as described above, it is possible to greatly reduce the rate of non-radiative recombination at the interface between the semiconductor and the emission-side coating, and thereby to greatly improve the COD (catastrophic optical damage) level. More preferably, the film of aluminum oxynitride or aluminum nitride AlOₓN₁₋ₓ (where 0≦x≦1) has a crystal of the same hexagonal crystal system as the nitride semiconductor; further preferably, it is crystallized with its crystal axes aligned with those of the nitride semiconductor, because that further reduces the rate of non-radiative recombination and further improves the COD level. To increase the reflectance on the light emission face side, there may be formed, on the above-mentioned coating, stacked films having films of silicon oxide, aluminum oxide, titanium oxide, tantalum oxide, zirconium oxide, silicon oxide, etc. stacked together.

As shown in FIG. 26, the nitride semiconductor laser chip 1100 according to Embodiment 2 has a length L (chip length L (resonator length L)) of about 300 μm to 1800 μm (for example, about 600 μm) in the direction (the Y direction (approximately the c-axis [0001] direction)) perpendicular to the resonator faces 30, and has a width W (chip width W) of about 150 μm to about 600 μm (for example, about 400 μm) in the direction (the X direction (approximately the a-axis [11-20] direction)) along the resonator faces 30.

In Embodiment 2, as described above, a plane having an off-angle in the a-axis direction relative to the m plane is taken as the principal growth plane 10a of the GaN substrate 10, and this makes it possible to suppress a bright-spotted EL emission pattern and variations in wavelength across the plane. That is, with that structure, it is possible to improve the EL emission pattern. This makes it possible to enhance the luminous efficacy of the nitride semiconductor laser chip. By enhancing luminous efficacy, it is possible to obtain a high-luminance nitride semiconductor laser chip. One reason that an effect of suppressing bright-spotted emission as described above is obtained is considered to be as follows: as a result of the principal growth plane 10a of the GaN substrate 10 having an off-angle in the a-axis direction relative to the m plane, when the active layer 14 (the well layers 14a) is grown on the principal growth plane 10a, the direction of migration of In atoms changes so that, even under conditions with a high In composition ratio (with a large supply of In), agglomeration of In is suppressed. Another reason is considered to be that the growth mode of the p-type nitride semiconductor layers formed on the active layer 14 also changes so as to enhance the activation rate of Mg as a p-type impurity and reduce the resistance of the p-type nitride semiconductor layers. Reducing the resistance of the p-type nitride semiconductor layers makes uniform injection of current easier, and thus makes the EL emission pattern uniform.

In Embodiment 2, by suppressing a bright-spotted EL emission pattern, it is possible to make the EL emission pattern uniform, and thus it is possible to reduce the driving voltage. Incidentally, by suppressing bright-spotted emission, it is possible to obtain a uniform EL emission pattern, and thus it is possible to increase gain in the formation of the nitride semiconductor laser chip.

In Embodiment 2, with the structure described above, it is possible to suppress a bright-spotted EL emission pattern, and thus it is possible to enhance luminous efficacy. This makes it possible to enhance device characteristics and reliability. That is, it is possible to obtain a nitride semiconductor laser chip with superb device characteristics and high reliability.

In Embodiment 2, on the GaN substrate 10 having as the principal growth plane 10a a plane having an off angle in the a-axis direction relative to the m plane, the GaN layer formed between the principal growth plane 10a and the active layer 14 (well layers 14a) is formed to have a total thickness of 0.7 μm or less (0.2 μm), and this makes it possible to greatly improve surface morphology and obtain good surface morphology. In this way, it is possible to give the GaN layer (the n-type GaN layer 11 and the lower guide layer 13) a uniform thickness distribution across the plane, and also to give the semiconductor layer formed further on the GaN layer a uniform thickness distribution across the plane. That is, it is possible to give the individual nitride semiconductor layers formed on the GaN substrate 10 a uniform thickness distribution across the plane. Moreover, by improving surface morphology, it is possible to reduce variations in device characteristics (for example, I-L response, I-V response, far-field pattern, wavelength, etc.), and thus it is possible to increase manufacturing yields. This makes it possible to easily obtain chips having characteristics within the rated ranges. Moreover, by enhancing surface morphology, it is possible to further enhance device characteristics and reliability.

In Embodiment 2, by making the absolute value of the off angle in the a-axis direction larger than 0.1 degrees, it is possible to suppress a bright-spotted EL emission pattern easily.

In a case where the principal growth plane 10a of the GaN substrate 10 has an off-angle also in the c-axis direction relative to the m plane, by making the off-angle in the a-axis direction larger than the off-angle in the c-axis direction, it is possible to effectively suppress a bright-spotted EL emission pattern. That is, with that structure, it is possible to suppress the inconvenience of the effect of suppressing bright-spotted emission being diminished due to too large an off-angle in the c-axis direction. Thus, it is possible to enhance luminous efficacy easily.

In Embodiment 2, by forming the barrier layers 14b of the active layer 14 out of AlGaN, it is possible to enhance the flatness of the barrier layers 14b. Thus, by forming the well layers 14a on the barrier layers 14b with high flatness, it is possible to enhance the crystallinity of the well layers 14a, and to suppress In layer separation or the like in the well layers. It is thus possible to further enhance luminous efficacy.

In Embodiment 2, giving the active layer 14 of the nitride semiconductor laser chip 1100 a DQW structure makes it possible to reduce the driving voltage easily. This too helps enhance device characteristics and reliability. Even when the active layer 14 is given a DQW structure, it is possible to suppress a bright-spotted EL emission pattern. In a case where the above-described GaN substrate 10 having a principal growth plane 10a provided with an off-angle relative to the m plane is used, giving the active layer 14 formed on the GaN substrate 10 a DQW structure, as compared with giving the active layer 14a multiple quantum well (MQW) structure, helps enhance luminous efficacy. This makes it possible to obtain a high-luminance nitride semiconductor laser chip easily.

In Embodiment 2, by giving the carrier block layer 15 formed of p-type Al_{y}Ga_{1-y}N an Al composition ratio y of 0.08 or more but 0.35 or less, it is possible to form an energy barrier sufficiently high with respect to carriers (electrons), and thus it is possible to more effectively prevent the carriers injected into the active layer 14 from flowing into the p-type nitride semiconductor layers. This makes it possible to suppress a bright-spotted EL emission pattern effectively. Giving the carrier block layer 15 an Al composition ratio y of 0.35 or less helps suppress an increase in the resistance of the carrier block layer 15 due to the Al composition ratio y being too high. Incidentally, in a region with a high In composition ratio x1 (x1≧0.15) in the well layers 14a, an Al composition ratio y of 0.08 or more in the carrier block layer 15 formed on the active layer 14 makes it extremely difficult to grow the carrier block layer 15 satisfactorily. This is because, as the In concentration in the well layers 14a increases, the flatness of the surface of the active layer 14 deteriorates, and this makes it difficult to form a film with a high Al composition ratio y with good crystallinity. However, by use of the GaN substrate 10 having as the principal growth plane 10a a plane having an off-angle in the a-axis direction relative to the m plane, even in a case where the In composition ratio x1 in the active layer 14 (the well layers 14a) is 0.15 or more but 0.45 or less, it is possible to form on that active layer 14 a carrier block layer 15 with an Al composition ratio y of 0.08 or more but 0.35 or less with good crystallinity. This makes it possible to suppress a bright-spotted EL emission pattern effectively and make the EL emission pattern even.

By use of the above-described GaN substrate 10 having a principal growth plane 10a provided with an off-angle in the a-axis direction relative to the m plane, even in a case where the In composition ratio x1 in the well layers 14a is 0.15 or more, that is, even under conditions where a bright-spotted EL emission pattern is prominent, it is possible to effectively suppress a bright-spotted EL emission pattern. Thus, by giving the well layers 14a of the active layer 14 an In composition ratio x1 of 0.15 or more, it is possible to obtain a prominent effect of suppressing bright-spotted emission. On the other hand, by giving the well layers 14a an In composition ratio x1 of 0.45 or less, it is possible to effectively suppress the inconvenience of a large number of dislocations developing in the active layer 14 as a result of strain such as lattice mismatch due to the In composition ratio x1 in the well layers 14a being more than 0.45.

In Embodiment 2, the barrier layers 14b formed under (on the GaN substrate 10 side of) the well layers 14a is formed of a nitride semiconductor layer containing Al (for example, Alₓ₂Ga₁₋ₓ₂N), and is given an Al composition ratio x2 in the range of 0<x2≦0.08; this offers effects such as an effect of enhancing the flatness of the barrier layers 14b and suppressing development of dark lines. This makes it possible to enhance the luminous efficacy of the well layers 14a, and thus it is possible to obtain a semiconductor laser chip with superb device characteristics and high reliability.

Incidentally, setting the distance h between the carrier block layer 15 and the well layers 14a to be 200 nm or more permits current to spread when carriers diffuse from the carrier block layer 15 to the active layer 14, and thus helps slightly suppress bright-spotted emission. On the other hand, by the use of the above-described GaN substrate 10 having a principal growth plane 10a provided with an off-angle relative to the m plane, even when the distance h between the carrier block layer 15 and the well layers 14a is not set to be 200 nm or more, it is possible to suppress bright-spotted emission effectively. For example, even when the distance h between the carrier block layer 15 and the well layers 14a is set to be less than 120 nm, it is possible to suppress bright-spotted emission effectively. The smaller the distance h between the carrier block layer 15 and the well layers 14a, the more preferable, because that enhances the efficiency of carrier injection into the well layers 14a. Accordingly, by making the distance h between the carrier block layer 15 and the well layers 14a smaller than 120 nm, it is possible to enhance the efficiency of carrier injection into the well layers 14a.

It is more preferable that the barrier layer (for example, in Embodiment 2, the third barrier layer) between the carrier block layer 15 and the well layers 14a be a nitride semiconductor layer containing Al and In. The carrier block layer is formed with a higher Al composition ratio than the barrier layer, and thus stress from the carrier block layer acts on the well layer. Forming a barrier layer containing In between the carrier block layer 15 and the well layers 14a, therefore, is preferable, because doing so helps mitigate stress. Moreover, it is preferable that the barrier layer between the carrier block layer 15 and the well layers 14a partly contain AlInGaN. Furthermore, the barrier layer between the carrier block layer 15 and the well layers 14a may be given a two-layer structure such as AlGaN/AlInGaN, AlInGaN/AlGaN, or AlInGaN/InGaN, or a multiple-layer structure such as AlInGaN/AlGaN/AlInGaN, AlInGaN/InGaN/AlInGaN, AlGaN/InGaN/AlGaN, or the like. From the viewpoint of the above-mentioned mitigation of stress, the barrier layer between the carrier block layer 15 and the well layers 14a may be InGaN. Forming the barrier layer in that way helps effectively suppress development of dark lines.

The effect of suppressing development of dark lines, which is obtained by forming a barrier layer out of a nitride semiconductor layer containing Al, is an utterly different one from the effect of suppressing bright-spotted emission, which is obtained by use of a nitride semiconductor substrate having as the principal growth plane a plane having an off angle in the a-axis direction relative to the m plane. Specifically, using a nitride semiconductor layer containing Al as a barrier layer is effective with a non-polar plane such as the m plane; on the other hand, even in a case where a barrier layer of InGaN is used, by providing an off angle in the a-axis direction, it is possible to suppress a bright-spotted EL emission pattern. However, forming a nitride semiconductor layer containing Al on a nitride semiconductor substrate having an off angle in the a-axis direction offers an effect of enhancing crystallinity etc., and thus using a nitride semiconductor substrate having an off angle in the a-axis direction and in addition using a nitride semiconductor layer containing Al as a barrier layer enhances the crystallinity of the barrier layer. Combining the two designs in this way is thus preferable, because doing so brings about an effect of synergy. Needless to say, using a nitride semiconductor substrate having an off angle in the a-axis direction and in addition using a nitride semiconductor layer containing Al as a barrier layer makes it possible to suppress development of dark lines and in addition to suppress bright-spotted emission.

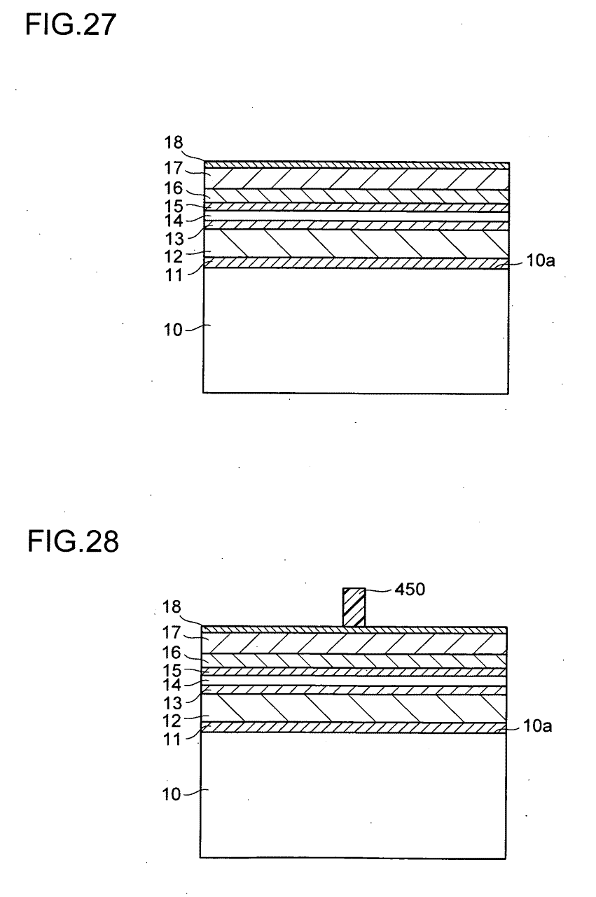

FIGS. 27 to 34 are diagrams illustrating a method of manufacture of the nitride semiconductor laser chip according to Embodiment 2 of the invention. Next, with reference to FIGS. 23 to 34, a method of manufacture of the nitride semiconductor laser chip 1100 according to Embodiment 2 of the invention will be described.

First, a GaN substrate 10 having as a principal growth plane 10a a plane having an off-angle relative to the m plane is prepared. This GaN substrate 10 can be fabricated by a method similar to that in Embodiment 1 described previously.

Next, as shown in FIG. 27, on the principal growth plane 10a of the GaN substrate 10, by an MOCVD process, individual nitride semiconductor layers are grown. At this time, the individual nitride semiconductor layers are grown in such a way that the total thickness of the GaN layer formed between the GaN substrate 10 and the active layer 14 (well layers 14a) is 0.7 μm or less.

Specifically, on the principal growth plane 10a of the GaN substrate 10, the following layers are grown successively: an n-type GaN layer 11 with a thickness of about 0.1 μm; a lower clad layer 12 of n-type Al_{0.06}Ga_{0.94}N with a thickness of about 2.2 μm; a lower guide layer 13 of n-type GaN with a thickness of about 0.1 μm; and an active layer 14. When the active layer 14 is grown, as shown in FIG. 25, two well layers 14a of Inₓ₁Ga₁₋ₓ₁N and three barrier layers 14b of Alₓ₂Ga₁₋ₓ₂N are alternately grown. Specifically, on the lower guide layer 13, the following layers are grown successively from bottom up: a first barrier layer 141b with a thickness of about 30 nm; a first well layer 141a with a thickness of about 3 nm to 4 nm; a second barrier layer 142b with a thickness of about 16 nm; a second well layer 142a with a thickness of about 3 nm to 4 nm; and a third barrier layer 143b with a thickness of about 60 nm. In this way, on the lower guide layer 13, an active layer 14 having a DQW structure composed of two well layers 14a and three barrier layers 14b is formed. At this time, the well layers 14a are so formed that the In composition ratio x1 there is 0.15 or more but 0.45 or less (for example, 0.2 to 0.25). On the other hand, the barrier layers 14b are so formed that the Al composition ratio x2 there is, for example, in the range of 0<x2≦0.08.

Next, as shown in FIG. 27, on the active layer 14, the following layers are grown successively: a carrier block layer 15 of p-type Al_{y}Ga_{1-y}N; an upper guide layer 16 of p-type Al_{0.01}Ga_{0.99}N with a thickness of about 0.05 μm; an upper clad layer 17 of p-type Al_{0.06}Ga_{0.94}N with a thickness of about 0.5 μm; and a contact layer 18 of p-type Al_{0.01}Ga_{0.99}N with a thickness of about 0.1 μm. At this time, it is preferable that the carrier block layer 15 be formed so as to have a thickness of 40 nm or less (for example, about 12 nm). Moreover, the carrier block layer 15 is so formed that the Al composition ratio y there is 0.08 or more but 0.35 or less (for example, about 0.15). The n-type semiconductor layers (the n-type GaN layer 11, the lower clad layer 12, and the lower guide layer 13) are doped with, for example, Si as an n-type impurity, and the p-type nitride semiconductor layers (the carrier block layer 15, the upper guide layer 16, the upper clad layer 17, and the contact layer 18) are doped with, for example, Mg as a p-type impurity.

In Embodiment 2, the n-type semiconductor layers are formed at a growth temperature of 900° C. or higher but lower than 1300° C. (for example, 1075° C.). The well layers 14a of the active layer 14 are formed at a growth temperature of 600° C. or higher but 800° C. or lower (for example, 700° C.). The barrier layers 14b, which are contiguous with the well layers 14a, are formed at the same growth temperature (for example, 700° C.) as the well layers 14a. The p-type nitride semiconductor layers are formed at a growth temperature of 700° C. or higher but lower than 900° C. (for example, 880° C.). The growth temperature of the n-type semiconductor layers is preferably 900° C. or higher but lower than 1300° C., and more preferably 1000° C. or higher but lower than 1300° C. The growth temperature of the well layers 14a of the active layer 14 is preferably 600° C. or higher but 830° C. or lower, and in a case where the In composition ratio x1 in the well layers 14a is 0.15 or more, preferably 600° C. or higher but 770° C. or lower; more preferably, 630° C. or higher but 740° C. or lower. The growth temperature of the barrier layers 14b of the active layer 14 is preferably the same as or higher than that of the well layers 14a. The growth temperature of the p-type nitride semiconductor layers is preferably 700° C. or higher but lower than 900° C., and more preferably 700° C. or higher but 880° C. or lower. Needless to say, since even forming the p-type nitride semiconductor layers at a temperature of 900° C. or higher gives p-type conductivity, the p-type nitride semiconductor layers may be formed at a temperature of 900° C. or higher.

As source materials for the growth of these nitride semiconductors, for example, the following materials can be used: as a source material of Ga, trimethylgallium ((CH₃)₃Ga; TMGa); as a source material of Al, trimethylaluminium ((CH₃)₃Al; TMAl); as a source material of In, trimethylindium ((CH₃)₃In; TMIn); as a source material of N, NH₃. As a carrier gas, for example, H₂ can be used. As for dopants, as an n-type dopant (n-type impurity), for example, monosilane (SiH₄) can be used; as a p-type dopant (p-type impurity), for example, cyclopentadienylmagnesium (CP₂Mg) can be used.

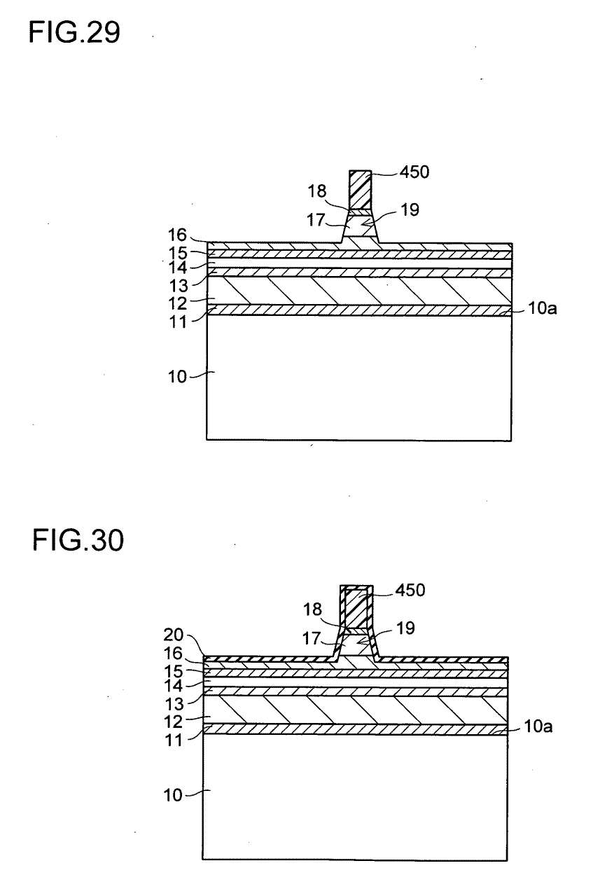

Next, as shown in FIG. 28, by use of a photolithography technology, on the contact layer 18, a stripe-shaped (elongate) resist layer 450 is formed that has a width of about 1 μm to 10 μm (for example, about 1.5 μm) and that extends parallel to the Y direction (approximately the c-axis [0001] direction). Then, as shown in FIG. 29, by a RIE (reactive ion etching) process using chlorine-based gas such as SiCl₄ or Cl₂ or Ar gas, and with the resist layer 450 used as a mask, etching is performed halfway into the depth of (meaning, so as to leave a small part of, and thus not to completely penetrate) the upper guide layer 16. In this way, a stripe-shaped (elongate) ridge portion 19 (see FIGS. 24 and 26) is formed which is constituted by an elevated portion of the upper guide layer 16, the upper clad layer 17, and the contact layer 18 and which extends parallel to the Y direction (approximately the c-axis direction), with each ridge portion 19 parallel to another.

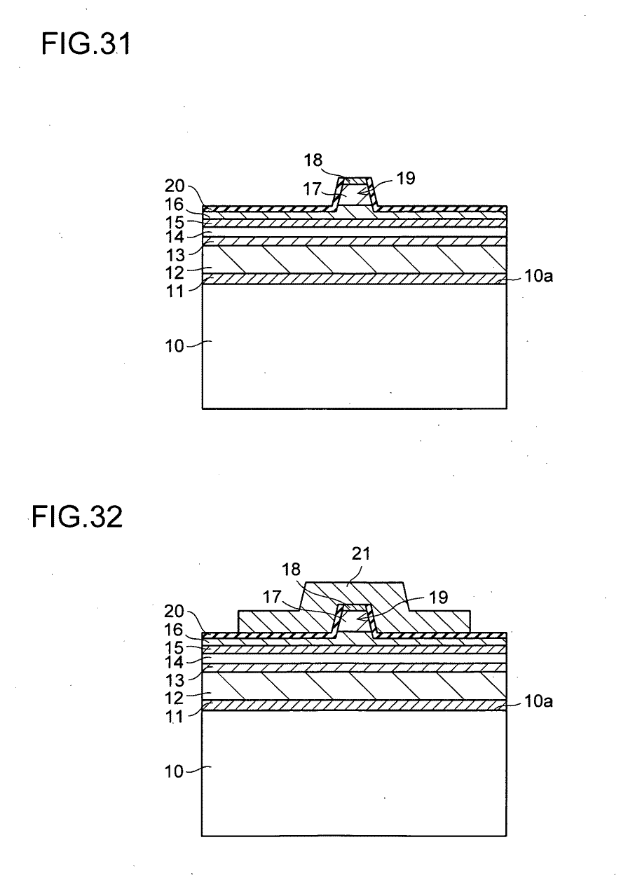

Subsequently, as shown in FIG. 30, with the resist layer 450 left on the ridge portion 19, by a sputtering process or the like, an insulating layer 20 of SiO₂ with a thickness of about 0.1 μm to 0.3 μm (for example, about 0.15 μm) is formed to bury the ridge portion 19. Then, the resist layer 450 is removed by lift-off so that the contact layer 18 at the top of the ridge portion 19 is exposed. In this way, on each side of the ridge portion 19, an insulating layer 20 as shown in FIG. 31 is formed.

Next, as shown in FIG. 32, by a vacuum deposition process or the like, the following layers are formed successively from the substrate side (the insulating layer 20 side): a Pd layer (unillustrated) with a thickness of about 15 μm; and a Au layer (unillustrated) with a thickness of about 200 nm. Thus, on the insulating layer 20 (the contact layer 18), a p-side electrode 21 having a multiple-layer structure is formed.

Next, to make the substrate easy to split, the back face of the GaN substrate 10 is ground or polished until the thickness of the GaN substrate 10 is reduced to about 100 μm. Thereafter, as shown in FIG. 23, on the back face of the GaN substrate 10, by a vacuum deposition process or the like, the following layers are formed successively from the GaN substrate 10's back face side: a Hf layer (unillustrated) with a thickness of about 5 nm; and an Al layer (unillustrated) with a thickness of about 150 nm. Thus, an n-side electrode 22 having a multiple-layer structure is formed. Then, on the n-side electrode 22, the following layers are formed successively from the n-side electrode 22 side: a Mo layer (unillustrated) with a thickness of about 36 nm; a Pt layer (unillustrated) with a thickness of about 18 nm; and a Au layer (unillustrated) with a thickness of about 200 nm. Thus, a metallized layer 23 having a multiple-layer structure is formed. Before the n-side electrode 22 is formed, dry etching or wet etching may be performed for the purpose of, for example, adjusting the n-side electrical characteristics.

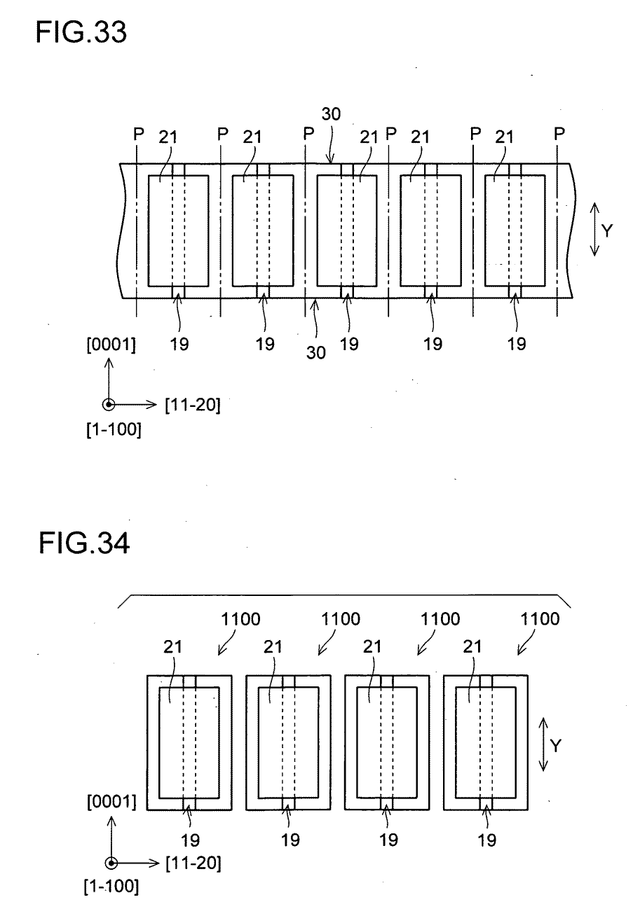

Subsequently, as shown in FIG. 33, by a technique such as a scribing-breaking process or laser scribing, the wafer is split into bars. This produces a bar-shaped array of chips having resonator faces 30 at the split facets. Next, by a technique such as a vacuum deposition process or a sputtering process, a coating is applied to the facets (resonator faces 30) of the bar-shaped array of chips. Specifically, on one of the facets which will serve as a light emission face, an emission-side coating (unillustrated) of, for example, a film of aluminum oxynitride or the like is formed. On the facet opposite from it, which will serve as a light reflection face, a reflection-side coating (unillustrated) of, for example, multiple-layered films of SiO₂, TiO₂, etc. is formed.

Lastly, the bar-shaped array of chips is split along planned splitting lines P along the Y direction (approximately the c-axis [0001] direction) into separate pieces of individual nitride semiconductor laser chips as shown in FIG. 34. In this way, the nitride semiconductor laser chip 1100 according to Embodiment 2 of the invention is manufactured.

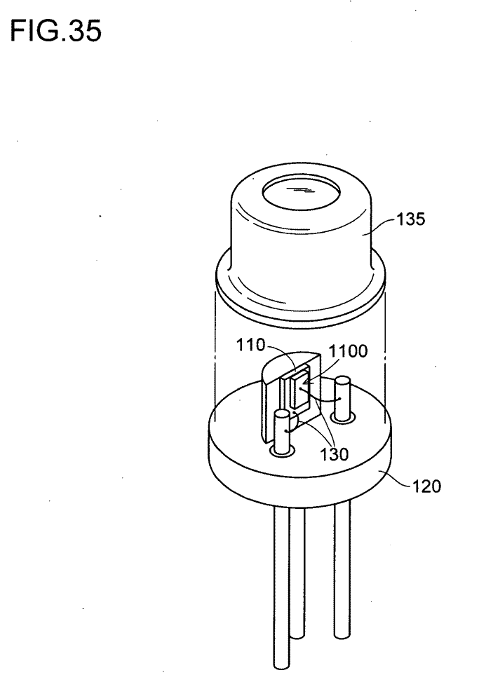

The nitride semiconductor laser chip 1100 according to Embodiment 2 manufactured as described above is, as shown in FIG. 35, mounted on a stem 120 with a sub-mount 110 interposed in between and is electrically connected to lead pins by wires 130. Then, a cap 135 is welded on the stem 120 to complete assemblage into a can-packaged semiconductor laser device (semiconductor device).

In the manufacturing method of the nitride semiconductor laser chip 1100 according to Embodiment 2, as described above, the GaN layer (the n-type GaN layer 11 and the lower guide layer 13) formed between the GaN substrate 10 and the active layer 14 (well layers 14a) is so formed as to have a total thickness of 0.7 μm or less (0.2 μm), and this makes it possible to obtain good surface morphology. In this way, it is possible to give the individual nitride semiconductor layers a uniform thickness distribution across the plane, and thus to enhance the flatness of the individual nitride semiconductor layers. Moreover, by enhancing surface morphology, it is possible to reduce variations in device characteristics, and thus to increase the number of chips having characteristics within the rated ranges. Thus, it is possible to increase manufacturing yields. By enhancing surface morphology, it is also possible to further enhance device characteristics and reliability.

In Embodiment 2, by forming the n-type semiconductor layers at a high temperature of 900° C. or higher, it is possible to give the n-type semiconductor layers a flat surface. Thus, by forming the active layer 14 and the p-type nitride semiconductor layers on the n-type semiconductor layers with a flat surface, it is possible to suppress degradation of crystallinity in the active layer 14 and the p-type nitride semiconductor layers. This too makes it possible to form a high-quality crystal. On the other hand, by forming the n-type semiconductor layers at a growth temperature lower than 1300° C., it is possible to suppress the inconvenience of the surface of the GaN substrate 10 re-evaporating and becoming rough during the raising of temperature due to the n-type semiconductor layers being formed at a growth temperature of 1300° C. or higher. Thus, with this scheme, it is possible to easily manufacture a nitride semiconductor laser chip 1100 with superb device characteristics and high reliability.

In Embodiment 2, by forming the well layers 14a of the active layer 14 at a growth temperature of 600° C. or higher, it is possible to suppress the inconvenience of a shorter atom diffusion length and hence degraded crystallinity due to the well layers 14a being formed at a growth temperature lower than 600° C. On the other hand, by forming the well layers 14a of the active layer 14 at a growth temperature of 800° C. or lower, it is possible to suppress the inconvenience of the active layer 14 being blackened by thermal damage due to the well layers 14a of the active layer 14 being formed at a growth temperature higher than 800° C. (for example, 830° C. or higher). The growth temperature of the barrier layers 14b, which are contiguous with the well layers 14a, is preferably the same as or higher than that of the well layers 14a.

In Embodiment 2, by forming the p-type nitride semiconductor layers at a growth temperature of 700° C. or higher, it is possible to suppress the inconvenience of the p-type nitride semiconductor layers having a high resistance due to their growth temperature being too low. On the other hand, by forming the p-type nitride semiconductor layers at a growth temperature lower than 1100° C., it is possible to reduce thermal damage to the active layer 14. Incidentally, forming the barrier layers out of a nitride semiconductor layer containing Al such as AlGaN or AlInGaN makes the active layer more resistant to thermal damage occurring during formation of the p-type semiconductor layers. That is, even when the p-type semiconductor layers are formed at a growth temperature of 1000° C. or higher, it is possible to suppress the active layer being blackened by thermal damage.

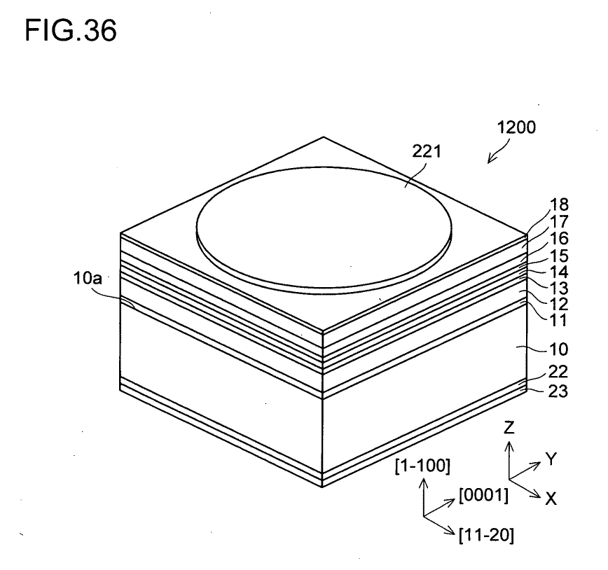

Next, a description will be given of experiments conducted to verify the effects of the nitride semiconductor laser chip 1100 according to the embodiment described above. In these experiments, first, a light-emitting diode chip 1200 as shown in FIG. 36 was fabricated as a test chip, and the EL emission pattern was inspected. The reason that a light-emitting diode chip was used for the inspection of the EL emission pattern is that, with a nitride semiconductor laser chip, which has a constricted current injection region as a result of a ridge portion being formed, it is difficult to inspect the EL emission pattern.

The test chip (light-emitting diode chip 1200) was fabricated by forming nitride semiconductor layers similar to those in the embodiment described above on a GaN substrate 10 similar to that in the embodiment described above. The formation of the nitride semiconductor layers was conducted in a similar manner as in the embodiment described above. Specifically, as shown in FIG. 36, by use of a GaN substrate 10 having as a principal growth plane 10a a plane having an off-angle relative to the m plane, on its principal growth plane 10a, the following layers were formed successively: an n-type GaN layer 11; a lower clad layer 12; a lower guide layer 13; an active layer 14; a carrier block layer 15; an upper guide layer 16; an upper clad layer 17; and a contact layer 18. Next, on the contact layer 18, a p-side electrode 221 was formed. The p-side electrode 221 was formed transparent to allow inspection of the EL emission pattern. On the back face of the GaN substrate 16, an n-side electrode 22 and a metallized layer 23 were formed. In the test chip, the GaN substrate 10 had an off-angle of 1.7 degrees in the a-axis direction and an off-angle of +0.1 degrees in the c-axis direction. In the test chip, the In composition ratio in the well layers was 0.25, and the Al composition ratio in the barrier layers was 2%. Current was injected into the thus fabricated test chip (the light-emitting diode chip 1200) to make it emit light, and the light distribution across the plane was inspected. With the test chip of Embodiment 2, an EL emission pattern similar to that in Embodiment 1 described previously (an emission pattern similar to that shown in FIG. 22) was observed.

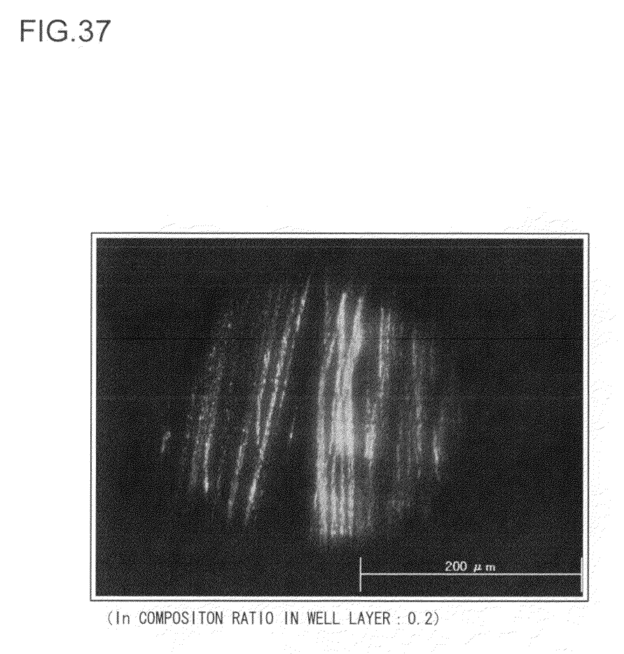

On the other hand, as a comparison chip, a light-emitting diode chip employing a GaN substrate having the m plane as a principal growth plane (substantially an m-plane just substrate, with an off angle of 0 degrees in the a-axis direction and an off angle of +0.05 degrees in the c-axis direction) was fabricated. This comparison chip was fabricated in the same manner as the test chip described above. The gas flow amount of In was the same as for the test chip, but in the comparison chip, the In composition ratio in the well layers was 0.2. In the comparison chip, the barrier layers were formed of In_{0.02}Ga_{0.98}N. As with the test chip, the light distribution across the plane was inspected. Except employing an m-plane just substrate as the GaN substrate, having an In composition ratio of 0.2 in the well layers, and having the barrier layers formed of InGaN, the comparison chip had a similar structure to the test chip (the light-emitting diode chip 1200). The EL emission pattern shown in FIG. 37 is (a microscope photograph of) the EL emission pattern observed in the comparison chip.

Whereas as shown in FIG. 37 the comparison chip exhibited a bright-spotted EL emission pattern, the test chip, despite having a higher In composition ratio in the well layers, exhibited an EL emission pattern of uniform light emission as a result of a bright-spotted EL emission pattern being suppressed. It was thus confirmed that using a GaN substrate 10 having as a principal growth plane 10a a plane having an off-angle in the a-axis direction relative to the m plane helped suppress a bright-spotted EL emission pattern. Moreover, whereas in the comparison chip with the barrier layers formed of InGaN, as in FIG. 46 referred to earlier, the PL emission pattern exhibited dark lines, in the test chip with the barrier layers formed of a nitride semiconductor layer containing Al (AlGaN), as in FIG. 47 referred to earlier, no development of dark lines was observed.

On the other hand, through measurement of luminous efficacy with the test chip and the comparison chip, it was confirmed that the luminous efficacy of the test chip was increased to 2.2 times that of the comparison chip. The emission wavelength of the test chip was 530 nm, and the emission wavelength of the comparison chip was 490 nm. It was thus confirmed that the test chip, in which the off-angle was controlled, was more efficient also in terms of In absorption than the comparison chip, which used an m-plane just substrate. The foregoing confirms that providing an off-angle in the a-axis direction relative to the m plane helps suppress bright-spotted emission and increase luminous efficacy in a wavelength region of green.

It is also confirmed that, by forming the barrier layers of the active layer out of a nitride semiconductor layer containing Al, it is possible to obtain a chip offering uniform, high luminous intensity even in a very long emission wavelength region of 530 nm. Also confirmed is that the increase in luminous intensity in a long wavelength region, which is the effect obtained by forming the barrier layers of the active layer out of a nitride semiconductor layer containing Al, is achieved in a preferable way when use is made of a non-polar substrate having the m plane, the a plane, or the like as the principal growth plane. This, it has been found out, is more preferable because, then, using a substrate having an off angle in the a-axis direction relative to the m plane, which permits formation of a nitride semiconductor layer containing Al with satisfactory flatness and satisfactory crystallinity, it is possible even to give the EL emission pattern extremely good uniformity.

Subsequently, by use of a plurality of GaN substrates with different off-angles in the a- and c-axis directions, a plurality of chips like the light-emitting diode chip 1200 shown in FIG. 36 were fabricated, and were subjected to experiments including inspection of the EL emission pattern.

The results reveal that providing an off-angle in the a-axis direction relative to the m plane gives the effect of suppressing a bright-spotted EL emission pattern. It is also found out that, whereas the effect of suppressing bright-spotted emission is weak with the off-angle in the a-axis direction in the range of 0.1 degrees or smaller, the effect of suppressing a bright-spotted EL emission pattern is prominent with the off-angle in the a-axis direction equal to 0.1 degrees or larger. Thus, it is confirmed that by using as the principal growth plane of a GaN substrate a plane having an off-angle in the a-axis direction relative to the m plane, it is possible to suppress a bright-spotted EL emission pattern. It is also confirmed that making the off angle in the a-axis direction larger than the off angle in the c-axis direction helps suppress a bright-spotted EL emission pattern more effectively.

### Practical Example 2

As a nitride semiconductor laser chip according to Practical Example 2, a nitride semiconductor laser chip similar to the one according to Embodiment 2 described above was fabricated by use of a GaN substrate having an off-angle of 1.7 degrees in the a-axis direction and an off-angle of +0.1 degrees in the c-axis direction relative to the m plane {1-100}. The In composition ratio in the well layers was 0.25, and the Al composition ratio in the barrier layers was 2%. In other respects, the structure of Practical Example 2 was similar to that of Embodiment 2 described above. Another nitride semiconductor laser chip fabricated in a similar manner to the one according to Embodiment 2 described above but by using a GaN substrate having no off-angle (an m-plane just substrate) was taken as Comparative Example 2. In other respects, the structure of the nitride semiconductor laser chip of Comparison Example 2 was similar to that of Embodiment 2.

With respect to Practical Example 2 and Comparison Example 2, the threshold current was measured. Whereas with the nitride semiconductor laser chip of Comparison Example 2 the value of the threshold current was about 120 mA, with the nitride semiconductor laser chip of Practical Example 2 the value of the threshold current was 55 mA; thus, it was confirmed that the threshold current was far lower with the nitride semiconductor laser chip of Practical Example 2 than with that of Comparison Example 2. The reason is considered to be that suppressed bright-spotted emission leads to uniform light emission across the plane and hence a higher gain. Also with regard to the driving voltage, it was confirmed that the driving voltage as observed when a current of 50 mA was injected was about 0.4 V lower with the nitride semiconductor laser chip of Practical Example 2 than with that of Comparison Example 2. One reason for these results is considered to be that using as the principal growth plane of a GaN substrate a plane having an off-angle in the a-axis direction relative to the m plane changes how Mg is absorbed into the p-type semiconductor layers in such a way as to enhance the activation rate. The emission wavelength of the nitride semiconductor laser chip according to Embodiment 2 was 505 nm. The reason that lasing was possible with a comparatively low threshold current density even in lasing at a long wavelength of 500 nm or more is considered to be that forming a GaN layer with a total thickness of 0.7 μm or less between a nitride semiconductor substrate having an off angle in the a-axis direction and an active layer (well layers) improves surface morphology and improves film flatness. It is also considered that using a nitride semiconductor layer containing Al as a barrier layer had effects such as an effect of suppressing development of dark lines.

### Practical Example 3

As a nitride semiconductor laser chip according to Practical Example 3, by use of a GaN substrate having an off angle of 4 degrees in the a-axis direction and an off angle of +1 degree in the c-axis direction relative to the m plane {1-100}, a nitride semiconductor laser chip was fabricated in which the barrier layers were formed of AlₛInₜGaᵤN (s+t+u=1). In Practical Example 3, the barrier layers were formed of AlₛInₜGaᵤN (s=0.01, t=0.03, u=0.96). That is, in Practical Example 3, the barrier layers were formed of AlInGaN. In other respects than the barrier layers, the structure of Practical Example 3 was similar to that of the embodiment (Practical Example 2) described above. Practical Example 3 offered similar effects to Practical Example 2 described above. Incidentally, in a case where the barrier layers are formed of AlₛInₜGaᵤN (s+t+u=1), it is preferable that, as in Embodiment 2 described above, the In composition be lower than the Al composition. To achieve light emission at a wavelength in a long wavelength region, the active layer needs to be formed at a low temperature of 900° C. or lower, typically about 700° C. to 800° C.; this might be, it is considered, the reason that the In content enhances crystallinity in low-temperature growth. Moreover, using an AlInGaN layer containing In as a barrier layer gives a higher index of refraction than using an AlGaN layer, and thus helps achieve efficient light confinement.

### Practical Example 4

As a nitride semiconductor laser chip according to Practical Example 4, by use of a GaN substrate having an off angle of 6 degrees in the a-axis direction and an off angle of −1.1 degrees in the c-axis direction relative to the m plane {1-100}, a nitride semiconductor laser chip was fabricated in which the barrier layers were formed of AlₛInₜGaᵤN (s+t+u=1). In Practical Example 4, the first barrier layer was formed of AlₛInₜGaᵤN (s=0.01, t=0, u=0.99), and the second and third barrier layers were formed of AlₛInₜGaᵤN (s=0.02, t=0.01, u=0.97). That is, in Practical Example 4, the first barrier layer was formed of AlGaN, and the second and third barrier layers were each formed of AlInGaN. In other respects than the barrier layers, the structure of Practical Example 4 was similar to that of the embodiment (Practical Example 2) described above. Practical Example 4 offered similar effects to Practical Example 2 described above. Incidentally, the first barrier layer may have a different composition from the second and third barrier layers as in Practical Example 4, or each barrier layer may have a different Al composition.

### Practical Example 5

As a nitride semiconductor laser chip according to Practical Example 5, by use of a GaN substrate having an off angle of 6 degrees in the a-axis direction and an off angle of +2 degrees in the c-axis direction relative to the m plane {1-100}, a nitride semiconductor laser chip was fabricated which was largely similar to that of Practical Example 2. Specifically, in Practical Example 5, the barrier layers were formed of AlGaN. Whereas in Practical Example 2 the three barrier layers (first, second, and third barrier layers) had the same Al composition ratio, in Practical Example 5, they had different Al composition ratios. Specifically, the first barrier layer had an Al composition ratio of 2%, and the second and third barrier layers had an Al composition ratio of 0.08%. Practical Example 5 offered similar effects to Practical Example 2 described above. Incidentally, a design in which the first barrier layer has a higher Al composition ratio than the other barrier layers as in Practical Example 5 offered similar effects.

### Practical Example 6

As a nitride semiconductor laser chip according to Practical Example 6, by use of a GaN substrate having an off angle of 8 degrees in the a-axis direction and an off angle of +4 degrees in the c-axis direction relative to the m plane {1-100}, a nitride semiconductor laser chip was fabricated which was largely similar to that of Practical Example 2. The difference is that, in Practical Example 6, the semiconductor layer in contact with the principal growth plane of the substrate was not an n-type GaN layer but a lower clad layer. That is, in Practical Example 6, no n-type GaN layer was formed, and, on the principal growth plane of the substrate, nitride semiconductor layers were stacked starting with a lower clad layer of n-type Al_{0.06}Ga_{0.94}N with a thickness of about 2.2 μm. This too offered similar effects.

### Practical Example 7

As a nitride semiconductor laser chip according to Practical Example 7, by use of a GaN substrate having an off angle of 3 degrees in the a-axis direction and an off angle of +1 degree in the c-axis direction relative to the m plane {1-100}, a nitride semiconductor laser chip was fabricated which was largely similar to that of Practical Example 2. The difference is that, here, the semiconductor layer in contact with the principal growth plane of the substrate was, in place of the n-type GaN layer, an InGaN layer of In_{0.02}Ga_{0.98}N with a thickness of about 0.1 μm. That is, in Practical Example 7, individual nitride semiconductor layers were formed starting with an InGaN layer. This too offered similar effects.

### Practical Example 8

As a nitride semiconductor laser chip according to Practical Example 8, by use of a GaN substrate having an off angle of 4 degrees in the a-axis direction and an off angle of +1 degree in the c-axis direction relative to the m plane {1-100}, a nitride semiconductor laser chip was fabricated which was largely similar to that of Practical Example 2. The difference is that, in Practical Example 8, the semiconductor layer in contact with the principal growth plane of the substrate was not an n-type GaN layer but a layer of n-type In_{0.02}Ga_{0.98}N with a thickness of about 0.1 μm. That is, in Practical Example 8, no n-type GaN layer was formed, and, on the principal growth plane of the substrate, a nitride semiconductor layer of n-type. In_{0.02}Ga_{0.98}N with a thickness of about 0.1 μm was stacked. On top of this, a lower clad layer was formed which had a thickness of about 1.5 μm and had a super lattice structure of 250 cycles of n-type Al_{0.12}Ga_{0.88}N (with a thickness of 4 nm) and GaN (with a thickness of 2 nm). This too offered similar effects.

### Practical Example 9

In Practical Example 9, an LED was fabricated by use of a GaN substrate having an off angle of 3 degrees in the a-axis direction and an off angle of +0.5 degrees in the c-axis direction relative to the m plane {1-100}. In Practical Example 9, first, on the principal growth plane of the substrate, an n-type Al_{0.01}Ga_{0.99}N layer with a thickness of about 1 μm was formed, and thereafter a 4QW active layer of Al_{0.01}Ga_{0.99}N (with a thickness of about 15 nm) and In_{0.25}Ga_{0.75}N (with a thickness of about 3 nm) was formed. Next, on the 4QW active layer, a p-type Al_{0.2}Ga_{0.8}N carrier block layer with a thickness of about 20 nm was formed. Then, on the p-type Al_{0.2}Ga_{0.8}N carrier block layer, a p-type GaN contact layer with a thickness of about 0.2 μm was formed. Thereafter, on the p-type GaN contact layer, as an oxide-based transparent electrically conductive film, a film of ITO (indium tin oxide) with a thickness of about 50 nm was formed on an EB (electron beam) vapor deposition machine, thereby to form a p-side electrode of ITO. Structured in this way, Practical Example 9 too offered effects of suppressing development of dark lines, improving luminous efficacy, and suppressing bright-spotted emission.

As the above-mentioned oxide-based transparent electrically conductive film, instead of an ITO transparent electrically conductive film, which is indium oxide-based, it is possible to use a ZnO-based transparent electrically conductive film, of which the main component is zinc oxide, a SnO₂-based transparent electrically conductive film, which is tin oxide-based, or the like. By use of such a transparent electrically conductive film, it is possible to enhance light extraction efficiency. Moreover, by use of a substrate having an off angle in the a-axis direction relative to the m plane, it is possible to form the electrode on a p-type layer whose surface morphology has been improved, and thus it is possible to obtain a low contact resistance; furthermore, it is possible to suppress bright-spotted emission to achieve uniform light emission and uniform injection and thereby enhance luminous efficacy; thus, using a transparent electrically conductive film as the contact electrode for the nitride semiconductor layers formed on the above-described substrate gives a great advantage, and is therefore preferable. Particularly preferable is an ITO electrode, because it allows annealing at low temperature and is thus less likely to inflict thermal damage to the active layer. In Practical Example 9, annealing was performed at 400° C.

### Practical Example 10

In Practical Example 10, an LED having substantially the same structure as that of Practical Example 9 was fabricated by use of a substrate similar to that used in Practical Example 9. The difference is that, in Practical Example 10, the barrier layers are formed of AlₛInₜGaᵤN (s=0.01, t=0.03, u=0.96). This too offered effects similar to those mentioned above. Moreover, the content of In in addition to that of Al in the barrier layers permits growth at low temperature, and is therefore preferable.

It should be understood that the embodiments disclosed herein are in every respect illustrative and not restrictive. The scope of the present invention is set out not in the description of the embodiments presented above but in the appended claims, and encompasses any variations and modifications made within the sense and scope equivalent to those of the claims.

For example, although Embodiments 1 and 2 described above deal with examples in which the invention is applied to a nitride semiconductor laser chip as an example of a nitride semiconductor chip, this is not meant to limit the invention; the invention may be applied to nitride semiconductor light-emitting chips. The invention may also be applied to semiconductor chips other than nitride semiconductor light-emitting chips such as nitride semiconductor laser chips and nitride semiconductor light-emitting diode chips. For example, the invention may be applied to electronic devices such as power transistors, ICs (integrated circuits), and LSIs (large-scale integrated circuits).

Although Embodiments 1 and 2 described above deal with examples in which the off-angle in the a-axis direction is set to be larger than 0.1 degrees, this is not meant to limit the invention; the off-angle in the a-axis direction may be 0.1 degrees or smaller. With consideration given to the effect of suppressing bright-spotted emission, and to surface morphology, however, it is preferable that the off-angle in the a-axis direction be larger than ±0.1 degrees.

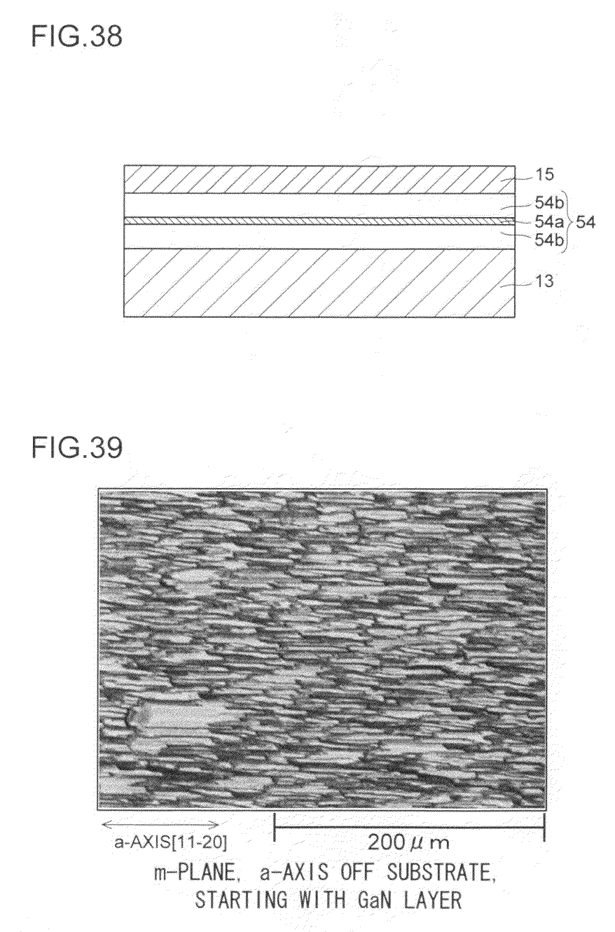

Although Embodiments 1 and 2 described above deal with examples in which the quantum well structure of the active layer is a DQW structure, this is not meant to limit the invention; the active layer may be formed to have a quantum well structure other than a DQW structure. For example, the quantum well structure of the active layer may be an SQW (single quantum well) structure. Specifically, for example, as shown in FIG. 38, on the lower guide layer 13, it is possible to form an active layer 54 having an SQW structure in which one well layer 54a of InGaN and two barrier layers 54b of Al_{0.005}Ga_{0.995}N are alternately stacked. The well layer 54a is given a thickness of about 3 nm to 4 nm, and the barrier layers 54b are given a thickness of about 70 nm. In the embodiments described above, giving the active layer an SQW structure helps reduce the driving voltage compared with giving it a DQW structure. Specifically, with an active layer having an SQW structure, the driving voltage as observed when a current of 50 mA is injected is about 0.1 V to 0.25 V lower than with an active layer having a DQW structure. This is considered to result possibly from the fact that, in a DQW structure, depletion of carriers in the barrier layer sandwiched between two well layers produces a strong electric field in the barrier layer. The active layer may be given, other than an SQW structure, an MQW structure. Also in cases where the active layer is given an SQW or MQW structure, it is possible to obtain an effect of suppressing bright-spotted emission. With a multiple quantum well structure including three or more well layers, it is possible to achieve effective light confinement and thereby increase gain.

Although Embodiments 1 and 2 described above deal with examples in which a GaN substrate is used as a nitride semiconductor substrate, this is not meant to limit the invention; any nitride semiconductor substrate other than a GaN substrate may instead be used. For example, it is possible to use nitride semiconductor substrates formed of InGaN, AlGaN, AlGaInN, etc. With regard to the individual nitride semiconductor layers grown as a crystal on the substrate, their respective thicknesses, compositions, etc. may be differently combined or changed appropriately to suit the desired characteristics. For example, a semiconductor layer may be added or eliminated, or the order of semiconductor layers may be partly changed. The conductivity types of semiconductor layers may be partly changed. That is, any variations and modifications are possible so long as the basic characteristics of a nitride semiconductor chip are obtained.

Although Embodiments 1 and 2 described above deal with examples in which the In composition ratio in the well layers is 0.2 to 0.25, this is not meant to limit the invention; the In composition ratio in the well layers may be changed as necessary within the range of 0.15 or more but 0.45 or less. The In composition ratio in the well layers may even be less than 0.15. The well layers may contain Al so long as its content is 5% or less. The carrier block layer may contain In so long as its content is 7% or less. The In content there is preferable because it makes it easy to form a film with good crystallinity at low temperature; it is preferable also because it helps reduce strain in the active layer that is formed to include a barrier layer formed of a nitride semiconductor layer containing Al, or Al and In.

In the embodiments describe above, the Al composition ratio x2 in the barrier layers may be changed as necessary within the range of 0<x2≦0.08. Incidentally, by forming the barrier layers out of AlGaN, it is possible to suppress dislocations that develop in the direction parallel to the c-axis direction (and appear as dark lines in the EL emission pattern) when the In composition ratio in the well layers is increased.

Although Embodiments 1 and 2 described above deal with examples in which the distance between the carrier block layer and the well layers is made equal to the thickness of the third barrier layer, it is also possible to form a plurality of nitride semiconductor layers of different compositions between the carrier block layer and the well layers (the most carrier block layer-side one of the well layers). Also preferable is to dope, to p-type, part of the interface between the carrier block layer and the well layers (the most carrier block layer-side one of the well layers) with a p-type impurity such as Mg. In the embodiments described above, no such doping is done.

Although Embodiments 1 and 2 described above deal with examples in which the carrier block layer is given a thickness of 40 nm or less, this is not meant to limit the invention; the carrier block layer may be given a thickness more than 40 nm. Even when the carrier block layer contains about 3% of In, the effects of the present invention can be obtained. For the purpose of reducing the driving voltage, it is preferable that the Al composition ratio in the carrier block layer be higher than the Al composition ratio in the p-type clad layer.

Although Embodiments 1 and 2 described above deal with examples in which Si is used as an n-type impurity for n-type semiconductor layers, this is not meant to limit the invention; as an n-type impurity other than Si, it is possible to use, for example, O, Cl, S, C, Ge, Zn, Cd, Mg, or Be. Particularly preferable n-type impurities are Si, O, and Cl.

Although Embodiments 1 and 2 described above deal with examples in which the insulating layer is formed of SiO₂, this is not meant to limit the invention; the insulating layer may be formed of an insulating material other than SiO₂. For example, the insulating layer may be formed of SiN, Al₂O₃, ZrO₂, or the like.

Although Embodiments 1 and 2 described above deal with examples in which the individual nitride semiconductor layers are grown by an MOCVD process, this is not meant to limit the invention; the individual nitride semiconductor layers may be grown by any epitaxial growth process other than an MOCVD process. Processes other than an MOCVD process include, for example, an HVPE (hydride vapor phase epitaxy) process, an MBE (molecular beam epitaxy) process, etc.

Although Embodiments 1 and 2 described above deal with examples in which the individual nitride semiconductor layers stacked on the GaN substrate do not include a GaN layer, this is not meant to limit the invention; the individual nitride semiconductor layers may include, as part of them, a GaN layer. For example, a GaN layer may be used as an optical guide layer or as a contact layer.

Although Embodiments 1 and 2 described above deal with examples in which a lower clad layer of AlGaN is the first to be formed on the GaN substrate, this is not meant to limit the invention; the formation of the lower clad layer may be preceded by the formation of a nitride semiconductor layer containing Al (for example, an AlGaN layer). That is, it is also possible to form, first, a nitride semiconductor layer containing Al (for example, an AlGaN layer) on, in contact with, the GaN substrate and then form a lower clad layer on that layer.

The AlGaN layer formed in contact with the GaN substrate may be one with n-type conductivity, one with p-type conductivity, or one which is undoped.

Although Embodiments 1 and 2 described above deal with examples in which, as the semiconductor layer in contact with the principal growth plane of the GaN substrate, an AlGaN layer is formed on the GaN substrate, this is not meant to limit the invention; the semiconductor layer in contact with the principal growth plane of the GaN substrate may be an AlInGaN layer, an AlInN layer, an InGaN layer, an InN layer, or the like.

The semiconductor layer formed in contact with the nitride semiconductor substrate may be one with n-type conductivity, one with p-type conductivity, or one which is undoped.

Although Embodiments 1 and 2 described above deal with examples in which the three barrier layers are all AlGaN layers, this is not meant to limit the invention; an AlGaN layer may be used as part of the three barrier layers. Forming at least one, in contact with a well layer, of a plurality of barrier layers out of a nitride semiconductor layer containing Al (for example, an AlGaN layer, an AlInGaN layer, an AlInN layer, or the like) offers an effect of enhancing luminous efficacy. As the number of well layers in the active layer varies, the number of barrier layers varies accordingly. In any case, by forming at least one barrier layer out of a nitride semiconductor layer containing Al, it is possible to obtain the above-mentioned effect. For example, in the embodiments described above, to enhance the flatness of the underlayer before the formation of a well layer, it is preferable to form the first and second barrier layers, which each serve as an underlayer before the formation of a well layer, out of a nitride semiconductor layer containing Al. An AlGaN layer also serves as an evaporation prevention layer for an InGaN layer, and accordingly, from the viewpoint of preventing evaporation, the second and third barrier layers, each formed on a well layer, may be nitride semiconductor layers containing Al. The second barrier layer may be given a two-layer structure composed of a side in contact with the first well layer and a side in contact with the second well layer, the side of the second barrier layer in contact with the first well layer being called the lower second barrier layer and the side of the second barrier layer in contact with the second well layer being called the upper second barrier layer. To enhance the flatness of the underlayer, it is preferable to form a nitride semiconductor layer containing Al as the upper second barrier layer. On the other hand, from the viewpoint of preventing evaporation, it is preferable to form a nitride semiconductor layer containing Al as the lower second barrier layer. All the barrier layers may be nitride semiconductor layers containing Al.

Although Embodiments 1 and 2 described above deal with examples in which the plurality of barrier layers are formed with different thicknesses, this is not meant to limit the invention; the plurality of barrier layers may be formed with the same thickness.

In the embodiments described above, any of the crystal axis directions mentioned (the [1-100] direction, the [11-20] direction, and the [0001] direction) may instead be any direction equivalent to it from a crystallographic point of view.

Although Embodiment 1 described above deals with examples in which, with a lower clad layer of AlGaN formed on the GaN substrate in contact with its principal growth plane, a barrier layer in the active layer is formed out of AlGaN, this is not meant to limit the invention; even in a case where the semiconductor layer in contact with the principal growth plane is a layer other than an AlGaN layer, by forming a barrier layer out of AlGaN, it is possible to obtain an effect of enhancing luminous efficacy. In a case where the semiconductor layer in contact with the principal growth plane is a GaN layer, it is preferable to form the GaN layer with a comparatively small thickness.

Although Embodiment 2 described above deals with examples in which two GaN layers, namely an n-type GaN layer and a lower guide layer, are formed between the substrate and the active layer, this is not meant to limit the invention; any GaN layer other than those just mentioned may also be formed so long as the total thickness is 0.7 μm or less. No GaN layer may be formed between the substrate and the active layer. In this case, it is preferable that the layered structure stacked on the substrate not include a GaN layer but be composed of semiconductor layers of compositions different from GaN, such as InGaN, AlGaN, InAlGaN, InAIN, etc.

Although Embodiment 2 described above deals with examples in which, with the GaN layer formed on the GaN substrate, between the substrate and the active layer, given a total thickness of 0.7 μm, a barrier layer in the active layer is formed out of AlGaN, this is not meant to limit the invention; even when the total thickness of the GaN layer is greater than 0.7 μm, by forming a barrier layer out of AlGaN, it is possible to obtain an effect of enhancing luminous efficacy.

What is claimed is:

1. A nitride semiconductor chip comprising:
a nitride semiconductor substrate having a principal growth plane; and
a nitride semiconductor layer formed on the principal growth plane of the nitride semiconductor substrate,
the principal growth plane being a plane having an off angle in an a-axis direction relative to an m plane,
the nitride semiconductor layer containing Al and being formed in contact with the principal growth plane.

2. The nitride semiconductor chip according to claim 1, wherein
an absolute value of the off angle in the a-axis direction is larger than 0.1 degrees.

3. The nitride semiconductor chip according to claim 1, wherein
the nitride semiconductor substrate is formed of GaN, and
the nitride semiconductor layer is formed of AlGaN.

4. The nitride semiconductor chip according to claim 1, wherein
an active layer having a quantum well structure is formed on the nitride semiconductor layer, and
the active layer has one well layer.

5. The nitride semiconductor chip according to claim 1, wherein
an active layer having a quantum well structure is formed on the nitride semiconductor layer, and
the active layer has two well layers.

6. The nitride semiconductor chip according to claim 1, wherein
an active layer having a quantum well structure is formed on the nitride semiconductor layer,
the active layer has a well layer formed of a nitride semiconductor containing In, and
the well layer has an In composition ratio of 0.15 or more but 0.45 or less.

7. The nitride semiconductor chip according to claim 4, wherein
the active layer has a barrier layer formed of a nitride semiconductor containing Al.

8. The nitride semiconductor chip according to claim 7, wherein
the barrier layer is formed of AlGaN.

9. The nitride semiconductor chip according to claim 1, wherein
the principal growth plane of the nitride semiconductor substrate has an off angle in a c-axis direction in addition to in the a-axis direction, and
the off angle in the a-axis direction is larger than the off angle in the c-axis direction.

10. A nitride semiconductor chip comprising:
a nitride semiconductor substrate having a principal growth plane;
a nitride semiconductor layer formed on the principal growth plane of the nitride semiconductor substrate; and
an active layer formed on the nitride semiconductor layer,
the principal growth plane being a non-polar plane,
the active layer having a barrier layer formed of a nitride semiconductor containing Al.

11. The nitride semiconductor chip according to claim 10, wherein
the principal growth plane is a plane having an off angle in an a-axis direction relative to an m plane.

12. The nitride semiconductor chip according to claim 10, wherein
the nitride semiconductor layer contains Al and is formed in contact with the principal growth plane.

13. A nitride semiconductor chip comprising:
a nitride semiconductor substrate having a principal growth plane; and
a nitride semiconductor stacked structure formed on the principal growth plane of the nitride semiconductor substrate,
the principal growth plane being a plane having an off angle in an a-axis direction relative to an m plane,
the nitride semiconductor stacked structure having an active layer containing In and a GaN layer formed between the nitride semiconductor substrate and the active layer,
the GaN layer having a total thickness of 0.7 μm or less.

14. The nitride semiconductor chip according to claim 13, wherein
an absolute value of the off angle in the a-axis direction is larger than 0.1 degrees.

15. The nitride semiconductor chip according to claim 13, wherein
the active layer has a quantum well structure including one well layer.

16. The nitride semiconductor chip according to claim 13, wherein
the active layer has a quantum well structure including two well layers.

17. The nitride semiconductor chip according to claim 13, wherein
the active layer has a quantum well structure and has a well layer formed of a nitride semiconductor containing In, and
the well layer has an In composition ratio of 0.15 or more but 0.45 or less.

18. The nitride semiconductor chip according to claim 13, wherein
the active layer has a barrier layer formed of a nitride semiconductor containing Al.

19. The nitride semiconductor chip according to claim 18, wherein
the barrier layer is formed of AlGaN.

20. The nitride semiconductor chip according to claim 13, wherein
the principal growth plane of the nitride semiconductor substrate has an off angle in a c-axis direction in addition to in the a-axis direction, and
the off angle in the a-axis direction is larger than the off angle in the c-axis direction.

21. The nitride semiconductor chip according to claim 13, wherein
the nitride semiconductor substrate is formed of GaN.

22. A nitride semiconductor chip comprising:
a nitride semiconductor substrate having a principal growth plane; and
a nitride semiconductor stacked structure formed on the principal growth plane of the nitride semiconductor substrate,
the principal growth plane being a plane having an off angle in an a-axis direction relative to an m plane,
the nitride semiconductor stacked structure including an active layer,
the active layer having a barrier layer formed of a nitride semiconductor containing Al.

23. The nitride semiconductor chip according to claim 22, wherein
the nitride semiconductor stacked structure further includes a semiconductor layer containing Al formed in contact with the principal growth plane.

24. The nitride semiconductor chip according to claim 23, wherein
the semiconductor layer containing Al is an AlGaN layer.

25. A method of manufacturing a nitride semiconductor chip, comprising:
a step of preparing a nitride semiconductor substrate including as a principal growth plane a plane having an off angle in an a-axis direction relative to an m plane; and
a step of forming on the principal growth plane of the nitride semiconductor substrate a nitride semiconductor layer containing Al in contact with the principal growth plane by an epitaxial growth process.

26. A method of manufacturing a nitride semiconductor chip, comprising:
a step of preparing a nitride semiconductor substrate including as a principal growth plane a plane having an off angle in an a-axis direction relative to an m plane; and
a step of forming on the principal growth plane of the nitride semiconductor substrate a nitride semiconductor stacked structure having an active layer containing In by an epitaxial growth process,
the step of forming the nitride semiconductor stacked structure including a step of forming a GaN layer between the nitride semiconductor substrate and the active layer,
the step of forming the GaN layer having a step of forming the GaN layer so that the GaN layer has a total thickness of 0.7 μm or less.

27. A semiconductor device comprising the nitride semiconductor chip according to claim 1.

28. A semiconductor device comprising the nitride semiconductor chip according to claim 13.
